(19) United States
(12) Patent Application Publication
(10) Pub. No.: US 2026/0022203 A1
(43) Pub. Date: Jan. 22, 2026

(54) SELF-CROSSLINKABLE POLYMER AND RESIST UNDERLAYER FILM FORMING COMPOSITION

(71) Applicant: NISSAN CHEMICAL CORPORATION, Tokyo (JP)

(72) Inventors: Yo KISHIKAWA, Toyama-shi (JP); Hikaru TOKUNAGA, Toyama-shi (JP)

(73) Assignee: NISSAN CHEMICAL CORPORATION, Tokyo (JP)

(21) Appl. No.: 18/850,809

(22) PCT Filed: Mar. 20, 2023
(86) PCT No.: PCT/JP2023/010815

§ 371 Date: Sep. 25, 2024

(30) Foreign Application Priority Data
Mar. 28, 2022 (JP) 2022-051966

(51) Int. Cl. C08G 61/12; C09D 165/00; G03F 7/11

(52) U.S. Cl. CPC C08G 61/124; C09D 165/00; G03F 7/11; C08G 2150/00; C08G 2261/1424; C08G 2261/314

(57) ABSTRACT

A self-cross-linkable polymer including unit structures A that have an aromatic ring and unit structures B that are organic groups with a connecting carbon atom, wherein: at least one kind of unit structure A is (i) a unit structure in which an —NR— bond connects at least two aromatic rings, (ii) a unit structure including a heterocyclic structure having at least one —NR— bond as a ring structural element, or (iii) a unit structure including an aromatic ring that has at least one —NR₂ substituent group; R is a hydrogen atom or alkoxymethyl group; at least some of the Rs in the entire polymer are alkoxymethyl groups; and the connecting carbon atom is a carbon atom in a unit structure B that forms a covalent bond with an aromatic ring in a unit structure A and is a carbon atom that does not form an aromatic ring.

### TECHNICAL FIELD

The present invention relates to a polymer resin suited for lithographic processing of semiconductor substrates, a resist underlayer film forming composition including the polymer resin, a resist underlayer film obtained from the resist underlayer film forming composition, a method for forming a resist pattern using the resist underlayer film forming composition, and a method for manufacturing a semiconductor device using the composition.

### BACKGROUND ART

In the recent lithographic processes for the manufacturing of semiconductor devices, there has been a demand that semiconductor process materials including resist underlayer films be further enhanced in performance.

For example, a resist underlayer film forming composition contains a polymer resin as the main component and further contains a crosslinking compound (a crosslinking agent) or a crosslinking reaction promoting catalyst (a crosslinking catalyst) that help the composition form a thermoset film. Without such a crosslinking agent or a crosslinking catalyst, the composition is usually incapable of forming a thermoset film unless heated to an extremely high temperature. The capability of forming a thermoset film at a lower temperature without a crosslinking agent or a crosslinking catalyst will simplify the work and such a polymer resin material is also advantageous in terms of cost. Furthermore, the addition of a crosslinking agent or a crosslinking catalyst often leads to problems, such as low etching resistance, more sublimates, optical constant variations, and deterioration in flattening properties and gap-filling properties. It is therefore strongly desired that a resist underlayer film material be designed without involving these components.

Patent Literatures 1 and 2 disclose polymers for use in organic film forming compositions. The polymers contain, on a nitrogen atom, a substituent having a carbon-carbon triple bond, such as a propargyl group. According to the disclosure, the carbon-carbon triple bonds serve as intermolecular crosslinking groups, and the compositions can form cured films even in an inert gas and exhibit high etching resistance and good gap-filling properties and flattening properties. However, the feature in these Patent Literatures resides in that the polymers contain carbon-carbon triple bonds on nitrogen atoms, and no other self-crosslinkable polymers are disclosed. Furthermore, these Patent Literatures are silent with respect to sublimates or the applicability to non-planar substrates.

### CITATION LIST

### Patent Literature

Patent Literature 1: JP 2019-41059 A
Patent Literature 2: JP 2019-44022 A

### SUMMARY OF INVENTION

### Technical Problem

It is therefore an object of the present invention to provide a polymer having, on a nitrogen atom, an alkoxymethyl group, such as an MOM group (a methoxymethyl group) and thereby to provide a polymer resin material that can form a thermoset film when being baked in air atmosphere or a nitrogen atmosphere irrespective of whether the temperature is high or low even in the absence of a crosslinking agent and a crosslinking catalyst. Another object of the present invention is to provide a resist underlayer film forming composition containing the polymer resin. These materials involve less components and thus offer cost advantages.

More preferably, objects of the present invention are to provide a polymer resin material that has high etching resistance and good gap-filling properties and flattening properties, generates less sublimate components when being baked, and exhibits good applicability with respect to a non-planar substrate, and to provide a resist underlayer film forming composition containing the polymer resin.

### Solution to Problem

Aspects of the present invention include the following.

[1]

A self-crosslinkable polymer comprising:

### (A)

one or more kinds of aromatic ring-containing unit structures A; and

### (B)

one or more kinds of unit structures B each comprising an organic group having one or more linking carbon atoms,
at least one kind of the unit structure A among the unit structures A is:
   (i)
a unit structure including a structure in which at least two aromatic rings are connected via at least one —NR— bond,
   (ii)
a unit structure containing a heterocyclic ring having at least one —NR— bond as a ring constituent, the unit structure being such that when the heterocyclic ring is not an aromatic heterocyclic ring, the heterocyclic ring forms a condensed ring with a first aromatic ring and/or is substituted with a substituent containing a second aromatic ring, or
   (iii)
a unit structure containing at least one aromatic ring having at least one —NR₂ substituent;
R is a hydrogen atom or an alkoxymethyl group and denotes an alkoxymethyl group in at least part of all the occurrences of R in the polymer; and
the linking carbon atom is a carbon atom in the unit structure B that forms a covalent bond with the aromatic ring in the unit structure A and does not constitute an aromatic ring.
   [2]

The self-crosslinkable polymer according to [1], which is a novolac resin.

[3]

The self-crosslinkable polymer according to [1] or [2], wherein the unit structures A are selected from unit structures (I-1) to (I-5) below:

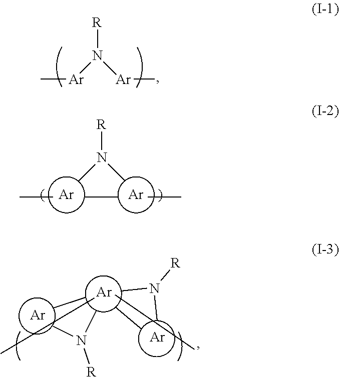

and regioisomers thereof,

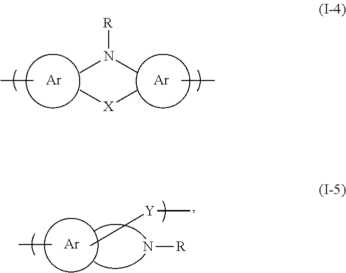

the unit structures (I-1) to (I-5) are optionally further substituted,
R in (I-1) to (I-5) is the same as defined in [1],
Ar in (I-1) independently at each occurrence denotes an optionally substituted aromatic ring and is the same as or different from one another,
in (I-2) to (I-5),

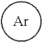

denotes an optionally substituted aromatic ring moiety in the condensed ring and is the same as or different from one another,
X in (I-4) denotes CR¹R², O, S, or NR′; R′ is the same as the definition of R in [1] and is the same as or different from R in the chemical formula (I-4); and R¹ and R² are the same as or different from each other and are each an aromatic ring residue or a C1-C3 aliphatic hydrocarbon group,
in (I-5),

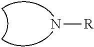

denotes an optionally substituted heterocyclic ring moiety in the condensed ring compound, and
Y is an aromatic ring-containing substituent on the aromatic ring moiety or on the heterocyclic ring moiety.
   [4]

The self-crosslinkable polymer according to any one of [1] to [3], wherein the unit structures B are unit structures including a structure represented by (II), (III), or (IV) below:

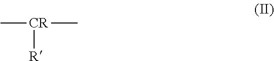

(in the formula (II), R and R′ each independently denote a hydrogen atom, an optionally substituted C6-C30 aromatic ring residue, an optionally substituted C3-C30 heterocyclic ring residue, or an optionally substituted C10 or lower, linear, branched, or cyclic alkyl group),

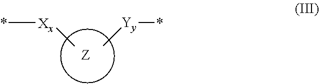

[in the formula (III),
Z is an optionally substituted C4-C25 monocyclic ring or bicyclic, tricyclic, or tetracyclic condensed ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic condensed ring is optionally further condensed with one or more aromatic rings to form a pentacyclic or higher condensed ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1,

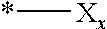

is bonded to any carbon atom (referred to as “carbon atom 1”) constituting any of the non-aromatic monocyclic rings in Z (when x=1) or extends from the carbon atom 1 (when x=0),

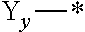

is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond],

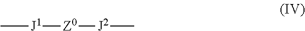

[in the formula (IV), Z⁰ denotes an optionally substituted C6-C30 aromatic ring residue, aliphatic ring residue, or organic group including two aromatic ring residues or aliphatic ring residues connected to each other via a single bond, and J¹ and J² each independently denote a direct bond or an optionally substituted divalent organic group].
[5]

The self-crosslinkable polymer according to [4], wherein
the formula (III) is formula (III-1) below:

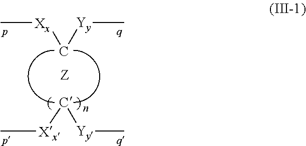

[in the formula (III-1),
Z is an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings,
the monocyclic, bicyclic, tricyclic, or tetracyclic organic group is optionally further condensed or fused with one or more aromatic rings to form a pentacyclic or higher condensed ring,
C and C′ each denote a carbon atom among atoms constituting a ring moiety of any of the non-aromatic monocyclic rings in Z, and C and C′ belong to the same non-aromatic monocyclic ring or to different non-aromatic monocyclic rings,
n indicates the number of the carbon atoms C′ and denotes an integer of 0 to 2,
p, q, p′, and q′ indicate the number of a valence bond and each independently denote 0 or 1,
when n is 0, p and q are 1,
when n is 1 or 2, at least one of p or q, and at least one of p′ or q′ in each C′ are each 1,
when n is 2, the two C′ atoms belong to the same non-aromatic monocyclic ring while optionally bonding directly to each other, or the two C′ atoms belong to different non-aromatic monocyclic rings,
X, Y, X′, and Y′ denote identical or different —CR¹R²— groups; R¹ and R² are the same as or different from each other and each denote a hydrogen atom or a C1-C3 hydrocarbon group; and when n is 2, the two groups X′ are the same as or different from each other, and the two groups Y′ are the same as or different from each other, and
x, y, x′, and y′ indicate the numbers of X, Y, X′, and Y′, respectively, and each independently denote 0 or 1].
   [6]

The self-crosslinkable polymer according to any one of [1] to [5], wherein the self-crosslinkable polymer is terminated with an optionally substituted C6-C30 aromatic ring residue, an optionally substituted C1-C10 unsaturated hydrocarbon group, a hydroxyl group, or a hydrogen atom.

[7]

A resist underlayer film forming composition comprising a thermal acid generator, the self-crosslinkable polymer described in any one of [1] to [6], and a solvent.

[8]

The resist underlayer film forming composition according to [7], further comprising a crosslinking agent.

[9]

The resist underlayer film forming composition according to [8], wherein the crosslinking agent is an aminoplast crosslinking agent or a phenoplast crosslinking agent.

[10]

The resist underlayer film forming composition according to [9], wherein the aminoplast crosslinking agent is a highly alkylated, alkoxylated, or alkoxyalkylated melamine, benzoguanamine, glycoluril, or urea, or a polymer thereof.

[11]

The resist underlayer film forming composition according to [9], wherein the phenoplast crosslinking agent is a highly alkylated, alkoxylated, or alkoxyalkylated aromatic compound, or a polymer thereof.

[12]

The resist underlayer film forming composition according to any one of [7] to [11], wherein the solvent is a compound having an alcoholic hydroxyl group or a compound having a group capable of forming an alcoholic hydroxyl group.

[13]

The resist underlayer film forming composition according to [12], wherein the compound having an alcoholic hydroxyl group or the compound having a group capable of forming an alcoholic hydroxyl group is a propylene glycol solvent, an oxyisobutyric acid ester solvent, or a butylene glycol solvent.

[14]

The resist underlayer film forming composition according to [12], wherein the compound having an alcoholic hydroxyl group or the compound having a group capable of forming an alcoholic hydroxyl group is propylene glycol monomethyl ether, cyclohexanone, propylene glycol monomethyl ether acetate, ethyl lactate, or methyl 2-hydroxy-2-methylpropionate.

[15]

The resist underlayer film forming composition according to any one of [7] to [14], further comprising a surfactant.

[16]

On a semiconductor substrate, a resist underlayer film comprising a baked product of a coating film comprising the resist underlayer film forming composition described in any one of [7] to [15].

[17]

A method for forming a resist pattern used in semiconductor manufacturing, the method comprising a step of applying the resist underlayer film forming composition described in any one of [7] to [15] onto a semiconductor substrate, and baking the resist underlayer film forming composition to form a resist underlayer film.

[18]

A method for manufacturing a semiconductor device, comprising:
a step of forming on a semiconductor substrate a resist underlayer film from the resist underlayer film forming composition described in any one of [7] to [15];
a step of forming a resist film on the resist underlayer film;
a step of forming a resist pattern by irradiation with light or electron beam followed by development;
a step of etching the resist underlayer film through the resist pattern; and
a step of processing the semiconductor substrate through the resist underlayer film having been patterned.
   [19]

A method for manufacturing a semiconductor device, comprising:
a step of forming on a semiconductor substrate a resist underlayer film from the resist underlayer film forming composition described in any one of [7] to [15];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned; and
a step of processing the semiconductor substrate through the resist underlayer film having been patterned.
   [20]

A method for manufacturing a semiconductor device, comprising:
a step of forming on a semiconductor substrate a resist underlayer film from the resist underlayer film forming composition described in any one of [7] to [15];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.
   [21]

A method for manufacturing a semiconductor device, comprising:
a step of forming on a semiconductor substrate a resist underlayer film from the resist underlayer film forming composition described in any one of [7] to [15];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.
   [22]

The manufacturing method according to any one of [19] to [21], wherein the hard mask is formed by applying an inorganic substance or by depositing an inorganic substance.

[23]

The manufacturing method according to any one of [18] to [21], wherein the resist film is patterned by a nanoimprinting method or by using a self-assembled film.

[24]

The method for manufacturing a semiconductor device according to [20] or [21], wherein the hard mask is removed by etching or with an alkaline chemical solution.

### Advantageous Effects of Invention

The self-crosslinkable polymer according to an aspect of the present invention can form a thermoset film when being baked in air atmosphere or a nitrogen atmosphere irrespective of whether the temperature is high or low even in the absence of a crosslinking agent and a crosslinking catalyst. The self-crosslinkable polymer involves less components and thus offers cost advantages.

More preferred aspects provide a polymer resin material comprising the self-crosslinkable polymer according to an aspect of the present invention, and a resist underlayer film forming composition containing the polymer resin. These materials have high etching resistance and good gap-filling properties and flattening properties, generate less sublimate components when being baked, and exhibit good applicability with respect to a non-planar substrate.

### DESCRIPTION OF EMBODIMENTS

### 1. Definition of Terms

The definitions of the main terms in the present specification related to novolac resins constituting an aspect of the present invention will be described below. Unless otherwise specified separately, the terms related to novolac resins are based on the following definitions.

### (1-1) “Novolac Resins”

The term “novolac resins” refers not only to narrowly defined phenol-formaldehyde resins (so-called novolac-type phenol resins) and aniline-formaldehyde resins (so-called novolac-type aniline resins) but also to a broad range of general polymers formed by the formation of covalent bonds (such as a substitution reaction, an addition reaction, a condensation reaction, or an addition condensation reaction) between an organic compound that has a functional group enabling covalent bonding to an aromatic ring in the presence of an acid catalyst or under similar reaction conditions [such as, for example, an aldehyde group, a ketone group, an acetal group, a ketal group; a hydroxyl or alkoxy group bonded to a secondary or tertiary carbon; a hydroxyl, alkoxy, or halo group bonded to an α-carbon atom in an alkylaryl group (such as a benzylic carbon atom); or a carbon-carbon unsaturated bond, such as divinylbenzene or dicyclopentadiene], and an aromatic ring in an aromatic ring-containing compound (preferably having, on the aromatic ring, a substituent containing a heteroatom, such as an oxygen atom, a nitrogen atom, or a sulfur atom).

Thus, the novolac resins referred to in the present specification are polymers in which the organic compound that contains a carbon atom derived from the above functional group (sometimes written as the “linking carbon atom”) connects a plurality of molecules of the aromatic ring-containing compound by forming, via the linking carbon atoms, covalent bonds with the aromatic rings in the molecules of the aromatic ring-containing compound.

In the present specification, the unit structures constituting a “novolac resin” are written as unit structures A, unit structures B, and unit structures C. The unit structure A is a unit structure derived from an aromatic ring-containing compound. The unit structure B is a unit structure derived from a compound having a functional group enabling covalent bonding to the aromatic ring in the unit structure A. The unit structure C is a unit structure that is equivalent, in bonding mode, to a composite unit structure A-B, and is derived from a compound having an aromatic ring and also having a functional group enabling covalent bonding to the aromatic ring in the unit structure A. Due to the identicalness in bonding mode, the unit structure C may be replaced with the composite unit structure A-B.

### (1-2) “Residues”

The term “residue” indicates an organic group that has a valence bond in place of a hydrogen atom bonded to a carbon atom or a heteroatom (such as a nitrogen atom, an oxygen atom, or a sulfur atom) and may be a monovalent group or a polyvalent group. For example, the substitution of one hydrogen atom with one valence bond results in a monovalent organic group, and the substitution of two hydrogen atoms with valence bonds yields a divalent organic group.

### (1-3) “Aromatic Rings” (Aromatic Groups, Aryl Groups, Arylene Groups)

The concept of “aromatic rings” comprehends aromatic hydrocarbon rings, aromatic heterocyclic rings, and residues thereof [also written as “aromatic groups”, “aryl groups” (in the case of monovalent groups), or “arylene groups” (in the case of divalent groups)], and the rings may be monocyclic (aromatic monocyclic rings) or polycyclic (aromatic polycyclic rings). In the case of polycyclic rings, at least one monocyclic ring is an aromatic monocyclic ring, but the remaining monocyclic ring or rings that form the condensed ring with that aromatic monocyclic ring may be monocyclic heterocyclic rings (heteromonocyclic rings) or monocyclic alicyclic hydrocarbons (alicyclic monocyclic rings).

Examples of the aromatic rings include, but are not limited to, aromatic hydrocarbon rings, such as benzene, indene, naphthalene, azulene, styrene, toluene, xylene, mesitylene, cumene, anthracene, phenanthrene, triphenylene, benzanthracene, pyrene, chrysene, fluorene, biphenyl, corannulene, perylene, fluoranthene, benzo[k]fluoranthene, benzo[b]fluoranthene, benzo[ghi]perylene, coronene, dibenzo[g,p]chrysene, acenaphthylene, acenaphthene, naphthacene, pentacene, and cyclooctatetraene, more typically, such aromatic hydrocarbon rings as benzene, naphthalene, anthracene, and pyrene; and aromatic heterocyclic rings, such as furan, pyran, pyridine, pyrimidine, pyrazine, thiophene, pyrrole, N-alkylpyrrole, N-arylpyrrole, imidazole, pyridine, pyrimidine, pyrazine, triazine, thiazole, indole, phenylindole, bisindolefluorene, bisindolebenzofluorene, bisindoledibenzofluorene, purine, quinoline, isoquinoline, chromene, thianthrene, phenothiazine, phenoxazine, xanthene, acridine, phenazine, carbazole, and indolocarbazole, more typically, furan, thiophene, pyrrole, indole, phenylindole, bisindolefluorene, phenothiazine, carbazole, and indolocarbazole.

The aromatic rings (such as, for example, benzene ring or naphthalene ring) may optionally have a substituent. Examples of such substituents include halogen atoms; saturated or unsaturated, linear, branched, or cyclic hydrocarbon groups (—R) (the hydrocarbon chains may be interrupted with an oxygen atom one or more times; examples of R include alkyl groups, alkenyl groups, alkynyl groups, and propargyl group); alkoxy groups or aryloxy groups (—OR wherein R denotes the hydrocarbon group —R described above); alkylamino groups [—NHR or —NR₂ (the two groups R may be the same as or different from each other), wherein R denotes the hydrocarbon group —R described above and may be, for example, an alkyl group, an alkenyl group, an alkynyl group, or a propargyl group, and the hydrocarbon chains may be interrupted with an oxygen atom one or more times]; hydroxyl group; amino group (—NH₂); carboxyl group; cyano group; nitro group; ester groups (—CO₂R or —OCOR wherein R denotes the hydrocarbon group —R described above); amide groups (—NHCOR, —CONHR, —NRCOR (the two groups R may be the same as or different from each other), or —CONR₂ (the two groups R may be the same as or different from each other), wherein R denotes the hydrocarbon group —R described above); sulfonyl-containing groups (—SO₂R wherein R denotes the hydrocarbon group —R described above or the hydroxyl group —OH); thiol group (—SH); sulfide-containing groups (—SR wherein R denotes the hydrocarbon group —R described above); ether bond-containing organic groups [residues of an ether compound represented by R¹¹—O—R¹¹ (R¹¹ independently at each occurrence denotes a C1-C6 alkyl group, such as a methyl group or an ethyl group, or an aryl group, such as a phenyl group, a naphthyl group, an anthranyl group, or a pyrenyl group); for example, organic groups containing an ether bond as a methoxy group, an ethoxy group, or a phenoxy group]; and aryl groups.

Furthermore, the aromatic rings may be organic groups having a condensed ring formed of one or more aromatic rings (such as benzene, naphthalene, anthracene, or pyrene) with one or more aliphatic rings or heterocyclic rings. Examples of the aliphatic rings here include cyclobutane, cyclobutene, cyclopentane, cyclopentene, cyclohexane, cyclohexene, methylcyclohexane, methylcyclohexene, cycloheptane, and cycloheptene. Examples of the heterocyclic rings include furan, thiophene, pyrrole, imidazole, pyran, pyridine, pyrimidine, pyrazine, pyrrolidine, piperidine, piperazine, and morpholine.

The aromatic rings may be organic groups having a structure in which two or more aromatic rings are connected via a divalent linking group, such as an alkylene group.

### (1-4) “Heterocyclic Rings”

The concept of “heterocyclic rings” comprehends both aliphatic heterocyclic rings and aromatic heterocyclic rings and includes not only monocyclic rings (heteromonocyclic rings) but also polycyclic rings (heteropolycyclic rings). In the case of polycyclic rings, at least one monocyclic ring is a heteromonocyclic ring, but the remaining monocyclic ring or rings may be aromatic hydrocarbon monocyclic rings or alicyclic monocyclic rings. Examples of the aromatic heterocyclic rings include those described in (1-3) above. Similarly to the aromatic rings in (1-3), the heterocyclic rings may have a substituent.

### (1-5) “Non-Aromatic Rings” (Aliphatic Rings)

The term “non-aromatic monocyclic rings” refers to monocyclic hydrocarbons that are not aromatic, and typically indicates monocyclic rings of alicyclic compounds. The rings may also be referred to as aliphatic monocyclic rings (including aliphatic heteromonocyclic rings) (the rings may contain an unsaturated bond as long as the rings do not belong to aromatic compounds). Similarly to the aromatic rings in (1-3), the non-aromatic monocyclic rings may have a substituent.

Examples of the non-aromatic monocyclic rings (aliphatic rings, aliphatic monocyclic rings) include cyclopropane, cyclobutane, cyclobutene, cyclopentane, cyclopentene, cyclohexane, methylcyclohexane, cyclohexene, methylcyclohexene, cycloheptane, and cycloheptene.

The term “non-aromatic polycyclic rings” refers to polycyclic hydrocarbons that are not aromatic, and typically indicates polycyclic rings of alicyclic compounds. The rings may also be referred to as aliphatic polycyclic rings [including aliphatic heteropolycyclic rings (at least one of the monocyclic rings constituting the polycyclic ring is an aliphatic heterocyclic ring) (the rings may contain an unsaturated bond as long as the rings do not belong to aromatic compounds)]. The non-aromatic polycyclic rings include non-aromatic bicyclic rings, non-aromatic tricyclic rings, and non-aromatic tetracyclic rings.

The term “non-aromatic bicyclic rings” refers to condensed rings composed of two monocyclic hydrocarbons that are not aromatic, and typically indicates condensed rings composed of two alicyclic compounds. In the present specification, the rings are also referred to as aliphatic bicyclic rings (including aliphatic heterobicyclic rings) (the rings may contain an unsaturated bond as long as the rings do not belong to aromatic compounds). Examples of the non-aromatic bicyclic rings include bicyclopentane, bicyclooctane, and bicycloheptene.

The term “non-aromatic tricyclic rings” refers to condensed rings composed of three monocyclic hydrocarbons that are not aromatic, and typically indicates condensed rings composed of three alicyclic compounds (that may be each a heterocyclic ring and may contain an unsaturated bond as long as the compound does not belong to aromatic compounds). Examples of the non-aromatic tricyclic rings include tricyclooctane, tricyclononane, and tricyclodecane.

The term “non-aromatic tetracyclic rings” refers to condensed rings composed of four monocyclic hydrocarbons that are not aromatic, and typically indicates condensed rings composed of four alicyclic compounds (that may be each a heterocyclic ring and may contain an unsaturated bond as long as the compound does not belong to aromatic compounds). Examples of the non-aromatic tetracyclic rings include hexadecahydropyrene.

(1-6)

The term “carbon atoms constituting a ring (moiety)” means the carbon atoms constituting a hydrocarbon ring (which may be an aromatic ring, an aliphatic ring, or a heterocyclic ring) in a substituent-free form.

(1-7)

The term “hydrocarbon groups” refers to groups resulting from the removal of one, or two or more hydrogen atoms from a hydrocarbon. The hydrocarbons include saturated or unsaturated aliphatic hydrocarbons, saturated or unsaturated alicyclic hydrocarbons, and aromatic hydrocarbons.

(1-8)

In the chemical structural formulas showing unit structures of novolac resins in the present specification, valence bonds (indicated by *) are sometimes described for the purpose of convenience. Such valence bonds may be present at any possible bonding positions in the unit structures unless otherwise specified, and the bonding positions in the unit structures are not limited to those that are illustrated.

### 2. Self-Crosslinkable Polymers [1]

(2-1)

A self-crosslinkable polymer according to an aspect of the present invention comprises:

### (A)

one or more kinds of aromatic ring-containing unit structures A; and

### (B)

one or more kinds of unit structures B each comprising an organic group having one or more linking carbon atoms.

At least one kind of the unit structure A among the unit structures A is:

(i)
a unit structure including a structure in which at least two aromatic rings are connected via at least one —NR— bond,
   (ii)
a unit structure containing a heterocyclic ring having at least one —NR— bond as a ring constituent, the unit structure being such that when the heterocyclic ring is not an aromatic heterocyclic ring, the heterocyclic ring forms a condensed ring with a first aromatic ring and/or is substituted with a substituent containing a second aromatic ring, or
   (iii)
a unit structure containing at least one aromatic ring having at least one —NR₂ substituent.

Here, R is a hydrogen atom or an alkoxymethyl group and denotes an alkoxymethyl group in at least part of all the occurrences of R in the polymer. Self-crosslinkability is thus imparted. The alkoxy in the alkoxymethyl group is preferably a C1-C10 hydrocarbon group, and more preferably a C1-C3 hydrocarbon group. The methoxymethyl group is most preferable.

R denotes an alkoxymethyl group in at least part of all the occurrences of R in the polymer. The frequency of the alkoxymethyl groups is controlled so as to attain desired self-crosslinkability.

One linking carbon atom [see (1-1)] in the unit structure B may (i) form covalent bonds with the respective aromatic rings in two unit structures A or (ii) form covalent bonds with the aromatic ring in one unit structure A and a polymer terminal group. In the latter case (ii), the unit structure B contains at least two linking carbon atoms, and more preferably contains two linking carbon atoms.

Furthermore, the linking carbon atom is a carbon atom in the unit structure B that forms a covalent bond with the aromatic ring in the unit structure A and thereby establishes covalent bonding between the unit structure A and the unit structure B, and does not constitute an aromatic ring.

Incidentally, the covalent bonding with the aromatic ring in the unit structure A comprehends covalent bonding with an aromatic ring in a unit structure C described later [(2-4-3-3), (2-4-5-3), and (2-4-6)] that is equivalent to a composite unit structure A-B in which one unit structure A and one unit structure B are bonded to each other.

(2-2)

The self-crosslinkable polymer according to an aspect of the present invention is preferably a novolac resin [see (1-1)].

Thus, the novolac resin referred to in the present specification is a polymer in which an organic compound (unit structures B) that contains a carbon atom derived from a functional group (corresponding to the “linking carbon atom”) connects a plurality of molecules of an aromatic ring-containing compound by forming covalent bonds with the aromatic rings (unit structures A) in the molecules of the aromatic ring-containing compound.

### (2-3: Unit Structures A)

(2-3-1)

The unit structures A in the self-crosslinkable polymer according to an aspect of the present invention comprise one or more kinds of aromatic ring-containing unit structures.

At least one kind of the unit structure A among the unit structures A is:

(i)
a unit structure including a structure in which at least two aromatic rings are connected via at least one —NR— bond,
   (ii)
a unit structure containing a heterocyclic ring having at least one —NR— bond as a ring constituent, the unit structure being such that when the heterocyclic ring is not an aromatic heterocyclic ring, the heterocyclic ring forms a condensed ring with a first aromatic ring and/or is substituted with a substituent containing a second aromatic ring, or
   (iii)
a unit structure containing at least one aromatic ring having at least one —NR₂ substituent.

Here, R is a hydrogen atom or an alkoxymethyl group and denotes an alkoxymethyl group in at least part of all the occurrences of R in the polymer.

The connection of the aromatic rings via an —NR— bond in (i) does not necessarily mean that the —NR— bond is directly covalently bonded to the aromatic rings. In an embodiment, the covalent bonds may be indirect via a divalent organic group (for example, a divalent hydrocarbon chain). In another embodiment, a plurality of —NR— bonds are connected to one another via a divalent organic group (for example, a divalent hydrocarbon chain), and two aromatic rings are connected via the unit of —NR— bonds.

The unit structure in (ii) containing a heterocyclic ring has an embodiment in which the heterocyclic ring forms a condensed ring with one or more first aromatic rings, or an embodiment in which the heterocyclic ring or the condensed ring is substituted with a substituent containing a second aromatic ring. The substituent on the condensed ring may be present on the heterocyclic ring moiety or on the first aromatic ring moiety. When the heterocyclic ring is not an aromatic heterocyclic ring, the heterocyclic ring forms a condensed ring with a first aromatic ring and/or is substituted with a substituent containing a second aromatic ring. This is because the unit structure A is an aromatic ring-containing unit structure. Here, specific examples of the unit structures in which the —NR— bond-containing ring is aromatic include such aromatic rings as pyrrole ring and such condensed aromatic rings as carbazole.

The unit structure in (iii) containing an aromatic ring having an —NR₂ substituent represents an embodiment in which the aromatic ring (that may be an aromatic hydrocarbon ring or an aromatic heterocyclic ring) has an —NR₂ substituent as a heteroatom-containing substituent. It is preferable that at least one of the two Rs in the —NR₂ substituent be an alkoxymethyl group, and it is more preferable that one of the two Rs be an alkoxymethyl group. Furthermore, the aromatic ring is preferably a condensed ring composed of a plurality of aromatic monocyclic rings.

(2-3-2)
(2-3-2-1)

In the case (i), the unit structure A is a unit structure including a structure in which at least two aromatic rings are connected via at least one —NR— bond. Such a unit structure is typically represented by formula (I-1) below:

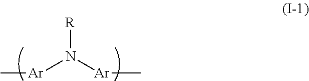

[wherein Ar denotes an aromatic ring and is the same as or different from one another, and R denotes a hydrogen atom or an alkoxymethyl group].

Embodiments of the unit structure further include those in which the plurality of aromatic rings connected via an —NR— bond have an additional connection via a single bond and thereby form a ring. Examples of such unit structures include those represented by formulas (I-2) and (I-3) below and regioisomers thereof.

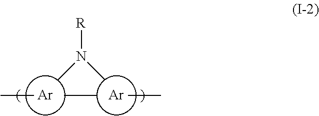

[In the formula,

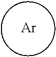

denotes an optionally substituted aromatic ring moiety in the condensed ring and is the same as or different from one another, and
R denotes a hydrogen atom or an alkoxymethyl group.]

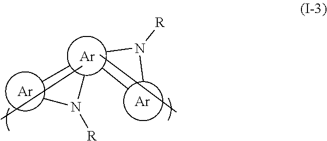

[In the formula,

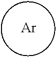

denotes an optionally substituted aromatic ring moiety in the condensed ring and is the same as or different from one another, and
R denotes a hydrogen atom or an alkoxymethyl group.]
   (2-3-2-2)

In the case (ii), the unit structure A is a unit structure containing a heterocyclic ring having at least one —NR— bond as a ring constituent. Examples of such unit structures include those represented by formulas (I-4) and (I-5) below:

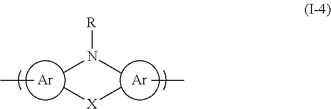

[wherein

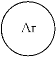

denotes an optionally substituted aromatic ring moiety in the condensed ring and is the same as or different from one another,
R denotes a hydrogen atom or an alkoxymethyl group,
X denotes C(R¹)(R²), O, S, or NR′; R′ is the same as the definition of R and is the same as or different from R; and R¹ and R² are the same as or different from each other and are each a C1-C3 aliphatic hydrocarbon group],

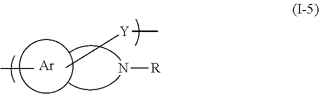

[wherein

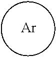

denotes an optionally substituted aromatic ring moiety in the condensed ring and is the same as or different from one another,

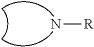

denotes an optionally substituted heterocyclic ring moiety in the condensed ring compound,
R denotes a hydrogen atom or an alkoxymethyl group, and
Y is an aromatic ring-containing substituent on the aromatic ring moiety or on the heterocyclic ring moiety].

The aromatic ring present in Y may be directly bonded to the condensed ring in the formula (I-5) or may be bonded to the condensed ring in the formula (I-5) via a divalent organic group. Furthermore, the aromatic ring present in Y may be directly bonded to the condensed ring in the formula (I-5) or may be indirectly bonded via a divalent linking group (for example, a divalent hydrocarbon group).

Furthermore, the valence bond on Y to other unit structure preferably extends from the aromatic ring in Y.

(2-3-3)

Preferably, the unit structures A containing an —NR— bond are at least one kind of unit structures selected from the following:

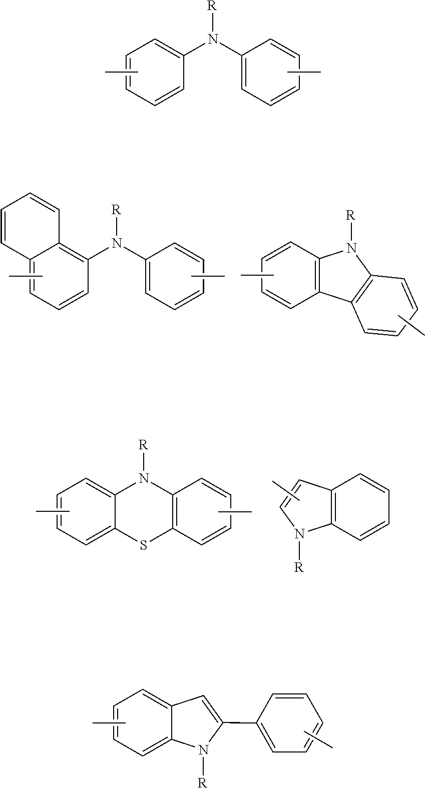

(2-3-4)

The “aromatic rings” in the unit structures A in the self-crosslinkable polymer according to an aspect of the present invention are as described in (1-3) hereinabove.

The “aromatic rings” in the unit structures A in the self-crosslinkable polymer according to an aspect of the present invention preferably has 6 to 30 or 6 to 24 carbon atoms.

Preferably, the “aromatic rings” in the unit structures A in the self-crosslinkable polymer according to an aspect of the present invention is one or more benzene, naphthalene, anthracene, or pyrene rings; or is a condensed ring formed between a benzene ring, a naphthalene ring, an anthracene ring, or a pyrene ring and a heterocyclic ring or an aliphatic ring.

(2-3-5)

The aromatic rings in the unit structures A in the self-crosslinkable polymer according to an aspect of the present invention may further have a substituent as long as the advantageous effects of the present invention are not impaired. The substituents are as described in (1-3) hereinabove.

(2-3-6)

Preferably, the unit structures A containing an —NR— bond or an NR₂ substituent are at least one kind of unit structures selected from the following.

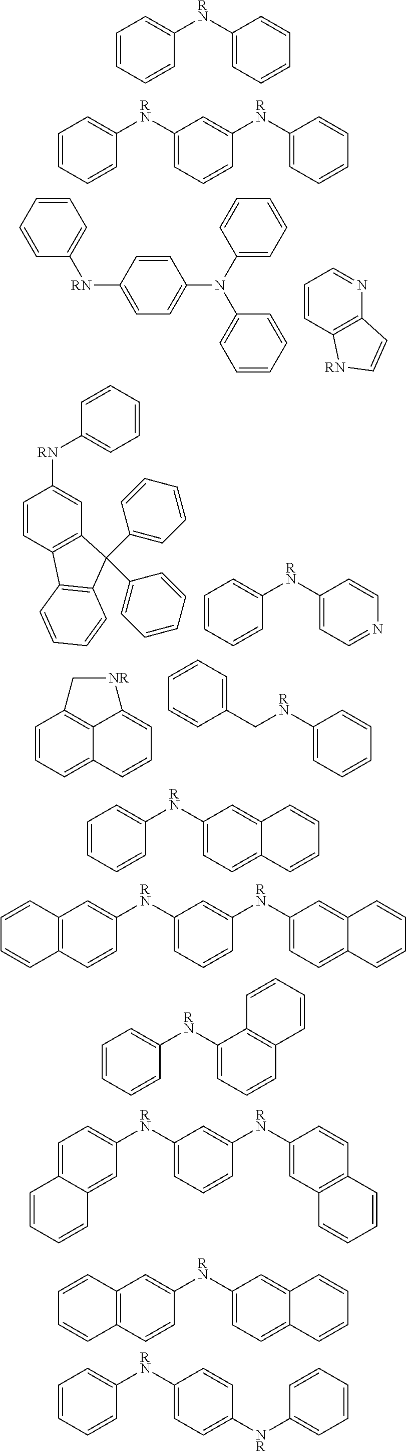

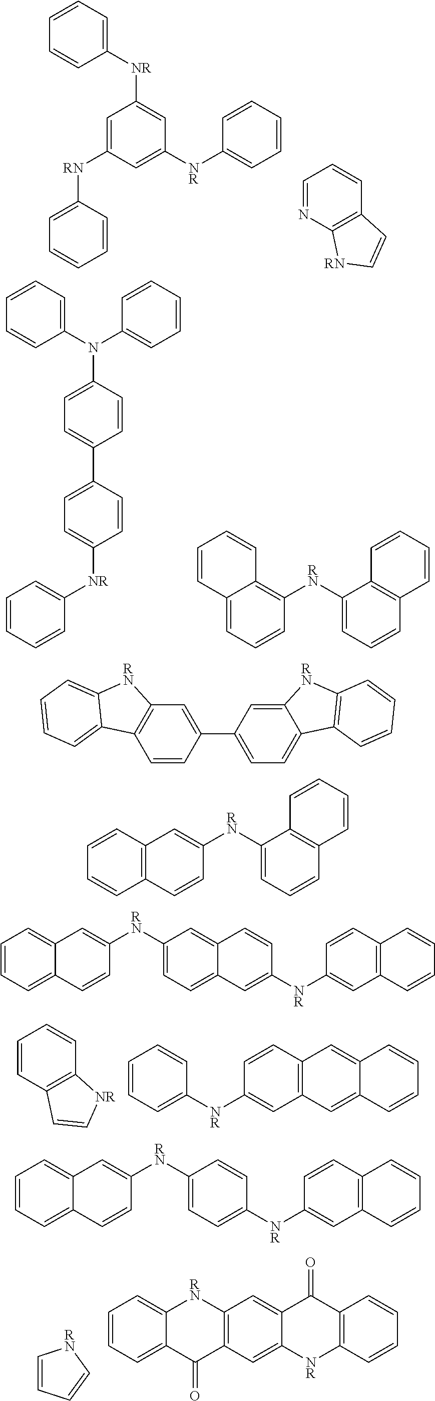

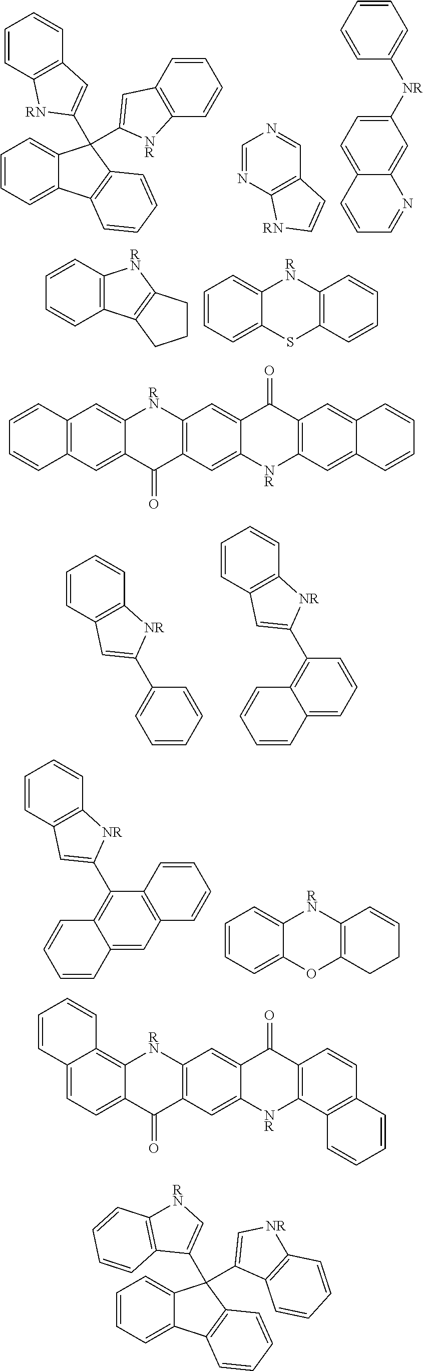

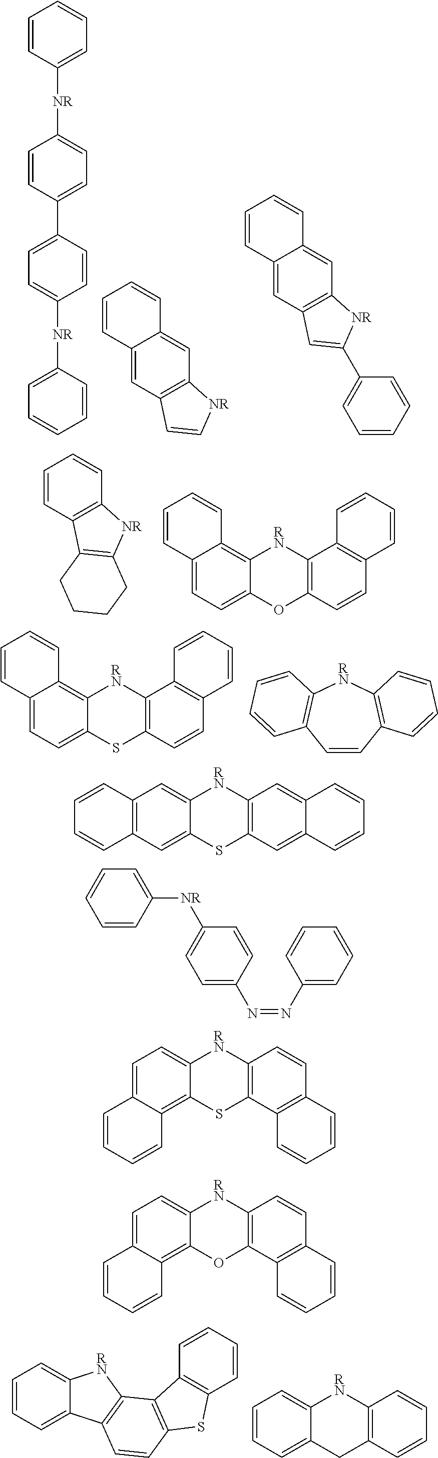

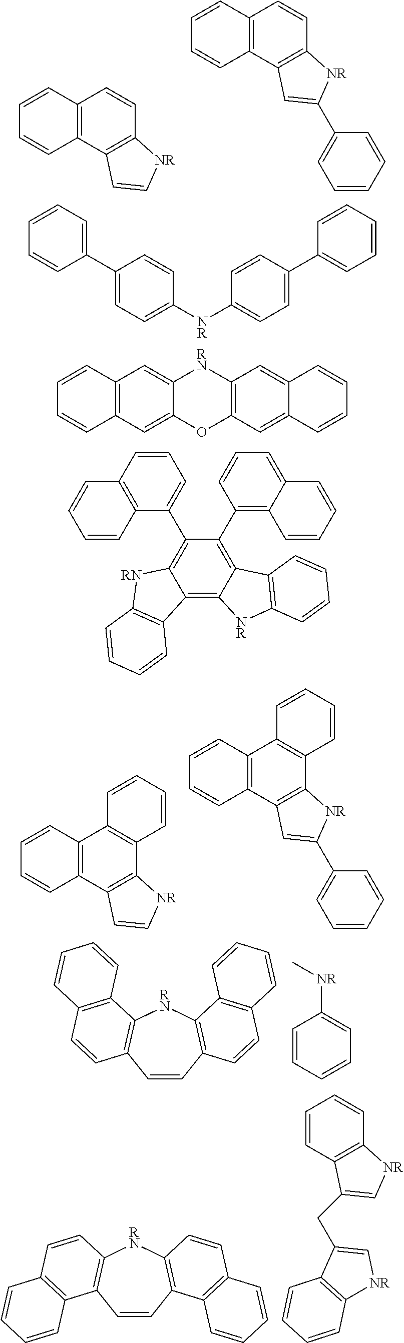

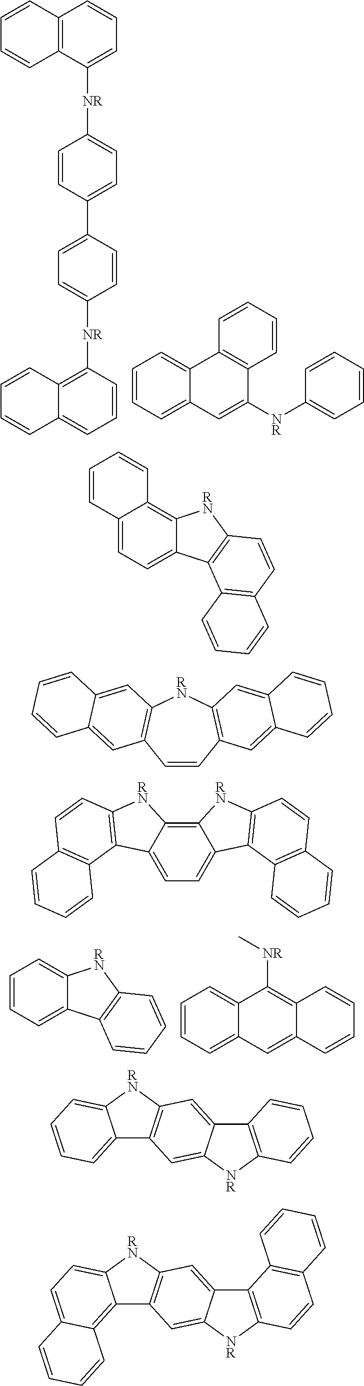

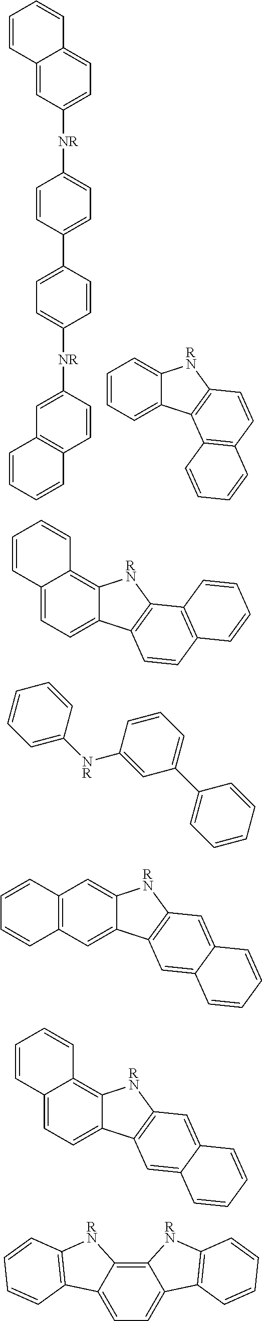

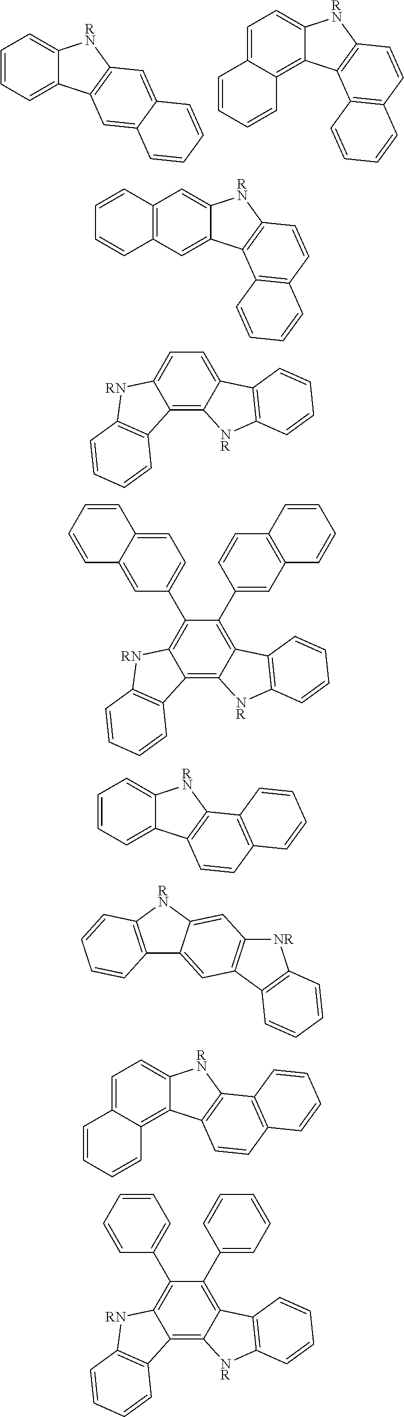

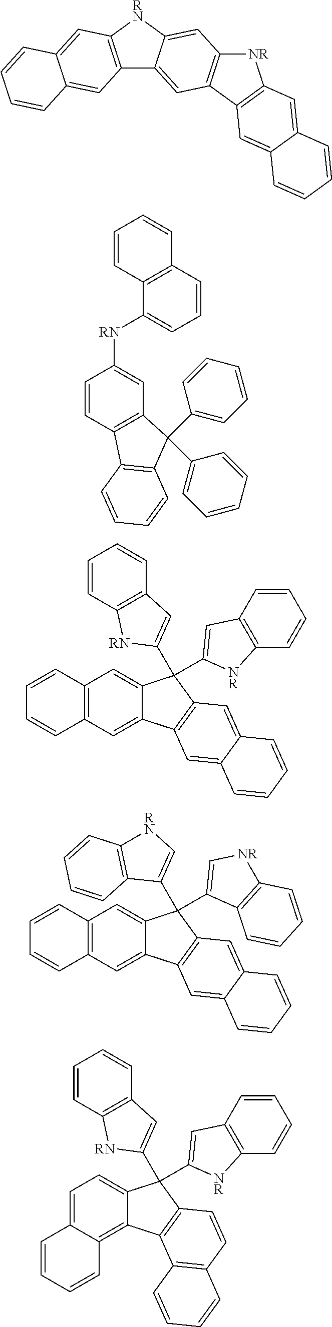

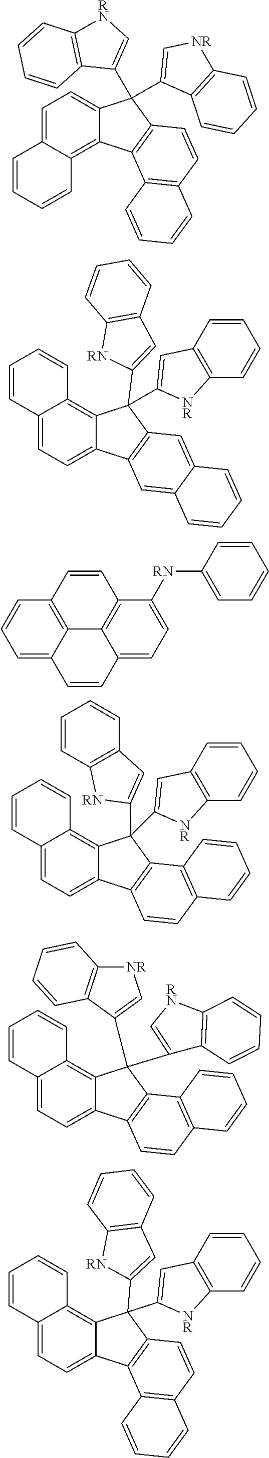

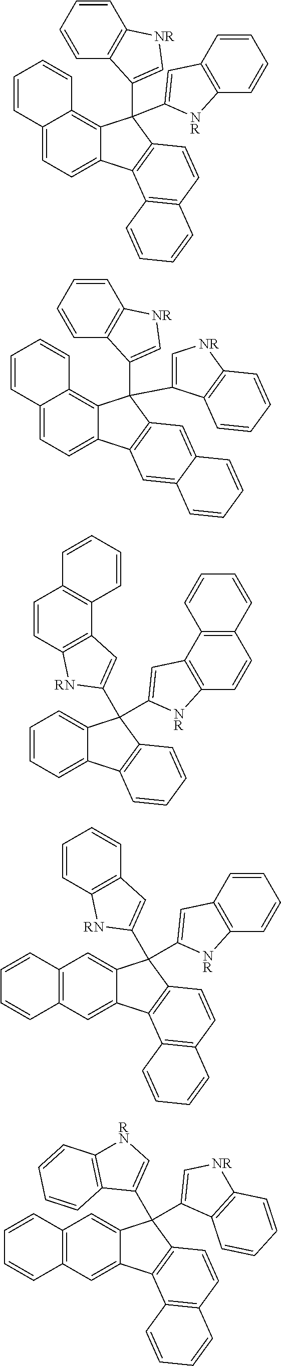

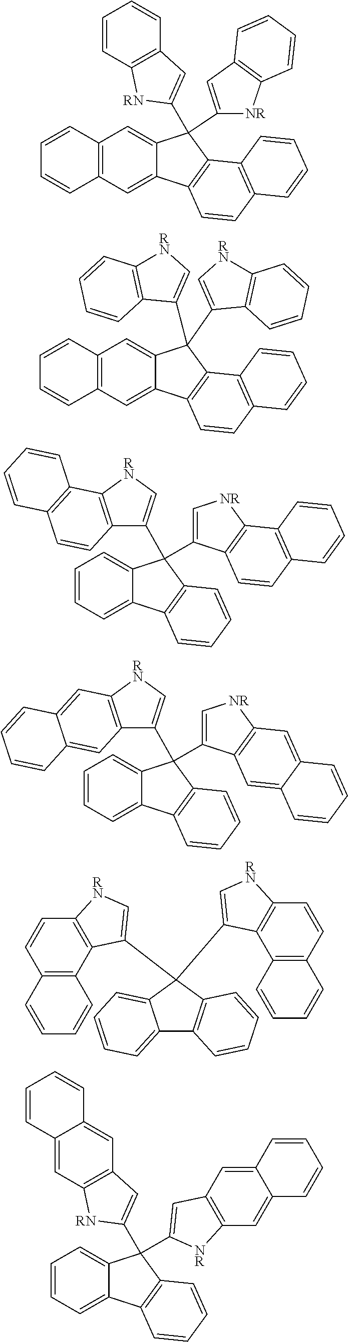

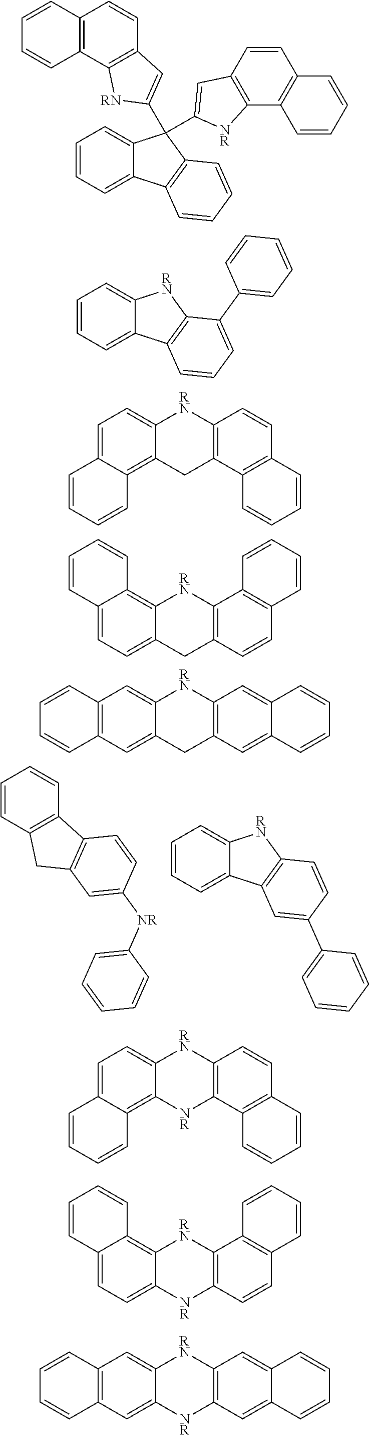

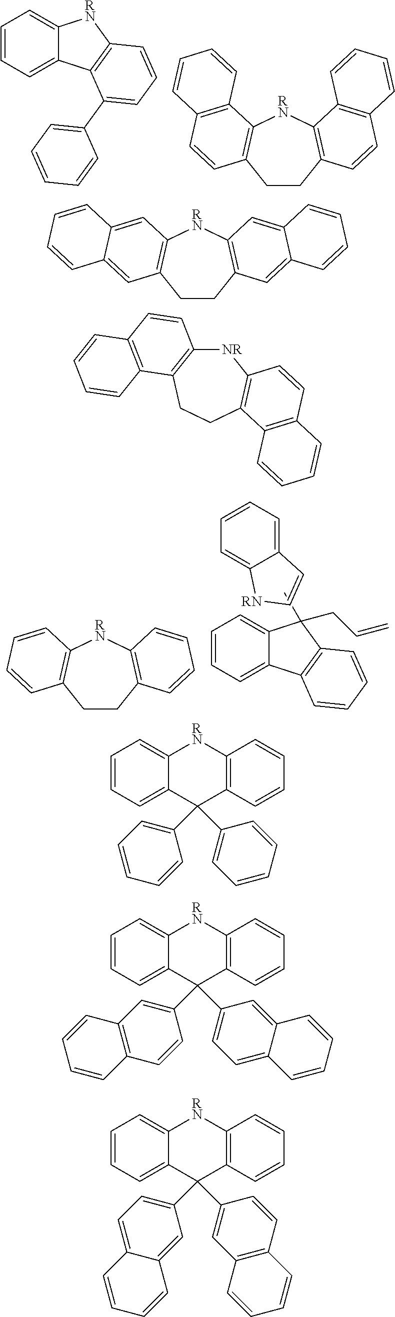

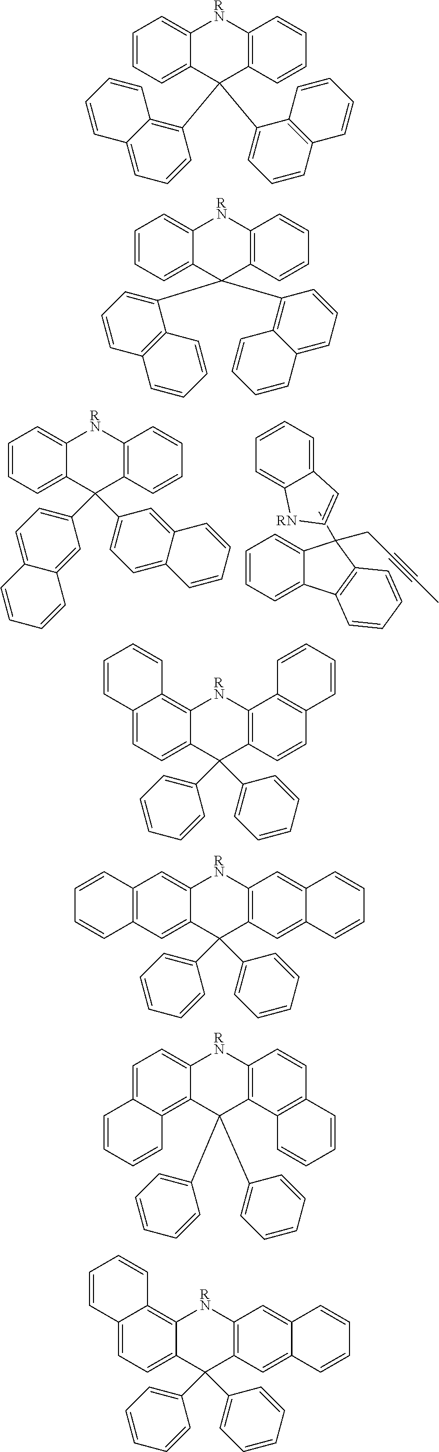

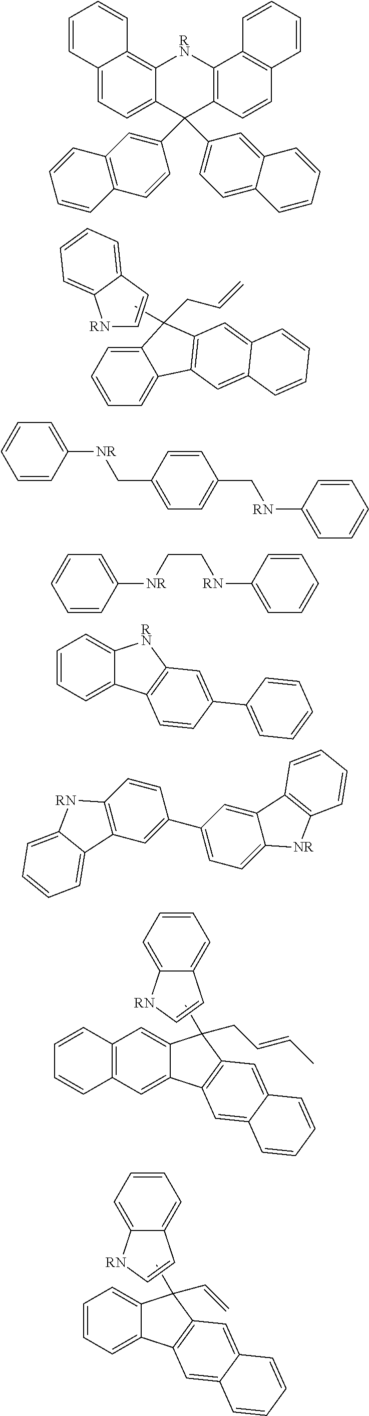

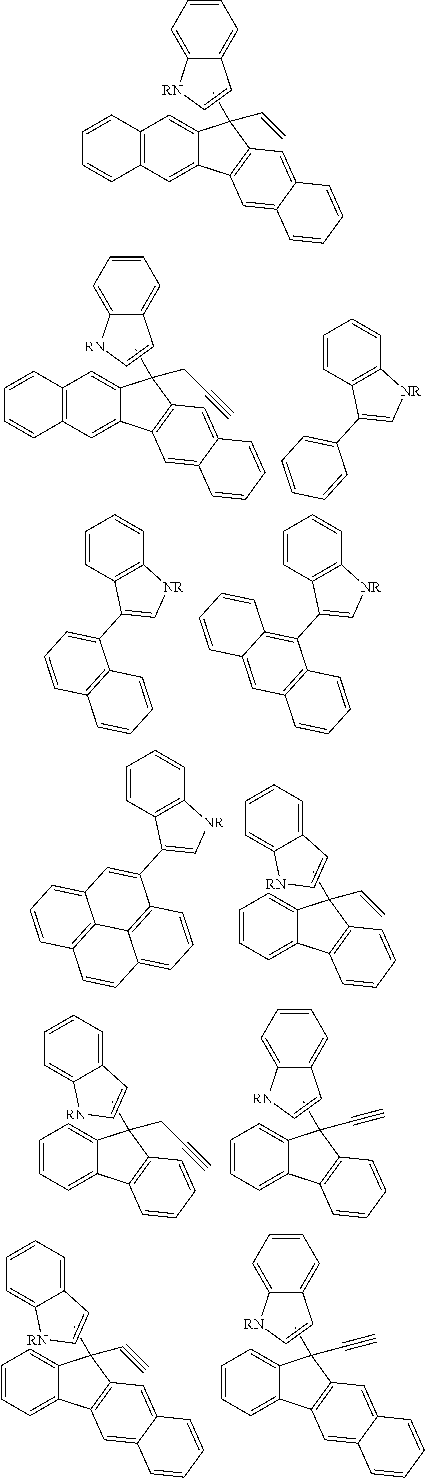

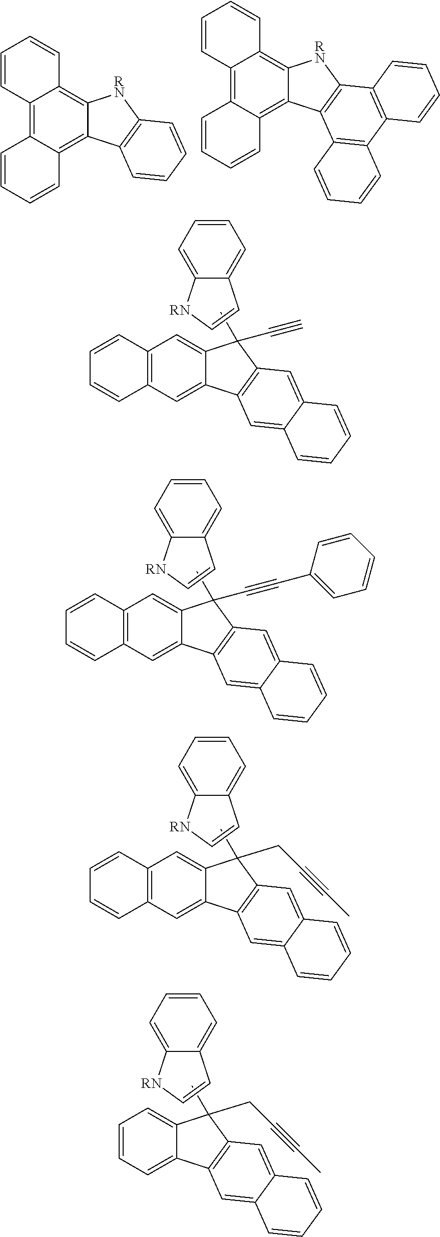

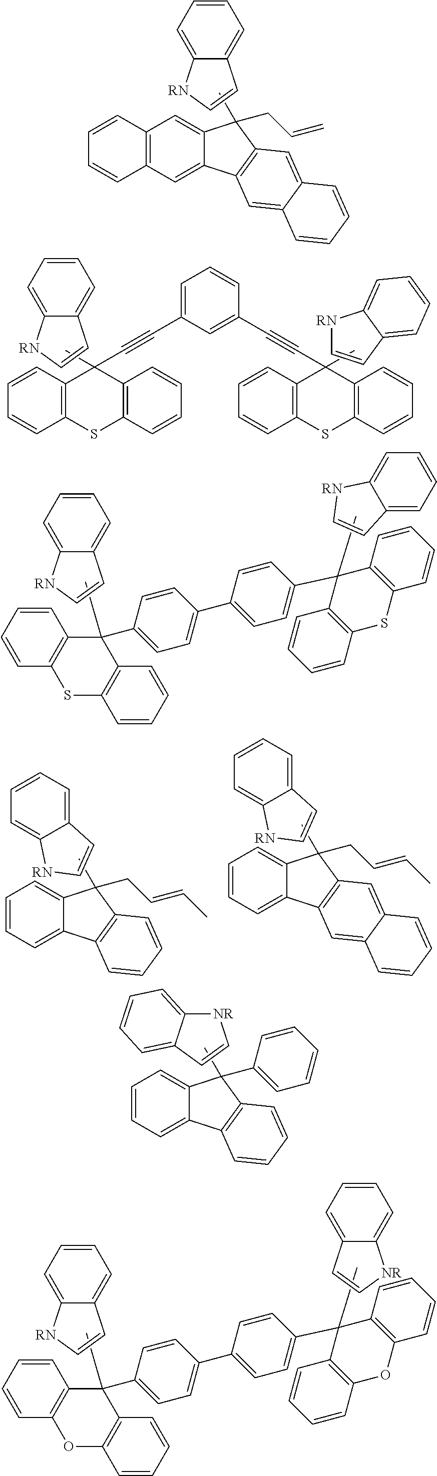

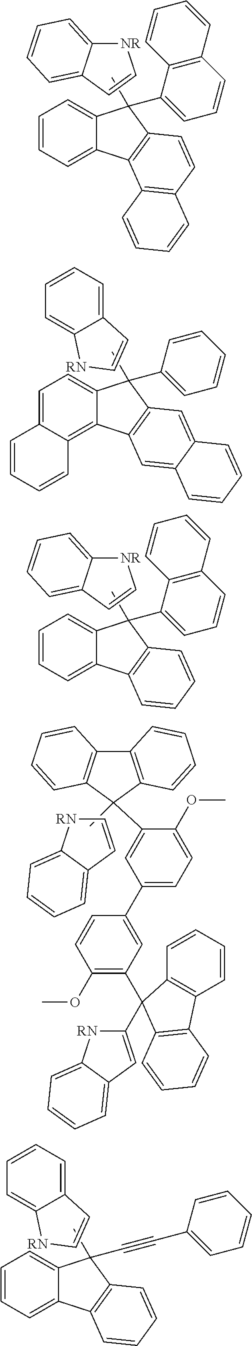

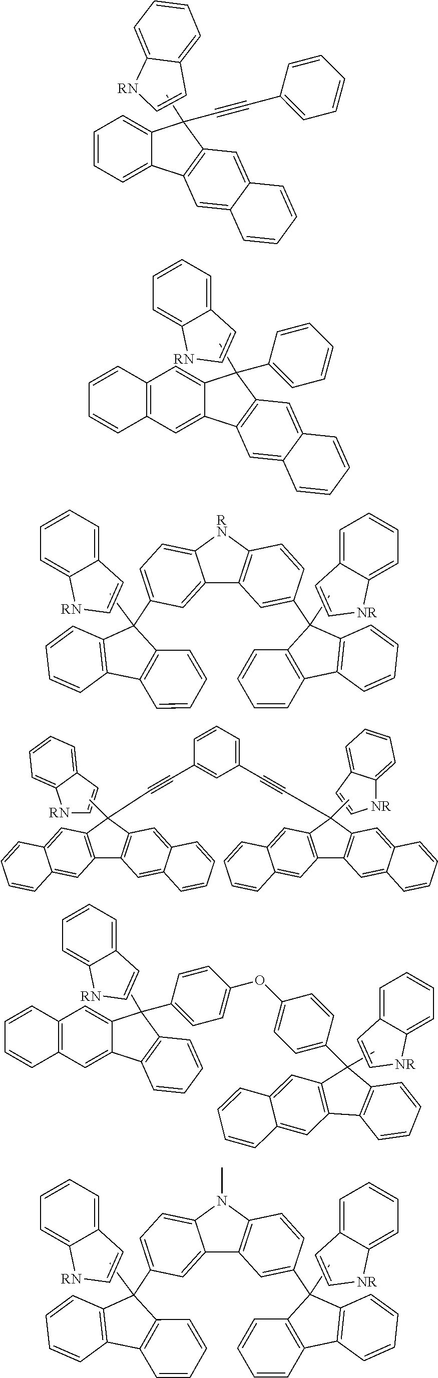

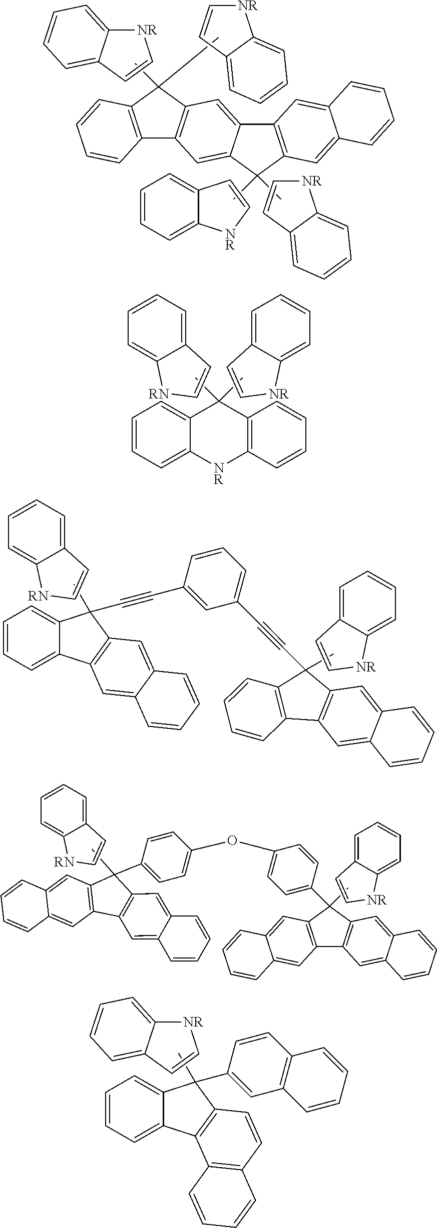

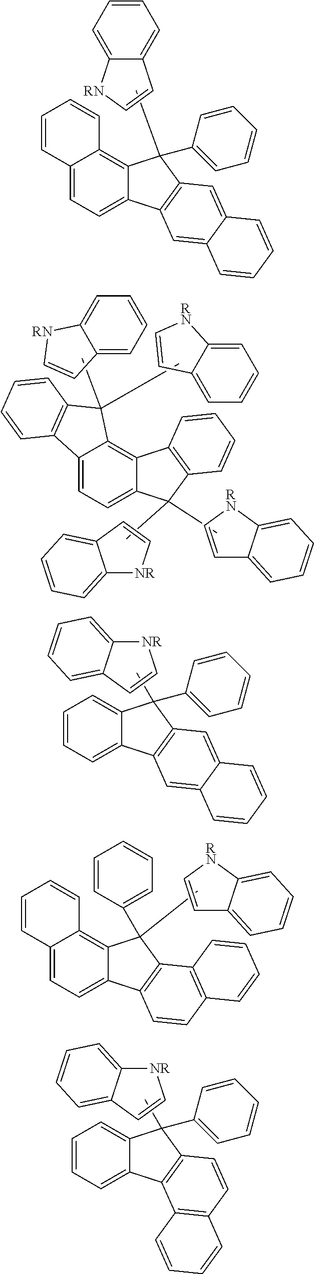

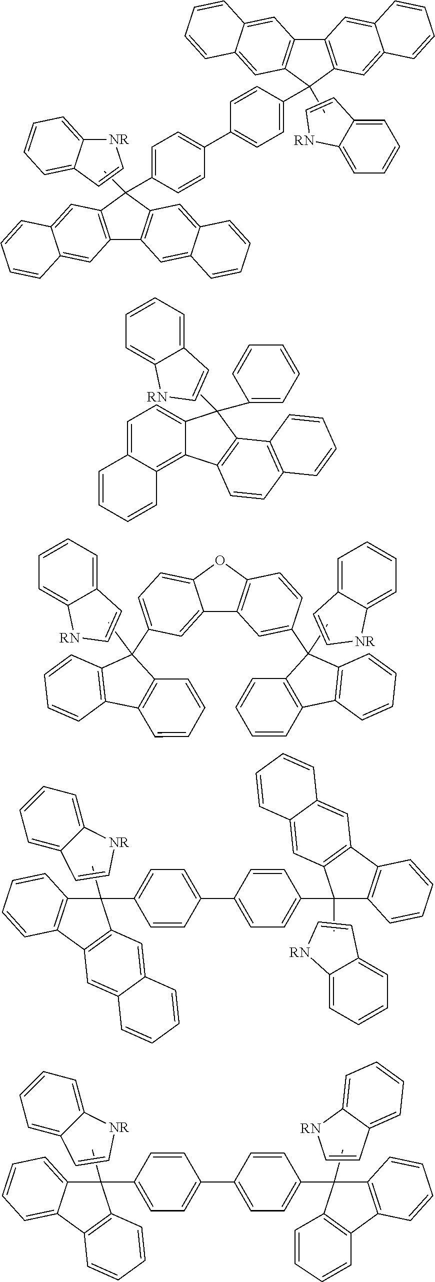

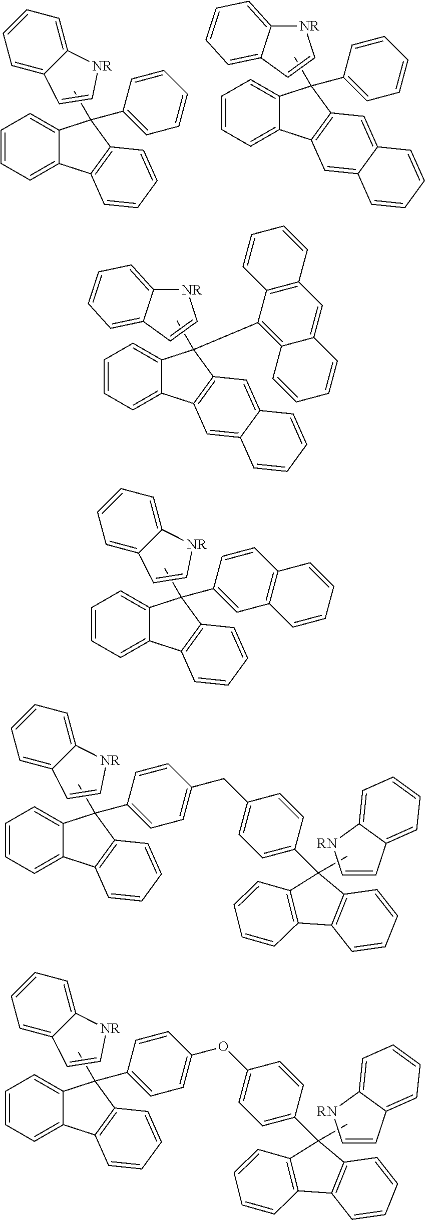

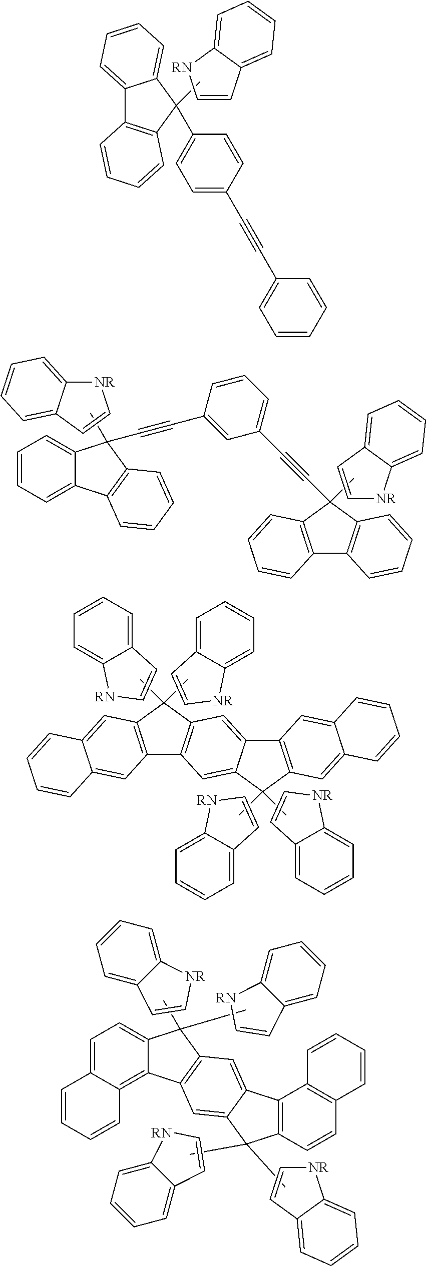

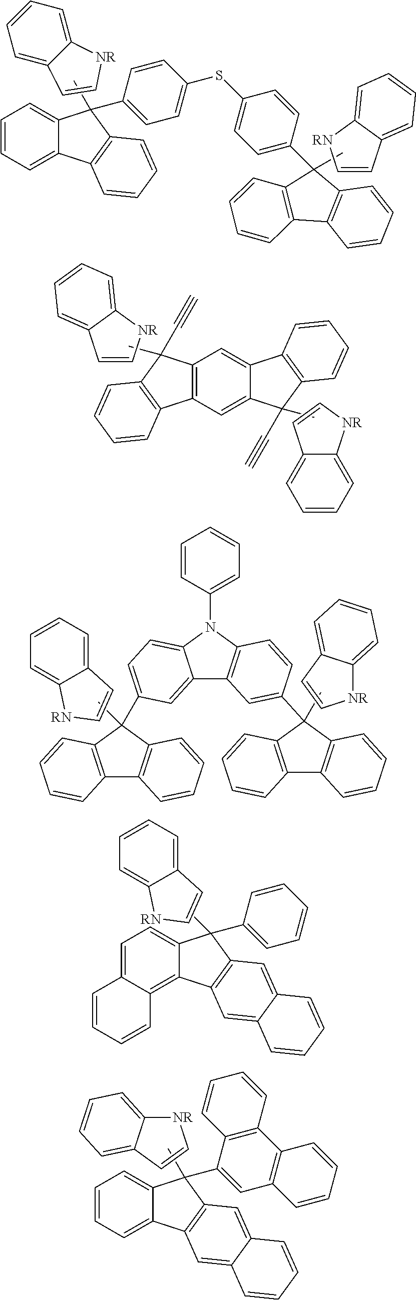

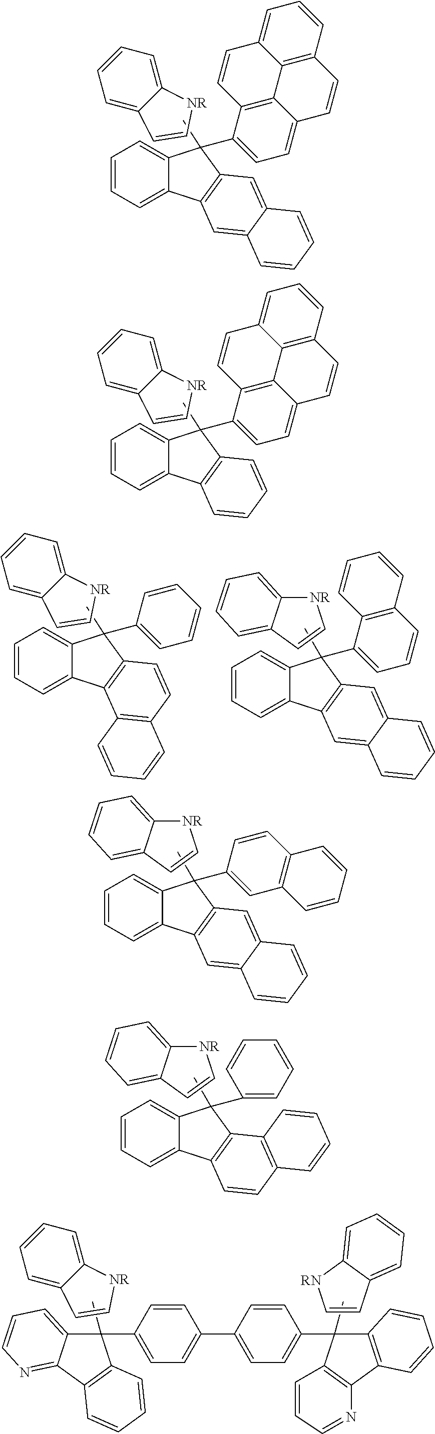

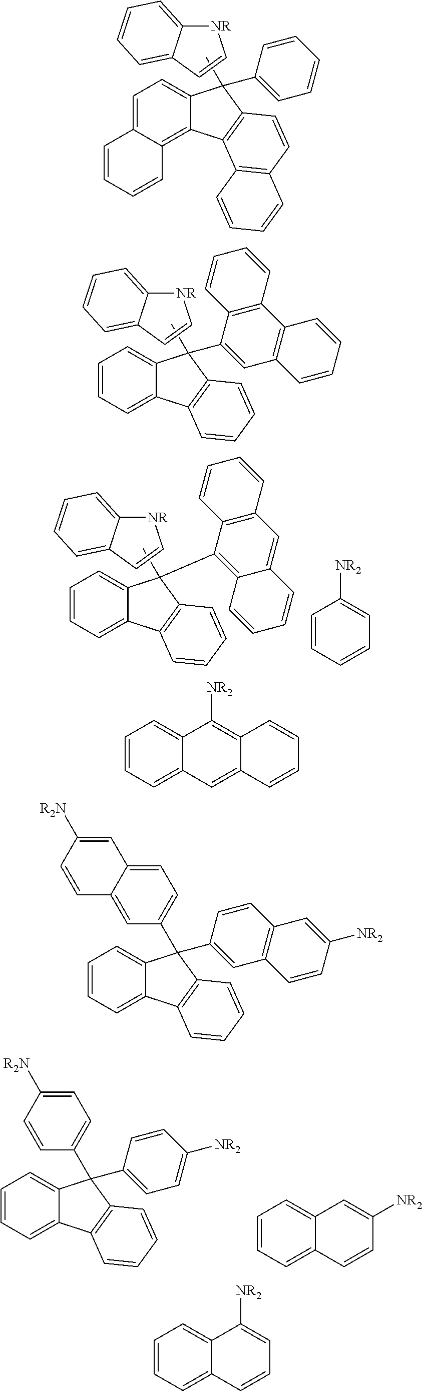

Among the skeletons illustrated above, more preferred skeletons include the following:

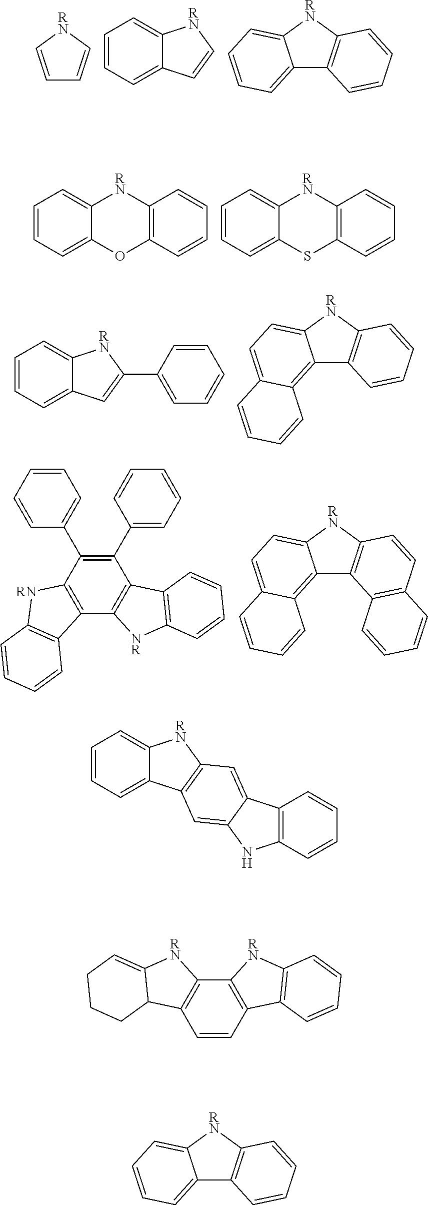

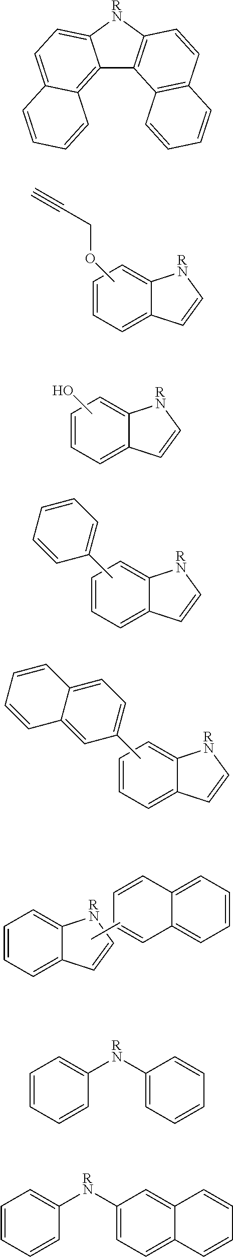

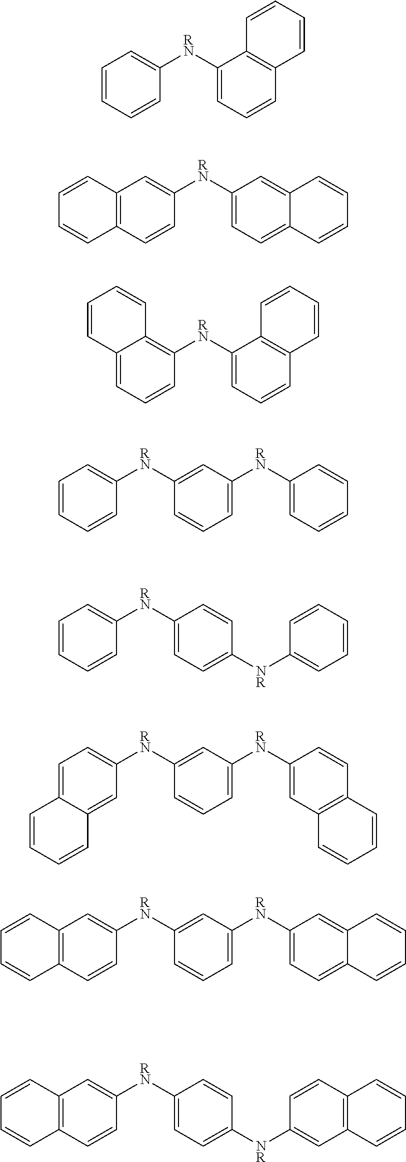

(2-3-7)

The unit structures A may optionally include unit structures that do not have an —NR— bond or an NR₂ substituent (wherein R is a hydrogen atom or an alkoxymethyl group). Examples of such unit structures include the following:

### (Examples of Amine Skeletons)

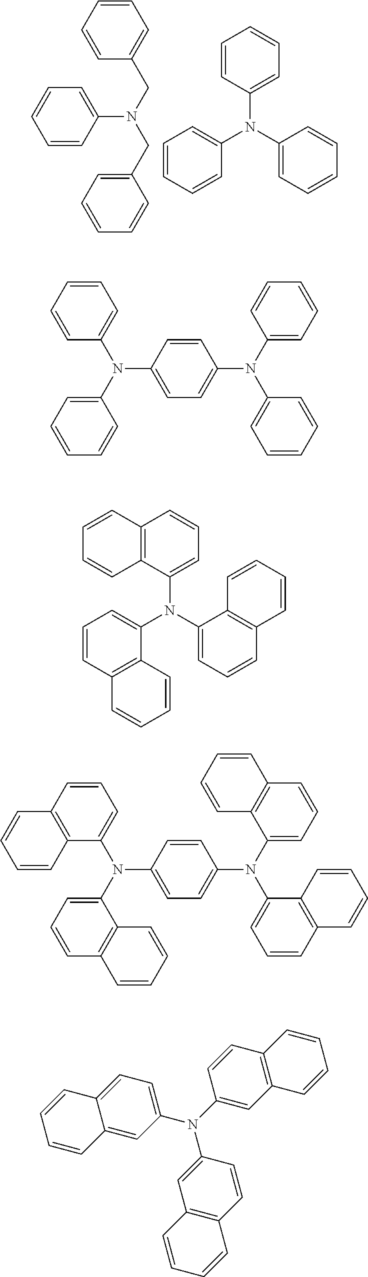

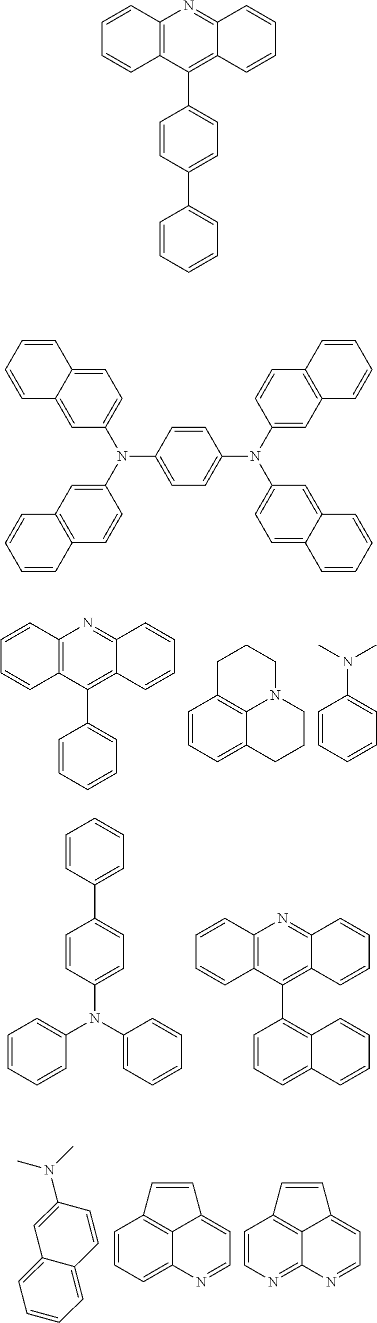

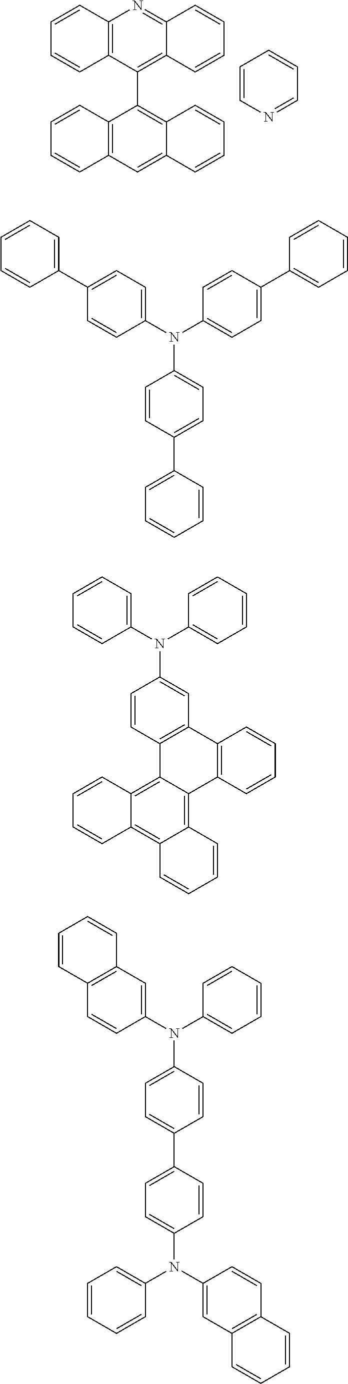

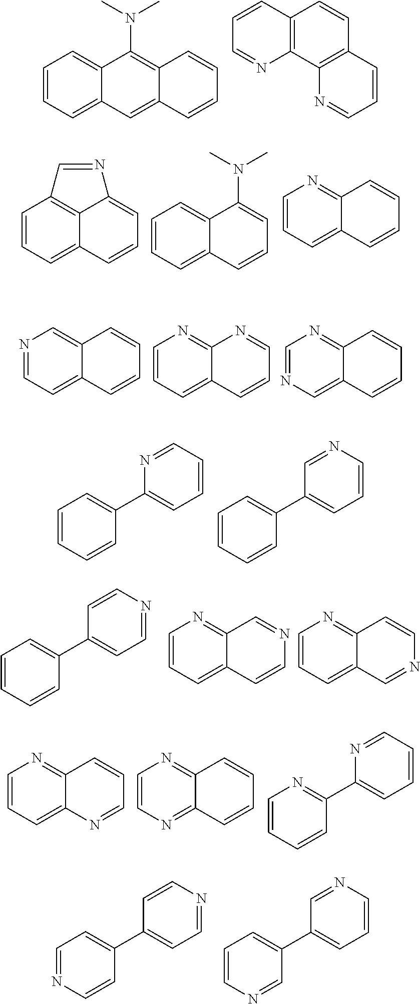

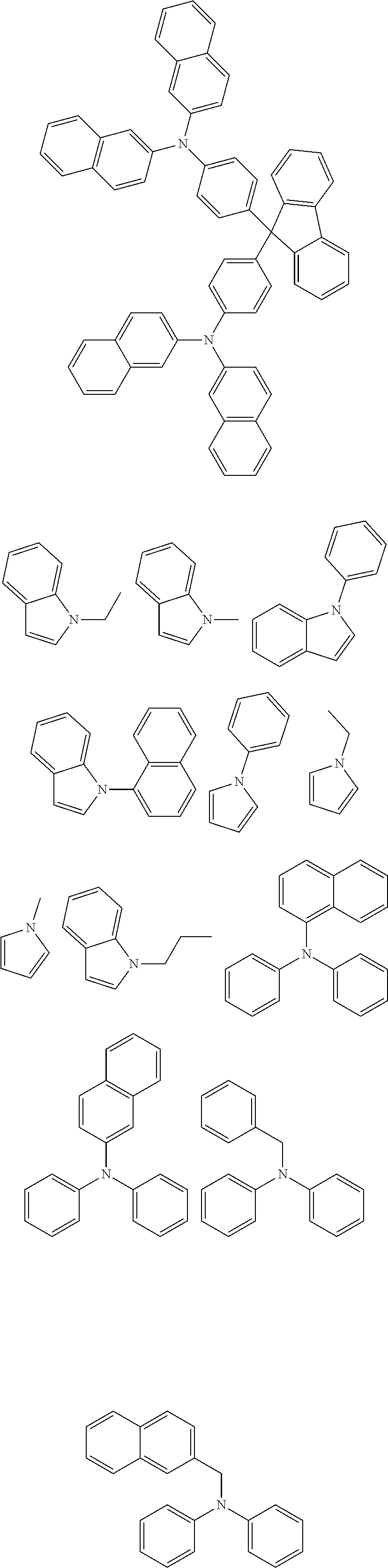

### (Examples of Phenol Skeletons)

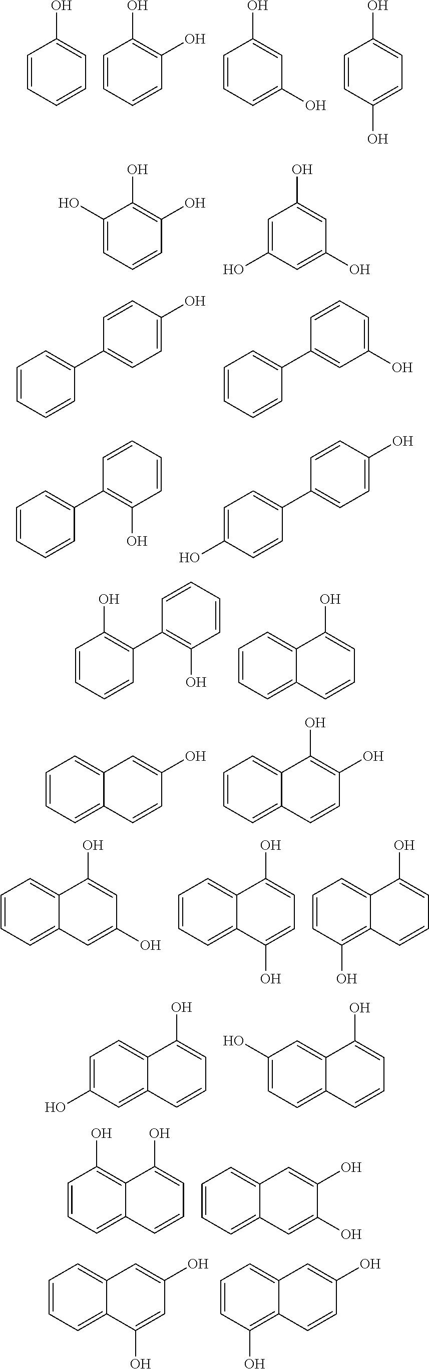

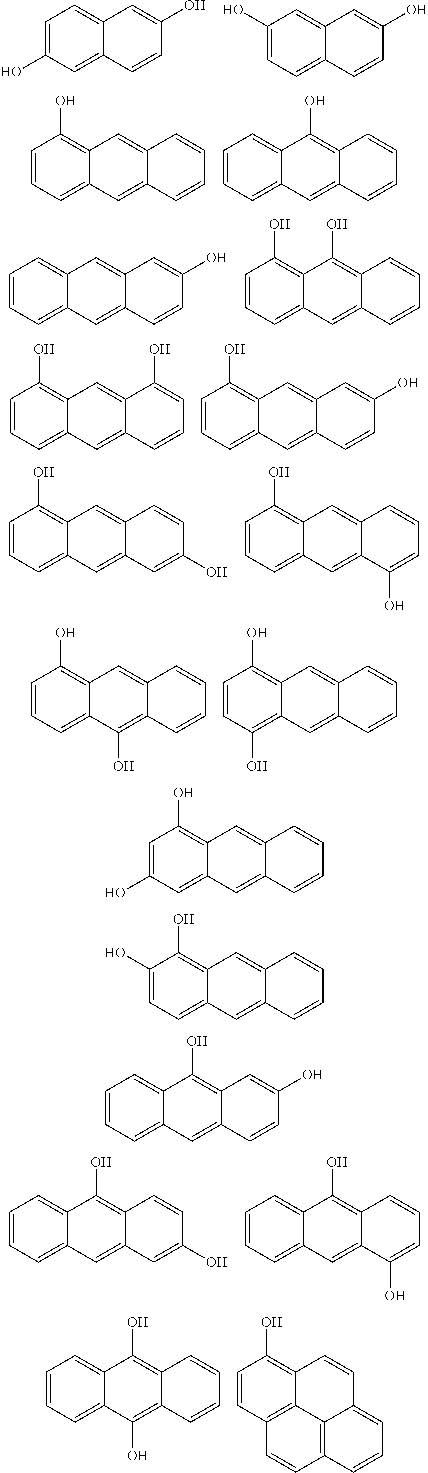

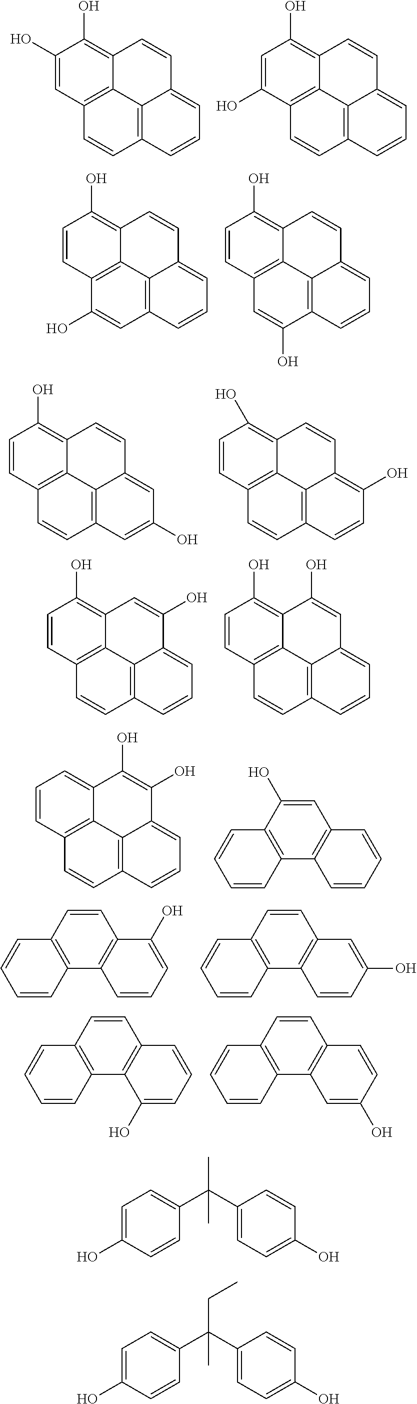

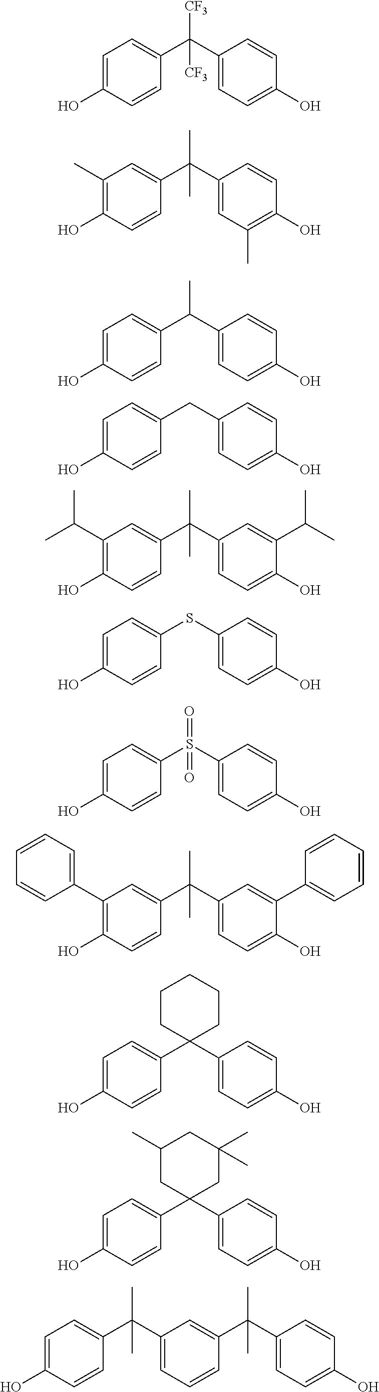

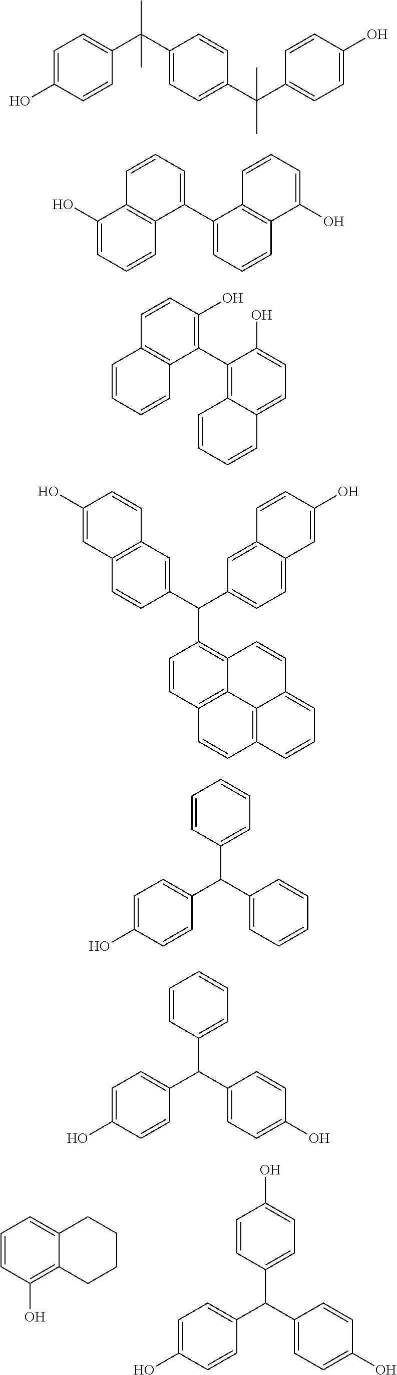

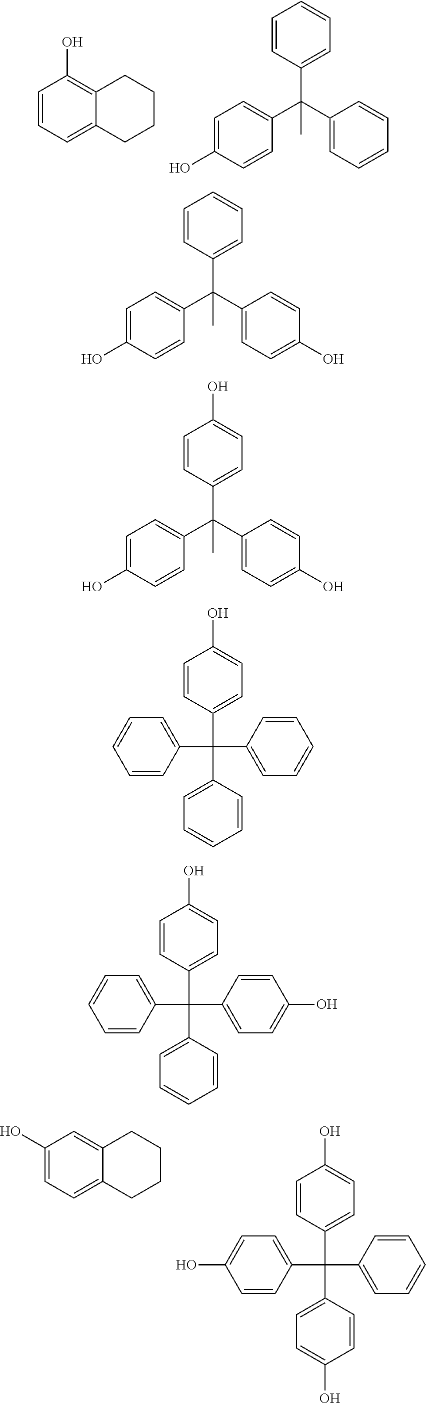

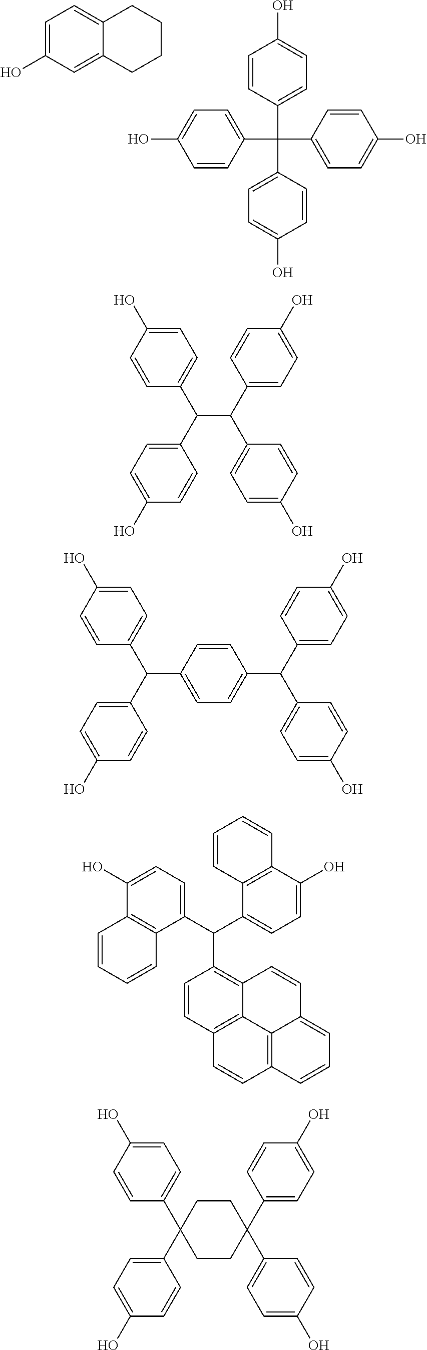

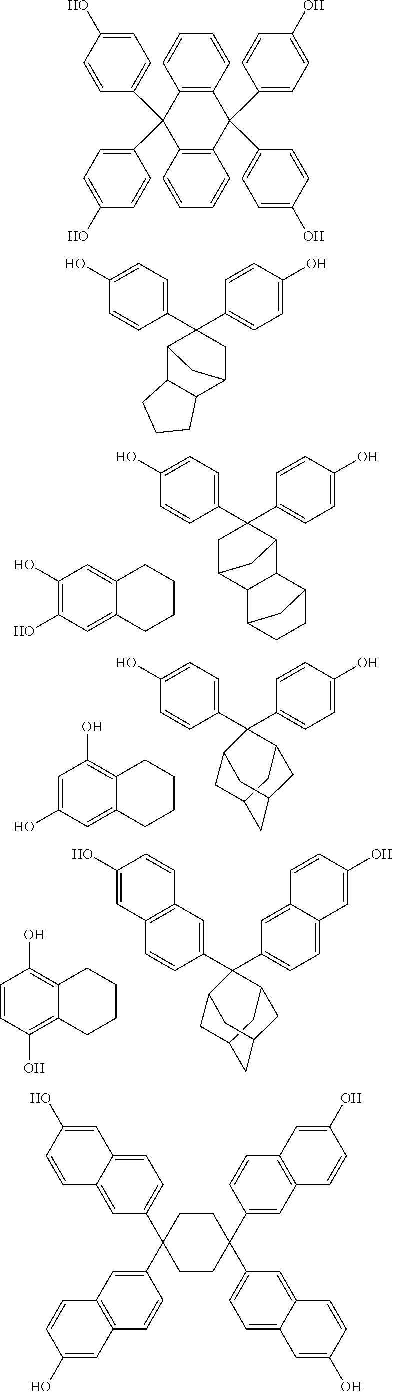

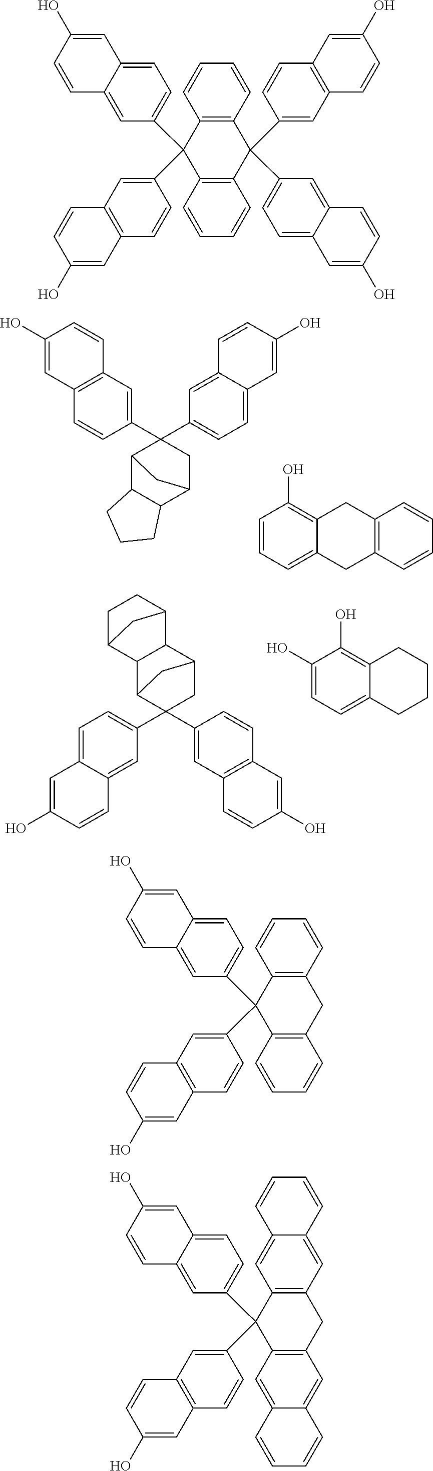

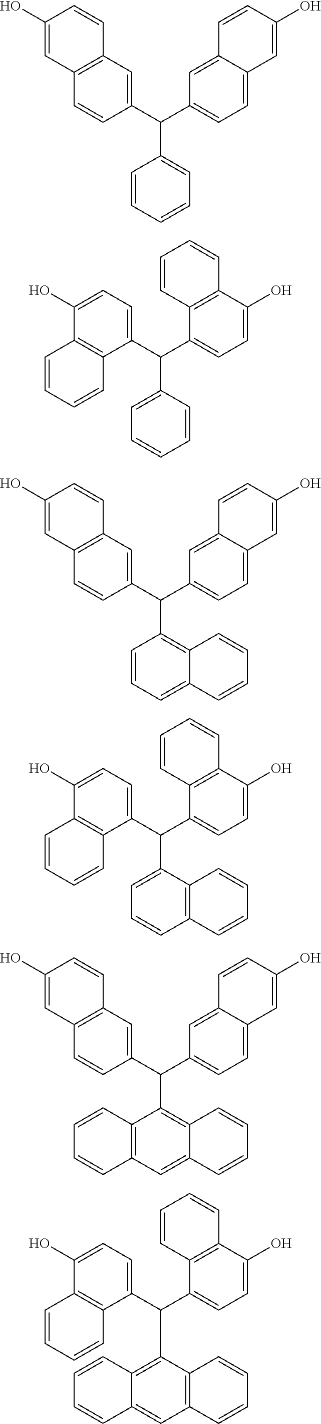

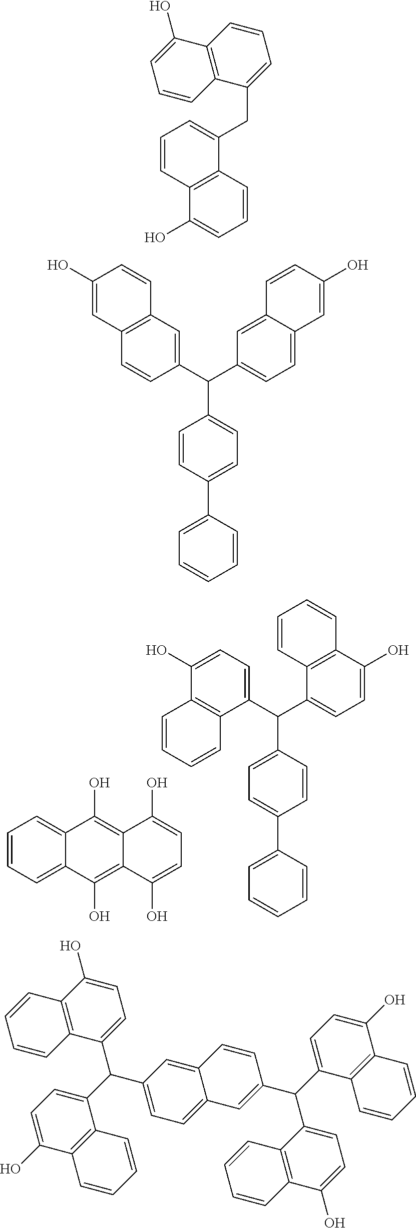

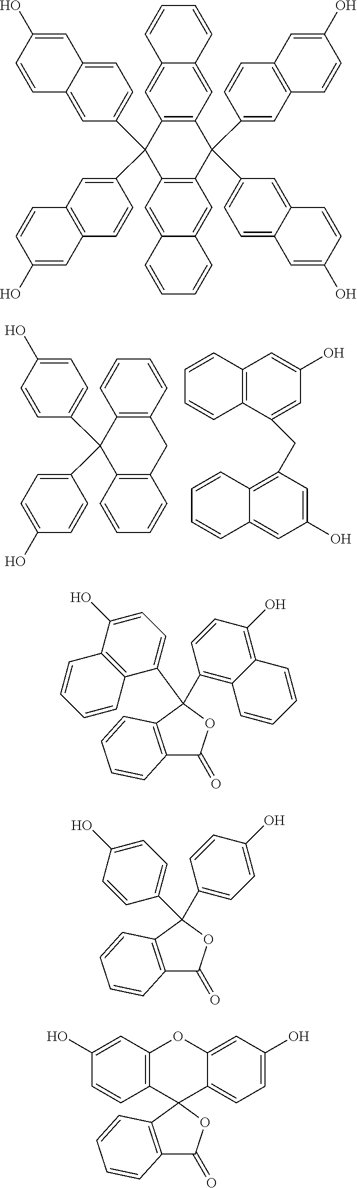

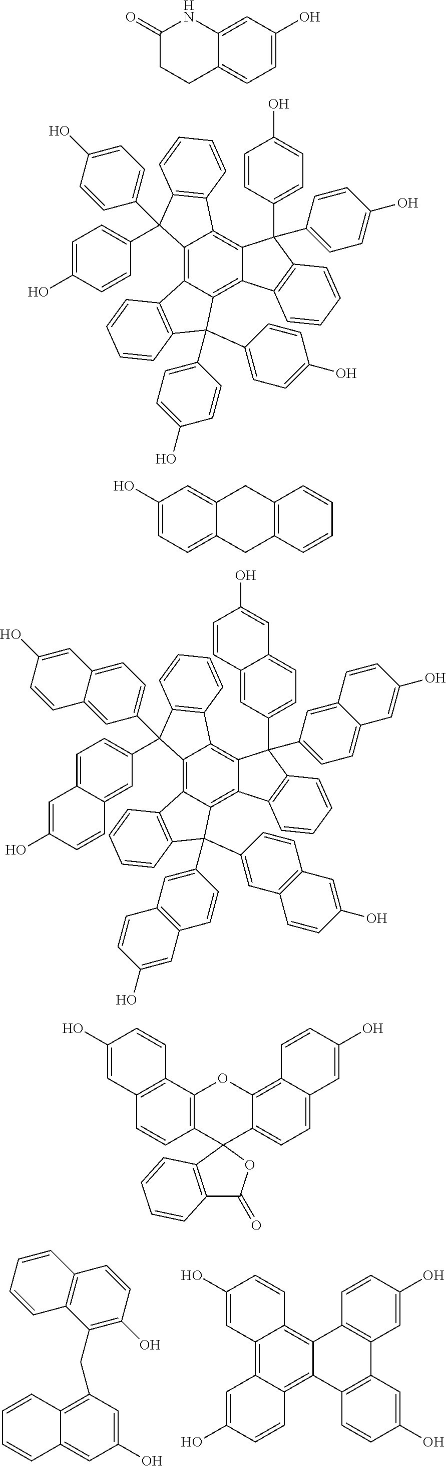

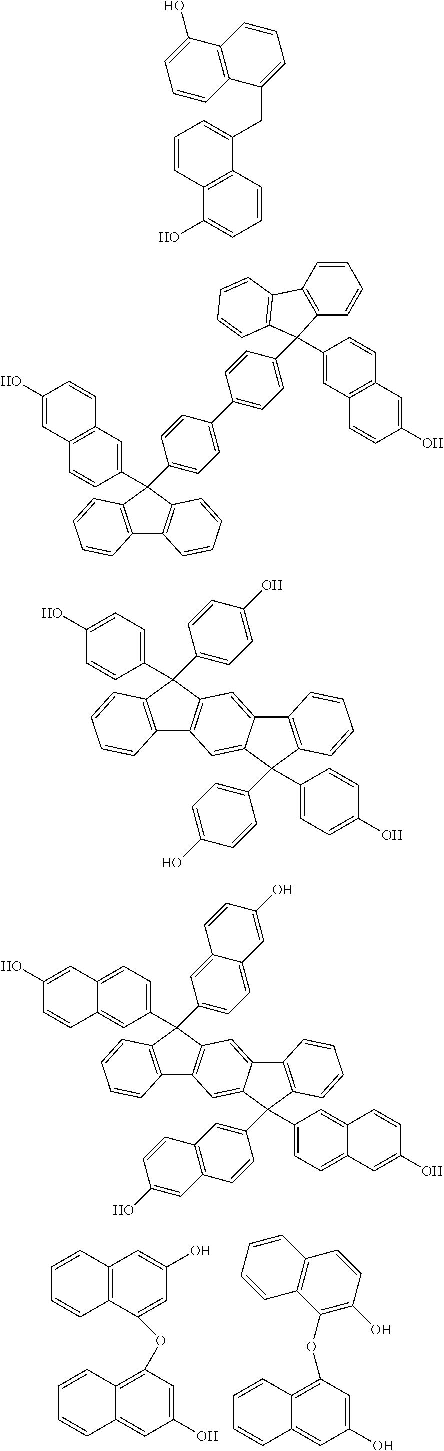

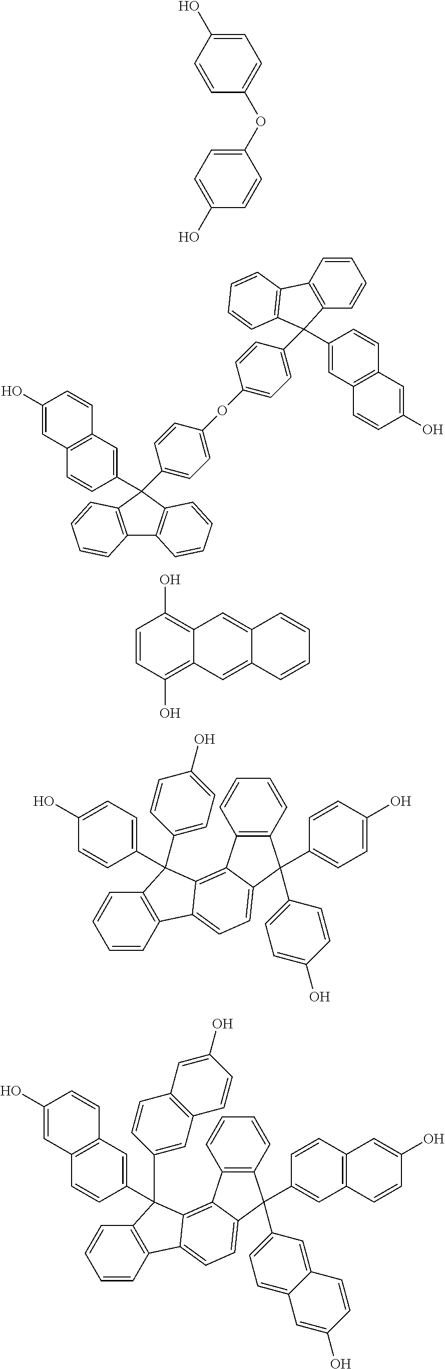

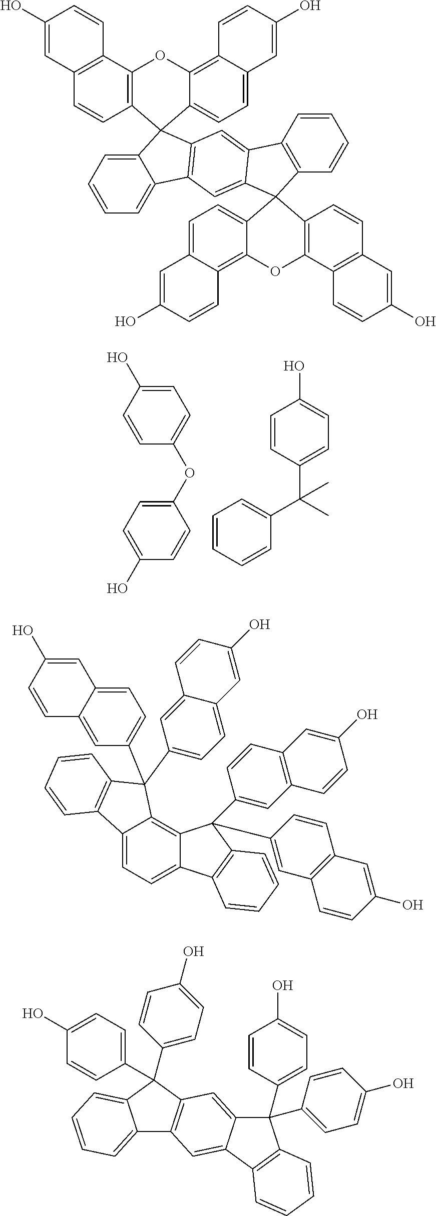

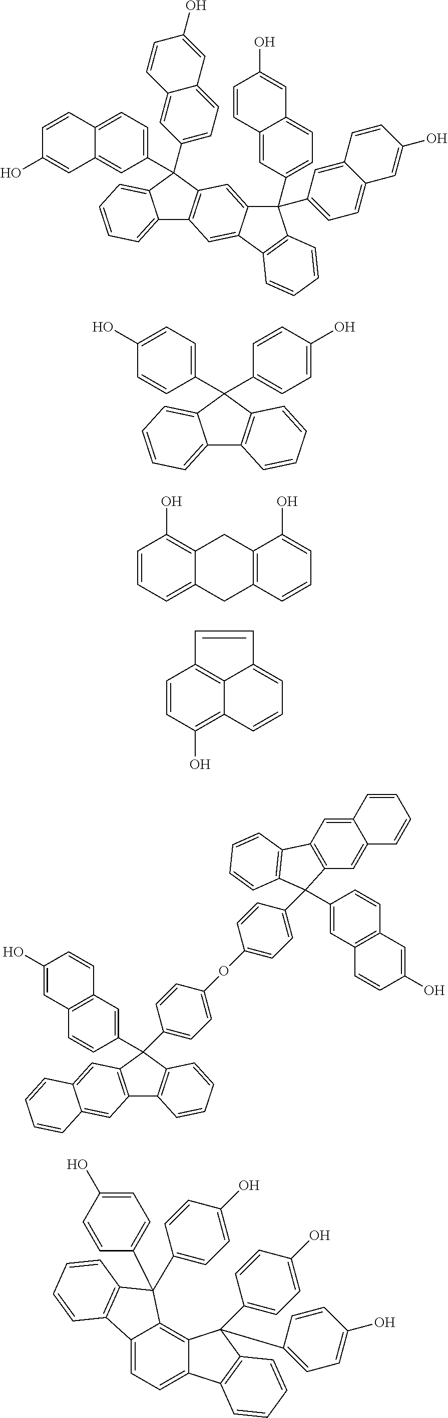

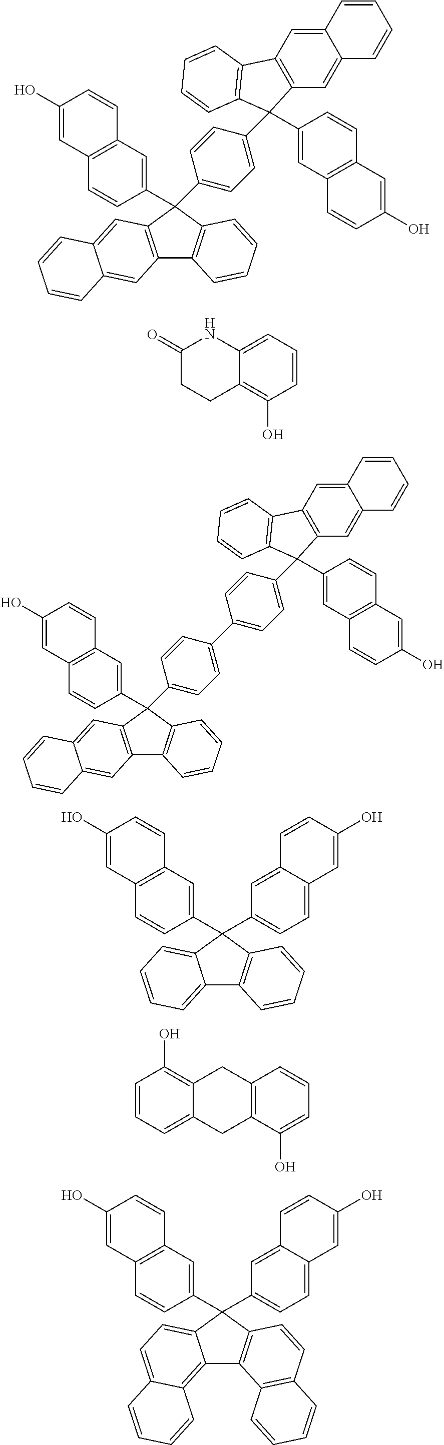

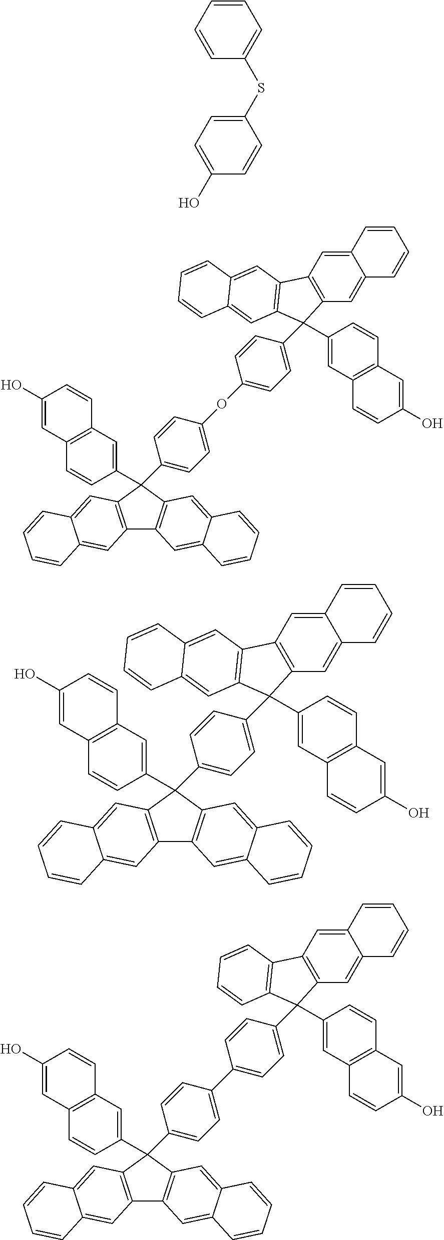 [SMILES: Oc1ccc(Sc2ccccc2)cc1 ; Oc1ccc2cc(C3(c4ccc(Oc5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc(C5(c6ccc7cc(O)ccc7c6)c6cc7ccccc7cc6-c6cc7ccccc7cc65)cc4)c4cc5ccccc5cc4-c4cc5ccccc5cc43)ccc2c1 ; Oc1ccc2cc(C3(c4ccc(-c5ccc(C6(c7ccc8cc(O)ccc8c7)c7cc8ccccc8cc7-c7cc8ccccc8cc76)cc5)cc4)c4ccccc4-c4cc5ccccc5cc43)ccc2c1]

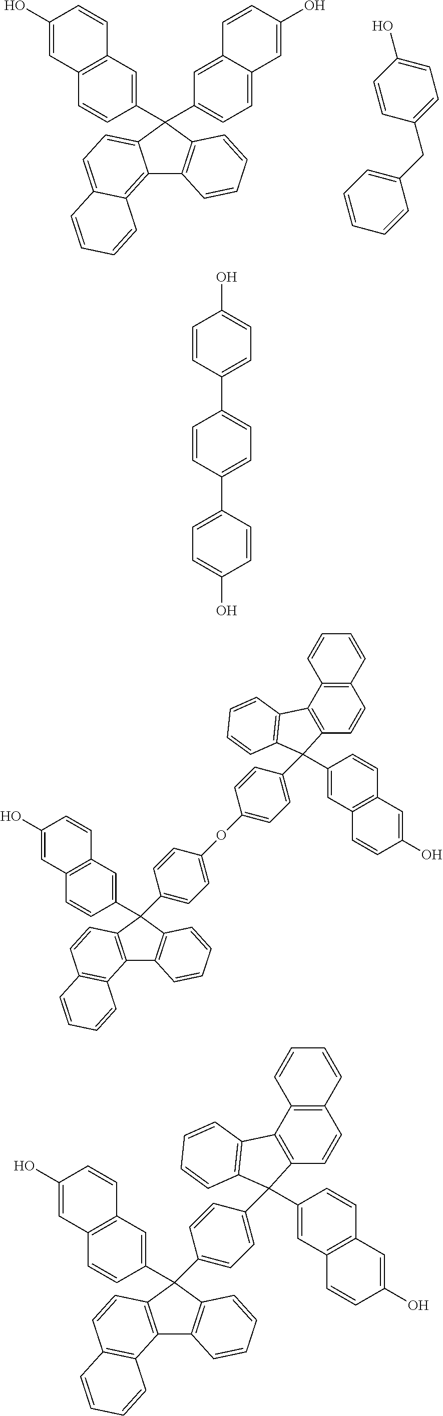 [SMILES: Oc1ccc2cc(C3(c4ccc5cc(O)ccc5c4)c4ccccc4-c4c3ccc3ccccc43)ccc2c1 ; Oc1ccc(Cc2ccccc2)cc1 ; Oc1ccc(-c2ccc(-c3ccc(O)cc3)cc2)cc1 ; Oc1ccc2cc(C3(c4ccc(Oc5ccc(C6(c7ccc8cc(O)ccc8c7)c7ccccc7-c7c6ccc6ccccc76)cc5)cc4)c4ccccc4-c4c3ccc3ccccc43)ccc2c1 ; Oc1ccc2cc(C3(c4ccc(C5(c6ccc7cc(O)ccc7c6)c6ccccc6-c6c5ccc5ccccc65)cc4)c4ccccc4-c4c3ccc3ccccc43)ccc2c1]

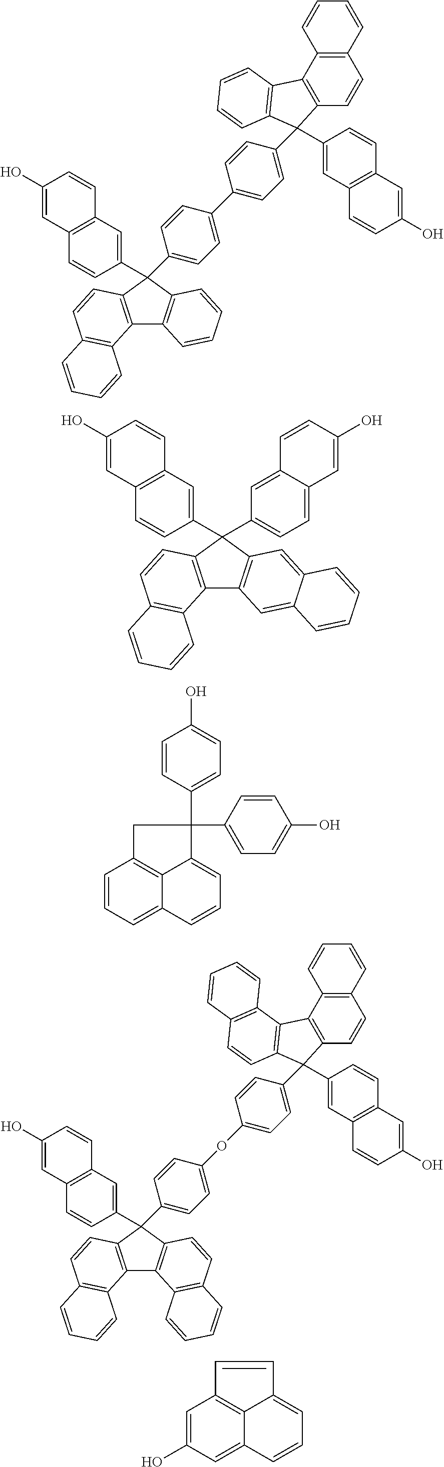

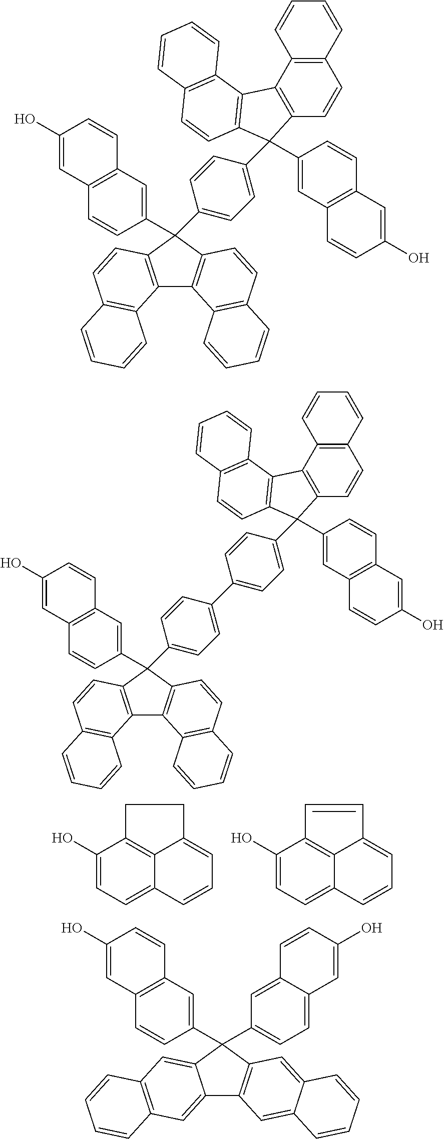

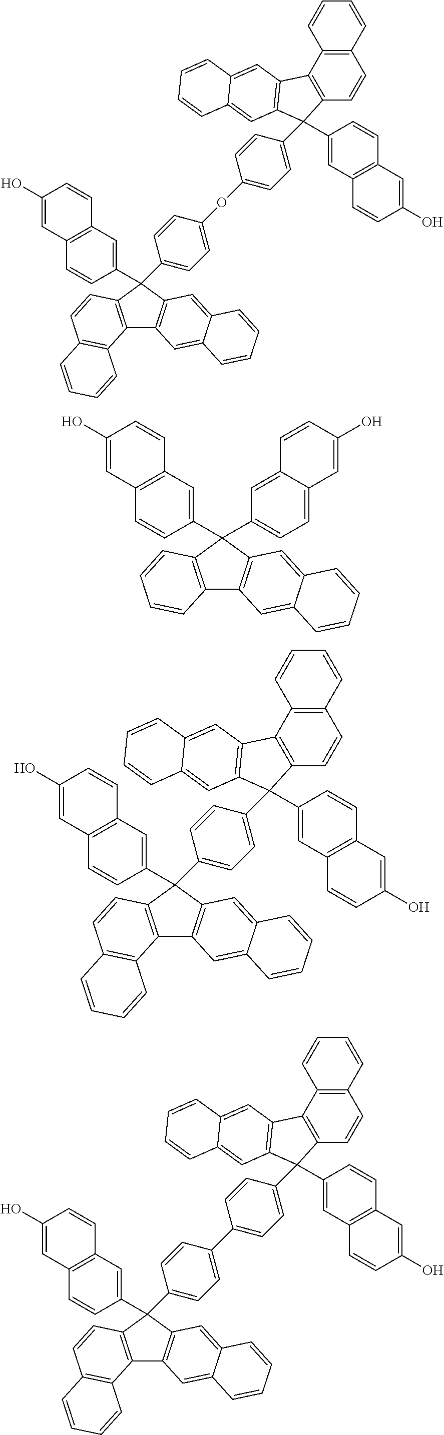

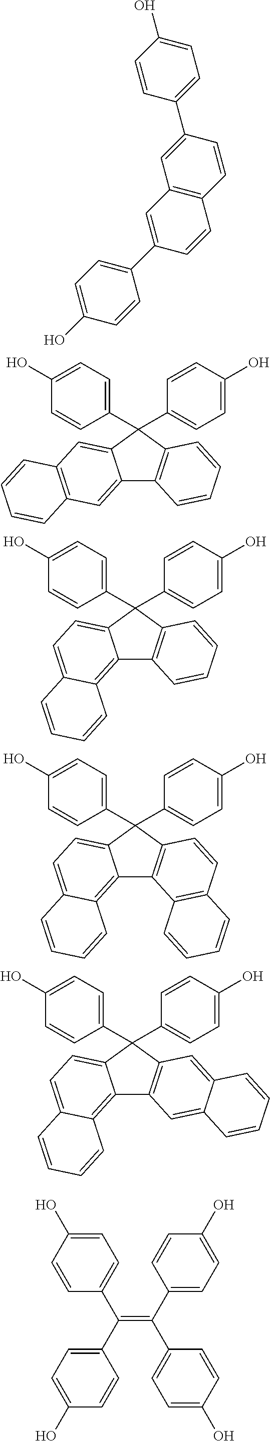

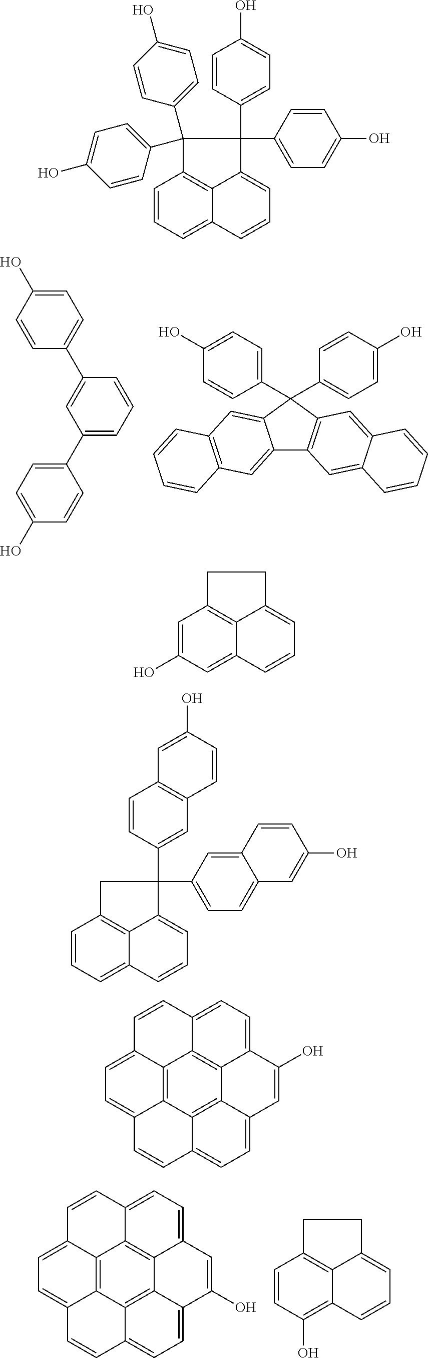

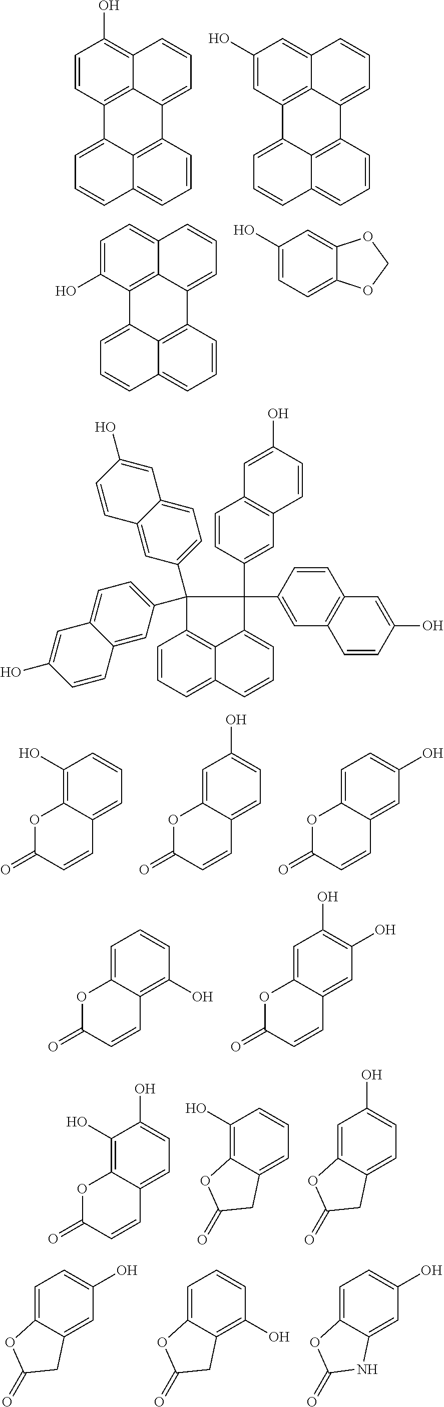

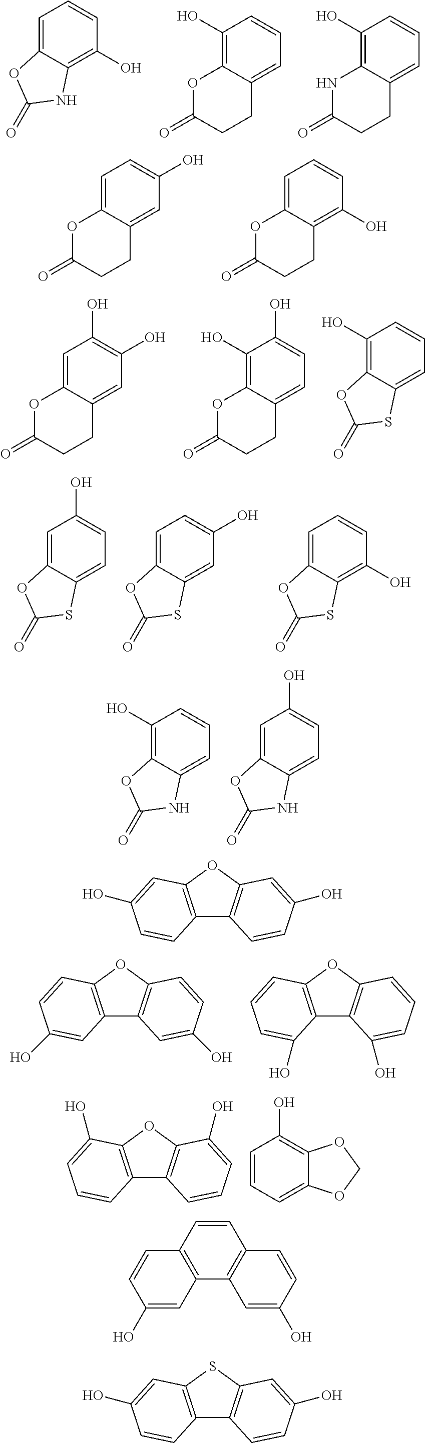

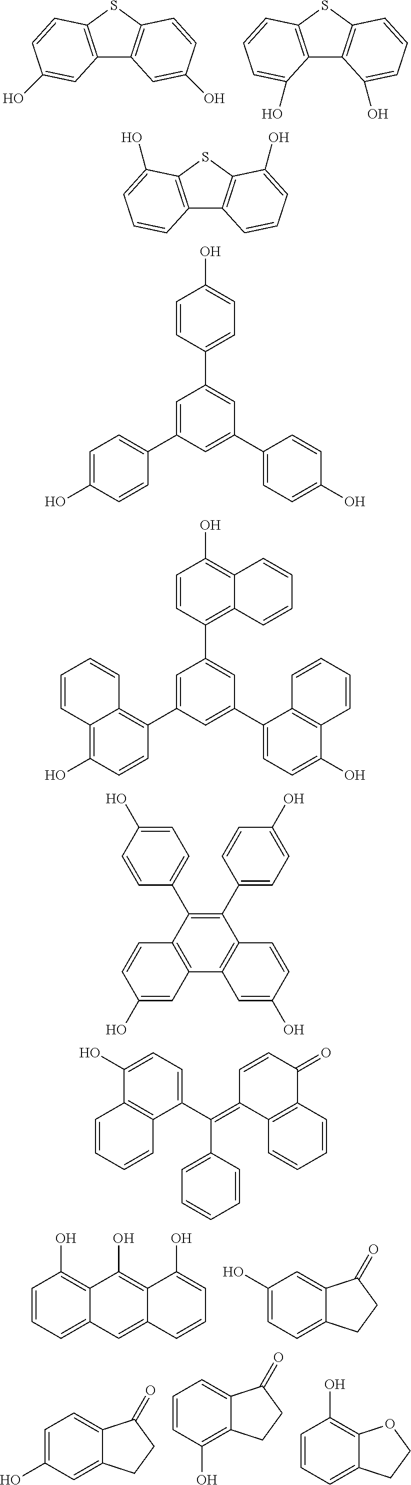

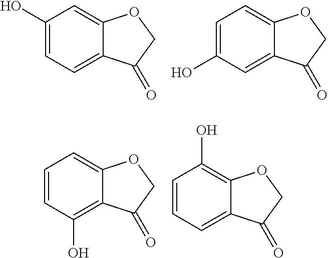

In particular, the unit structures A other than the unit structures A having an —NR— bond or an NR₂ substituent are preferably unit structures A having a phenol skeleton. Examples of such unit structures are illustrated below.

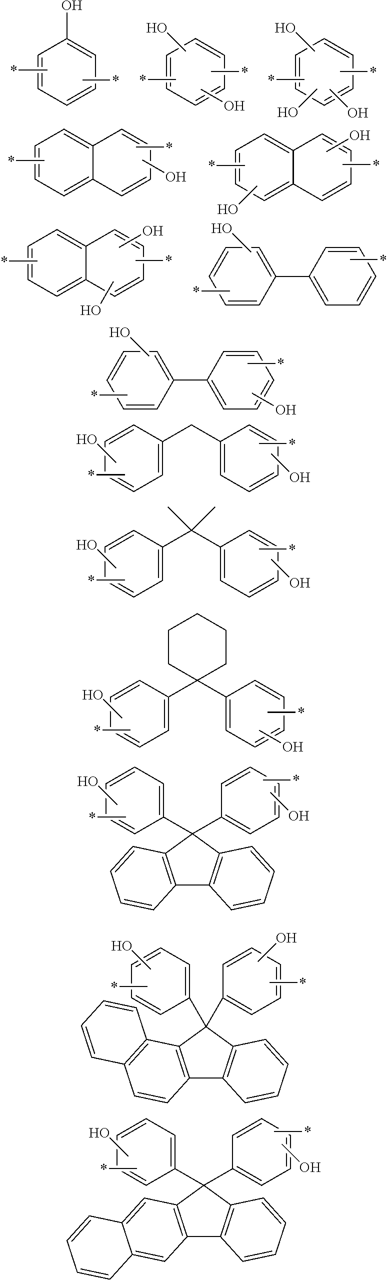

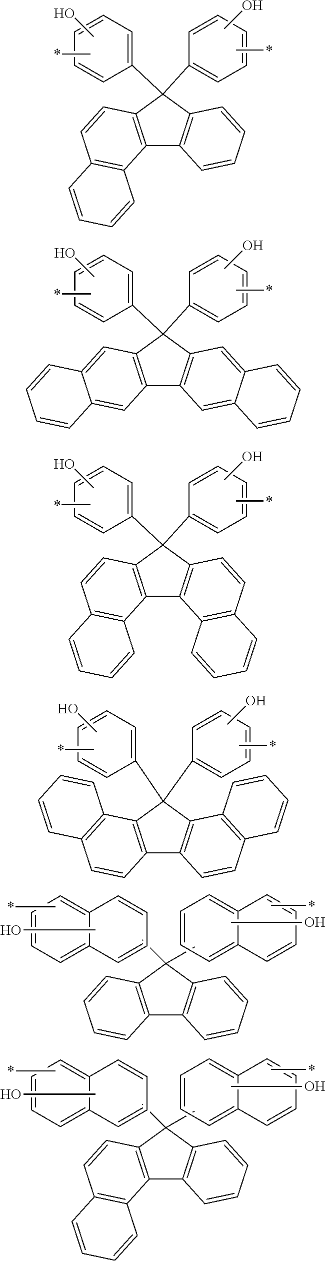

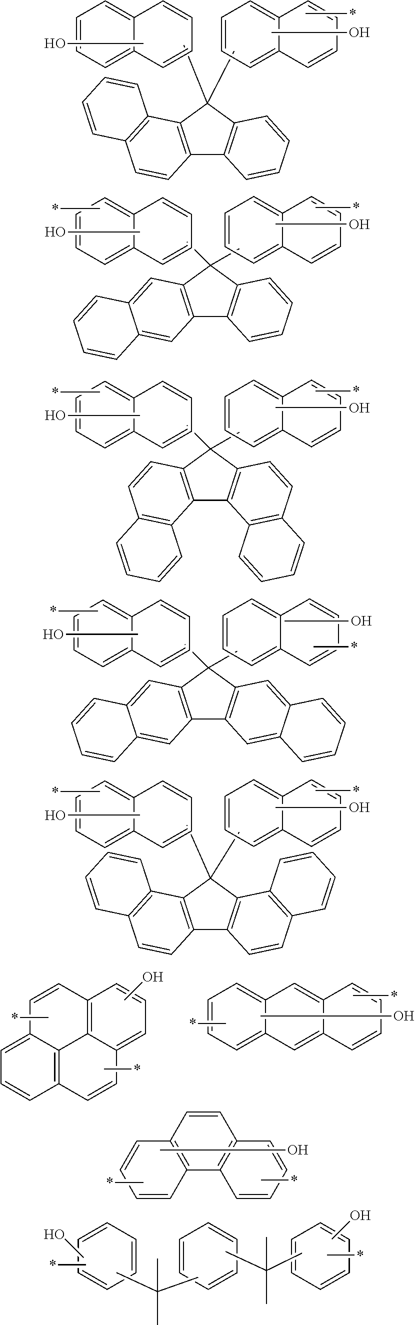

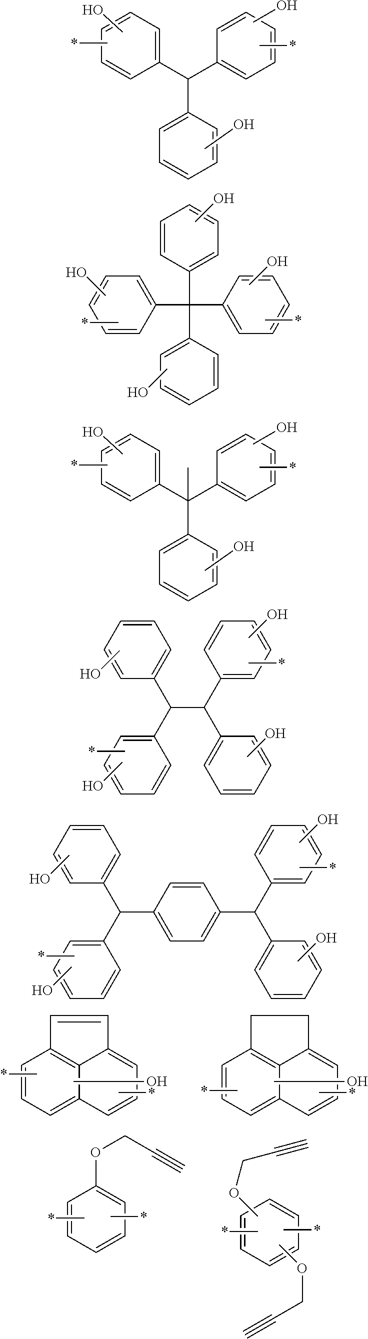

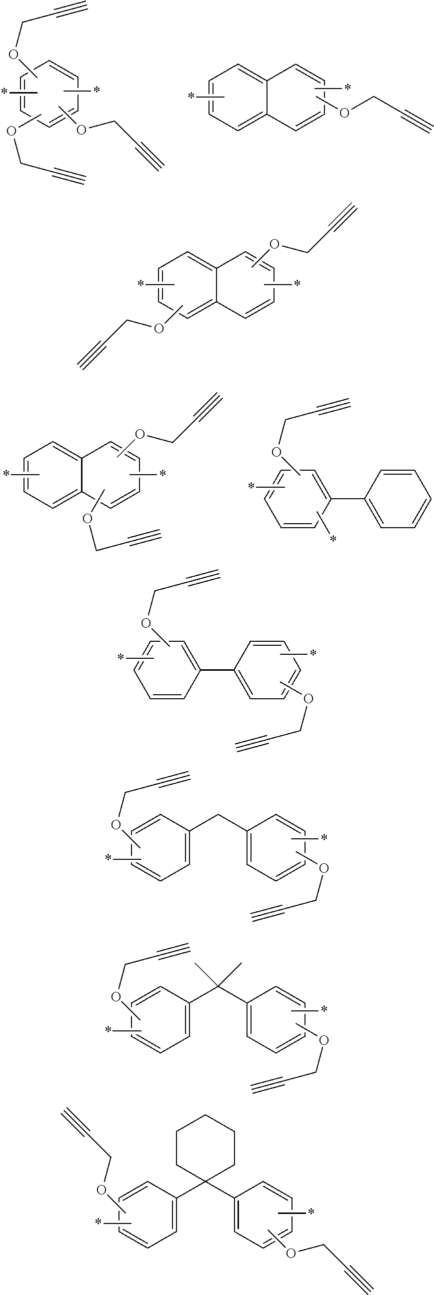

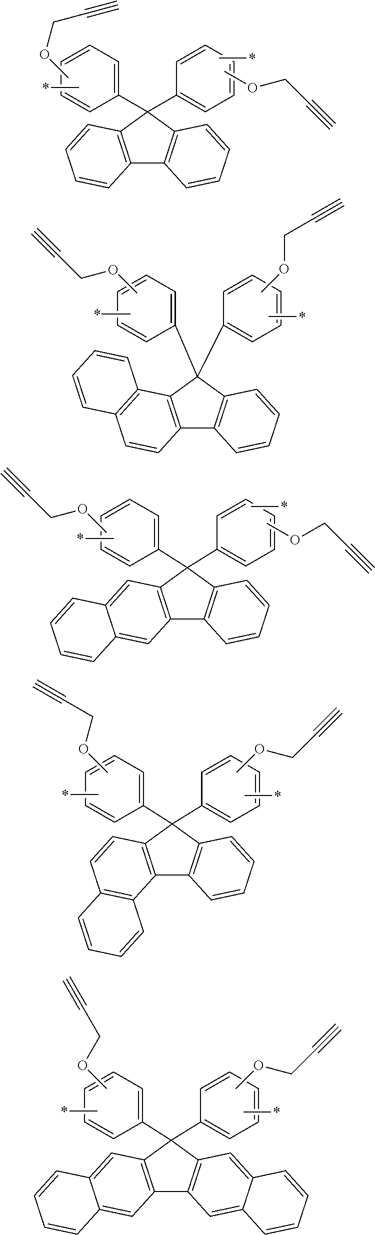

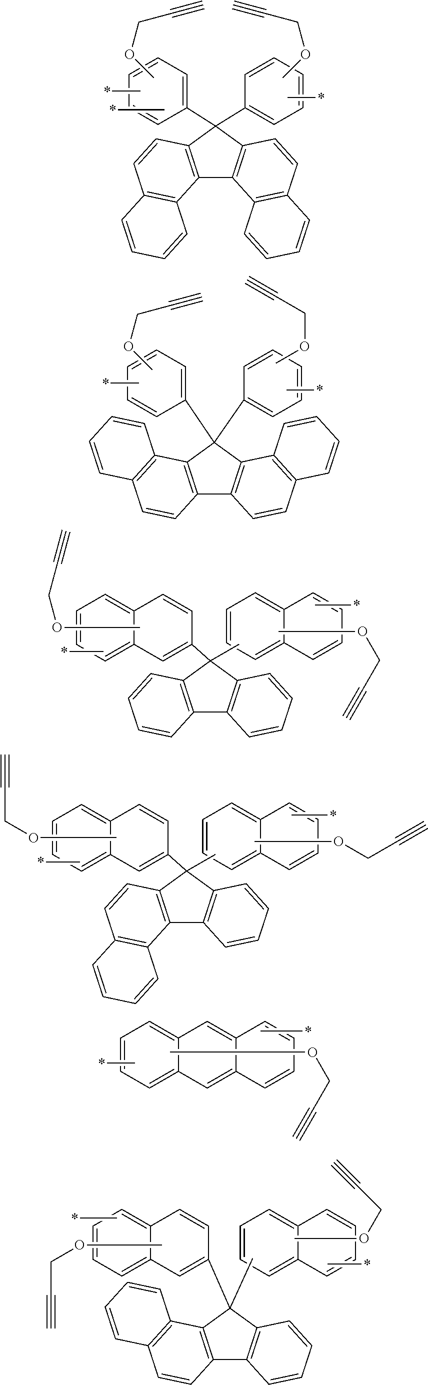

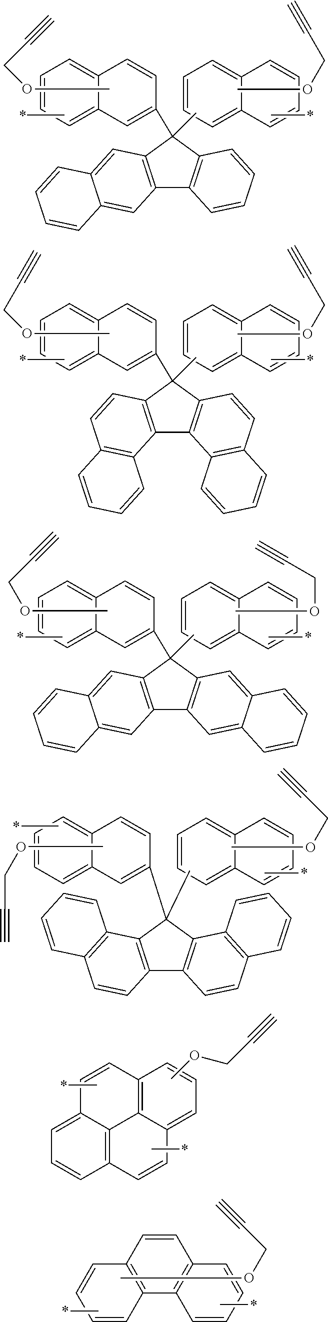

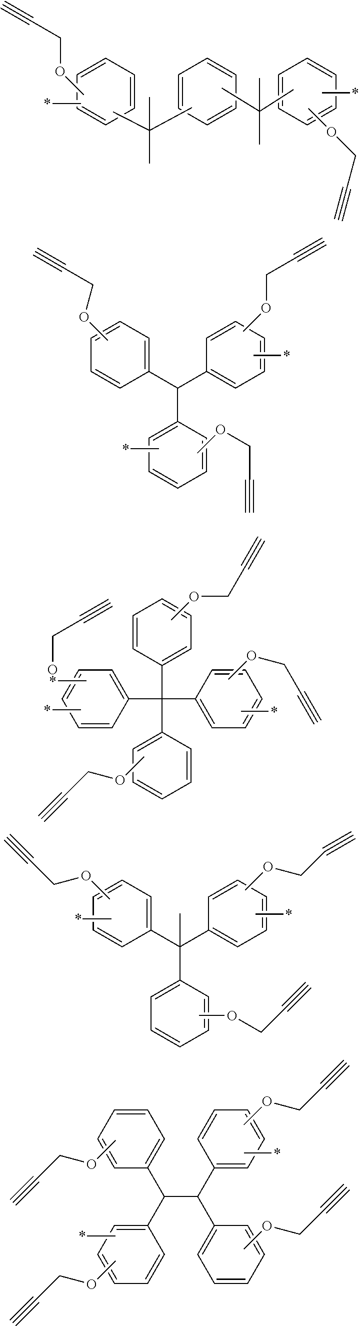

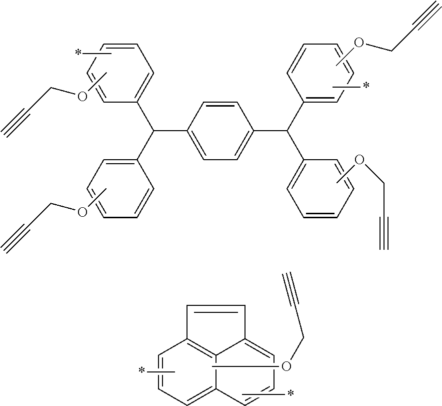

When R in NR and R in the NR₂ substituents in the skeletons of the unit structures A illustrated in (2-3-6) are H, the amine skeletons NH may be substituted with the following substituents in place of H, and the NH₂ substituents may be substituted with the following substituents in place of at least one H. The phenol skeletons illustrated in (2-3-7) may be substituted with the following substituents in place of H in OH.

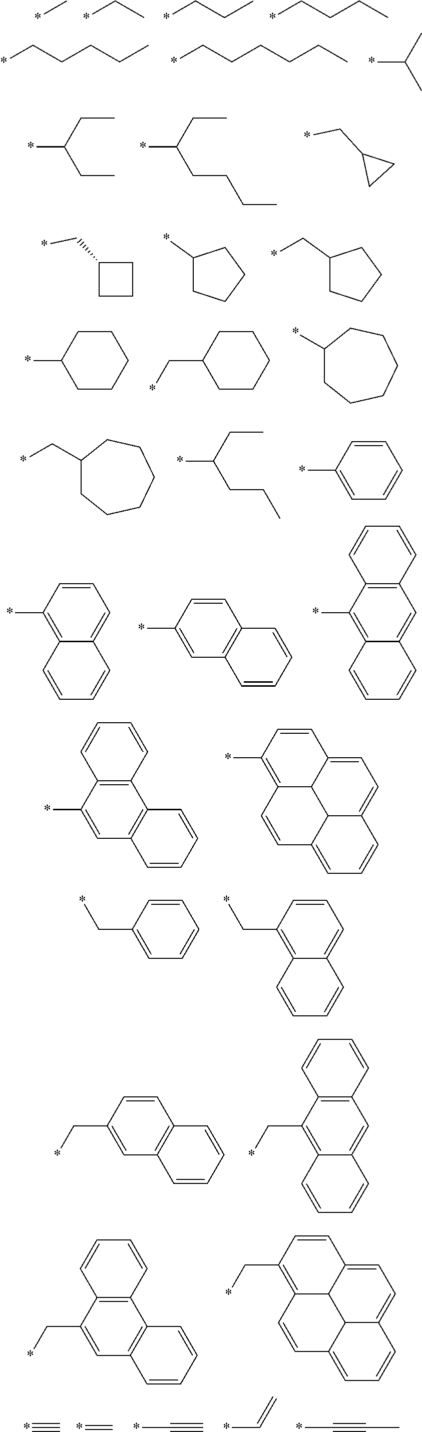

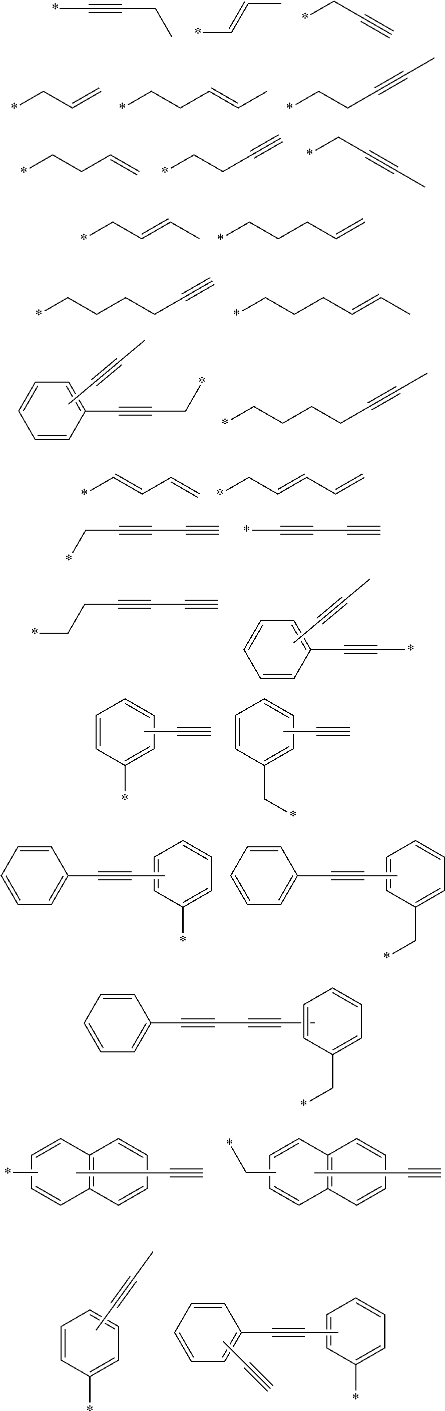

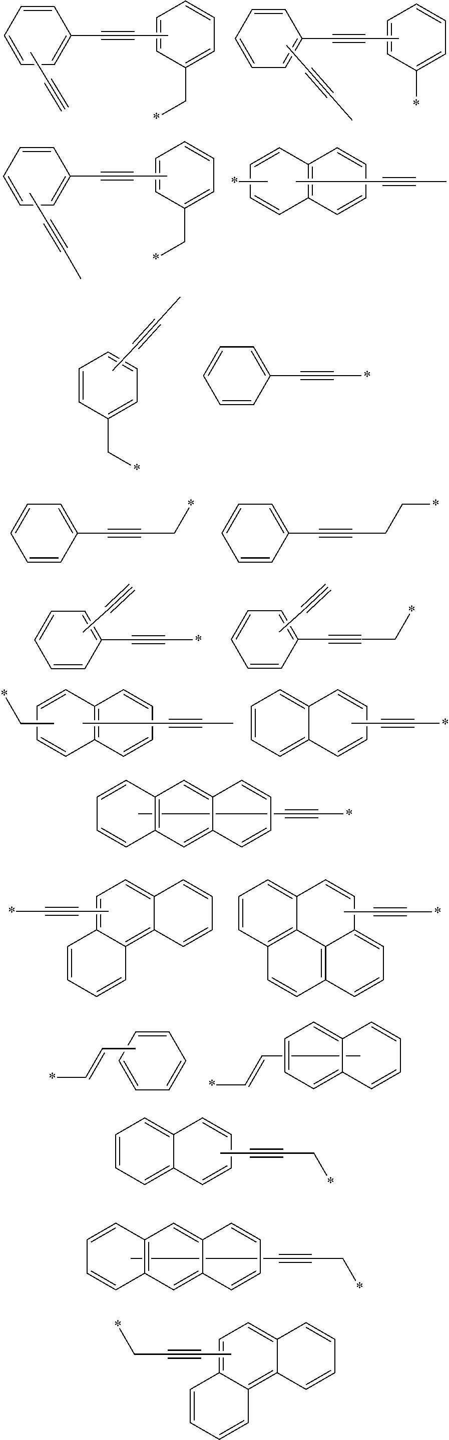

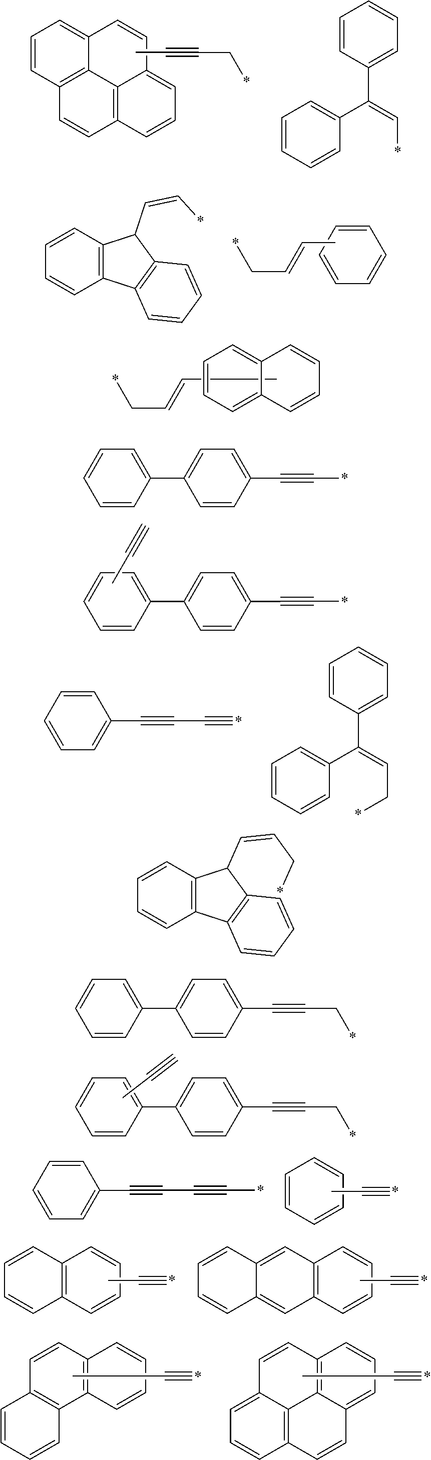

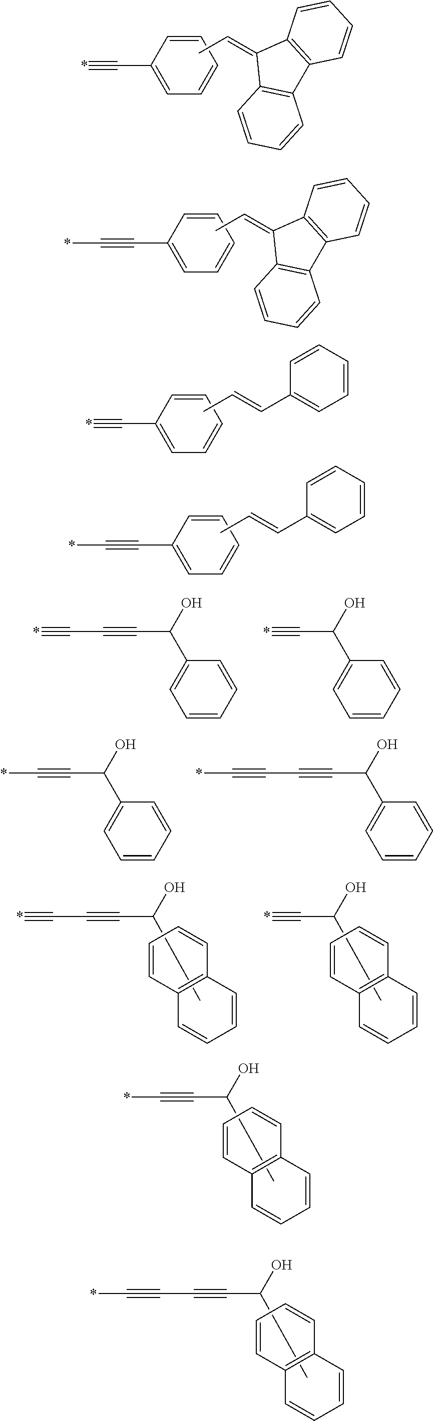

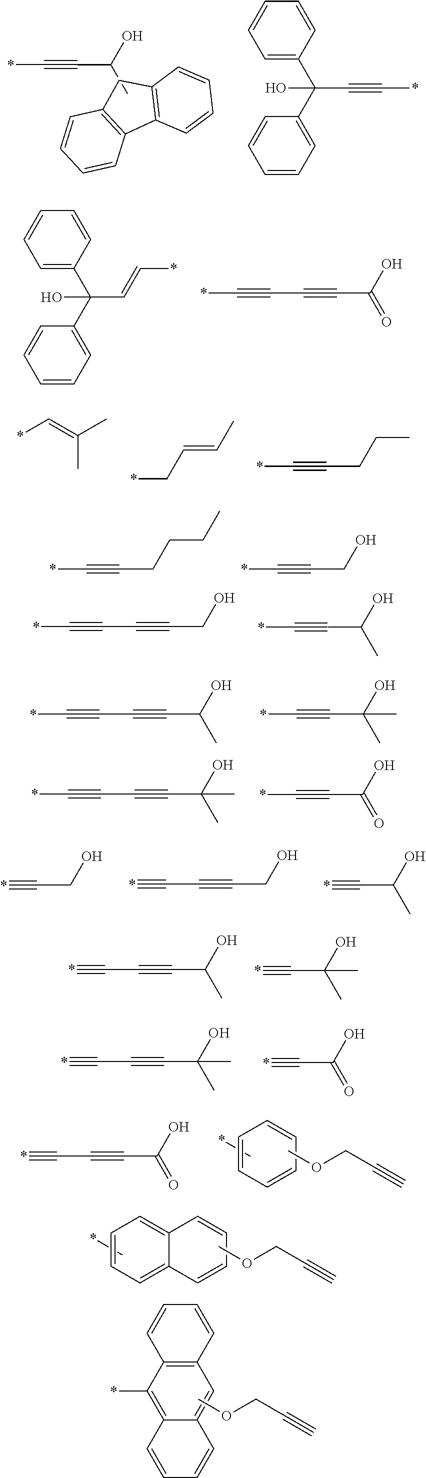

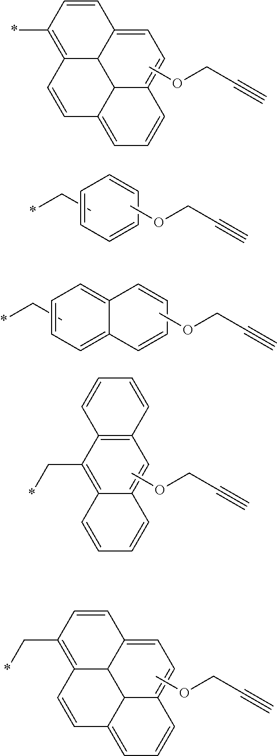

(2-3-9)

As will be described later in, for example, (2-4-3-3), (2-4-5-3), and (2-4-6), the unit structures described hereinabove have a structure that allows the unit structures to function also as unit structures B. However, the presence of the aromatic ring(s) in the structures determines the function as:
the unit structures A, or optionally also as:
unit structures C each equivalent to a composite unit structure AB in which one unit structure A and one unit structure B are bonded to each other.

### (2-4: Unit Structures B)

(2-4-1)

The unit structures B in the self-crosslinkable polymer according to an aspect of the present invention comprise one or more kinds of unit structures each comprising an organic group having one or more linking carbon atoms.

The linking carbon atoms are as described in (1-1) hereinabove.

Preferably, the unit structures B in the polymer each comprise an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings. Furthermore, the monocyclic, bicyclic, tricyclic, or tetracyclic organic group is optionally further condensed or fused with one or more aromatic rings to form a pentacyclic or higher condensed ring. The one or more linking carbon atoms are not carbon atoms constituting an aromatic monocyclic ring and form a covalent bond with the aromatic ring in the unit structure A [or the unit structure C] and thereby establishes bonding between the unit structure A [or the unit structure C] and the unit structure B.

(2-4-2)

Preferably, the unit structures B comprise one, or two or more kinds of unit structures including a structure represented by formula (II), (III), or (IV) below.

For example, these unit structures may be such that identical or different two or three structures represented by the above formulas are connected via a divalent or trivalent linking group [see (2-4-4-3) described later].

For example, the unit structures B form a covalent bond with a carbon atom on the aromatic ring in the unit structure A via a valence bond in formula (II), (III), or (IV) below and thereby establish bonding between the unit structure A [or the unit structure C] and the unit structure B.

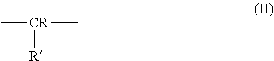

[In the formula (II), R and R′ each independently denote a hydrogen atom, an optionally substituted C6-C30 aromatic ring residue, an optionally substituted C3-C30 heterocyclic ring residue, or an optionally substituted C10 or lower, linear, branched, or cyclic alkyl group.]

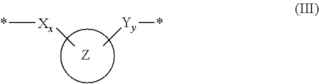

[In the formula (III),
Z is an optionally substituted C4-C25 monocyclic ring or bicyclic, tricyclic, or tetracyclic condensed ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic condensed ring is optionally further condensed with one or more aromatic rings to form a pentacyclic or higher condensed ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1,

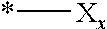

is bonded to any carbon atom (referred to as “carbon atom 1”) constituting any of the non-aromatic monocyclic rings in Z (when x=1) or extends from the carbon atom 1 (when x=0),

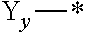

is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond.]

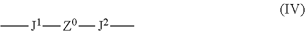

[In the formula (IV), Z⁰ denotes an optionally substituted C6-C30 aromatic ring residue, aliphatic ring residue, or organic group including two aromatic ring residues or aliphatic ring residues connected to each other via a single bond, and J¹ and J² each independently denote a direct bond or an optionally substituted divalent organic group.]
(2-4-3)
(2-4-3-1)

The unit structures B may include the formula (II):

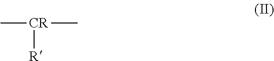

In this case, the term “substituted”, the “aromatic ring”, and the “heterocyclic ring” in the definition of R and R′ in the formula (II) are the same as described in (1-3) and (1-4) hereinabove.

Examples of the “alkyl group” in the definition of R and R′ in the formula (II) include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, and n-decyl group.

Preferably, R and R′ are each independently phenyl, naphthalenyl, anthracenyl, phenanthrenyl, naphthacenyl, or pyrenyl.

(2-4-3-2)

In principle, the two valence bonds in the formula (II) are bonded to aromatic rings in dissimilar structures having an aromatic ring (corresponding to the unit structures A or C). At a polymer terminal, however, the valence bond is bonded to a polymer terminal group [see (2-4-7) described later].

For example, the unit structure including a structure represented by the formula (II) may include the form of dimer or trimer structure in which two or three identical or differing structures of the formula (II) are bonded via a divalent or trivalent linking group. In this case, one of the two valence bonds in each of the structures of the formula (II) is bonded to the linking group. Examples of such linking groups include linking groups having two or three aromatic rings (corresponding to the unit structures A). Specific examples of the divalent or trivalent linking groups will be described later in (2-4-4-3).

(2-4-3-3)

When at least one of R or R′ in the formula (II) is an aromatic ring, and when the aromatic ring is bonded to the other unit structure B while one of the valence bonds in the formula (II) is bonded to the aromatic ring in the unit structure A, the resultant structure may be regarded as a single unit structure C equivalent to a composite unit structure A-B and may replace at least part of the composite unit structures A-B.

That is, the unit structures including a structure represented by the formula (II) may include such unit structures C. In this case, the remaining valence bond in the formula (II) will be bonded, for example, to a polymer terminal group or to an aromatic ring in other polymer chain to form a crosslink.

Embodiments of such unit structures C will be described in more detail with respect to formula (V) in (2-4-6) later.

In the present specification, any reference to a bonding to the unit structure A may be interpreted as including a bonding to the aromatic ring in the unit structure C, even if not explicitly stated. Furthermore, in the present specification, any reference to a bonding to the unit structure B may be interpreted as including a bonding to the linking carbon atom in the unit structure C, even if not explicitly stated.

(2-4-3-4)

Some specific examples of the organic groups including a structure represented by the formula (II) are illustrated below. * indicates a bonding site to the unit structure A. It is needless to mention that the illustrated structures may be part of the whole unit structure.

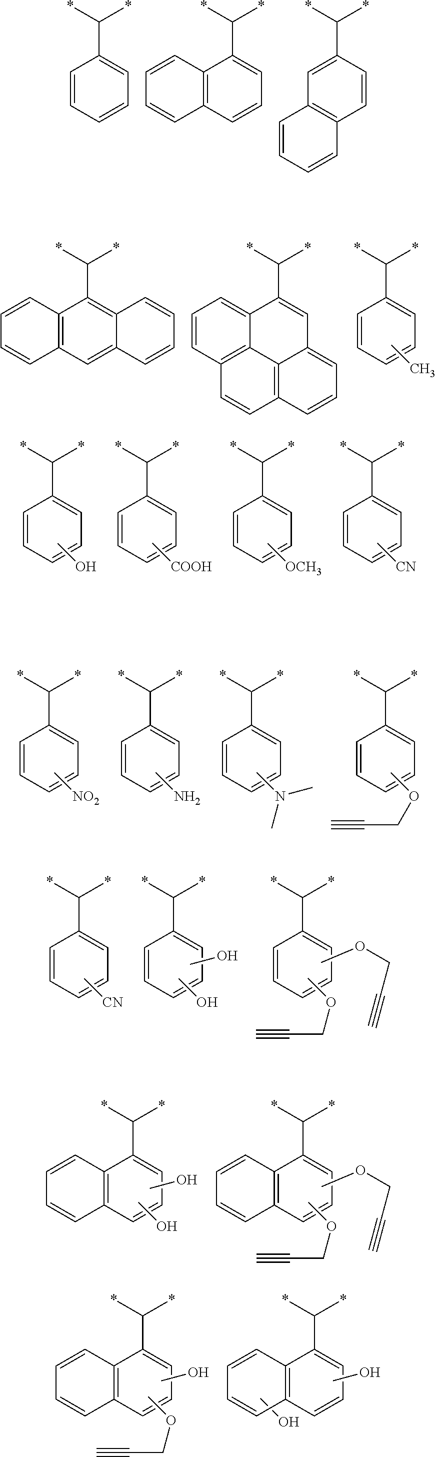

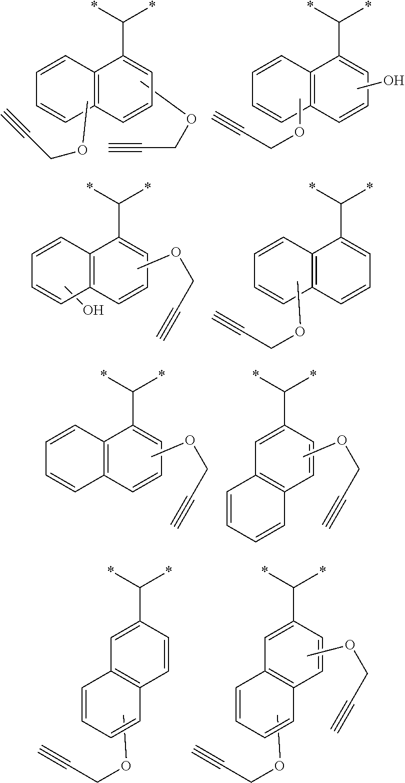

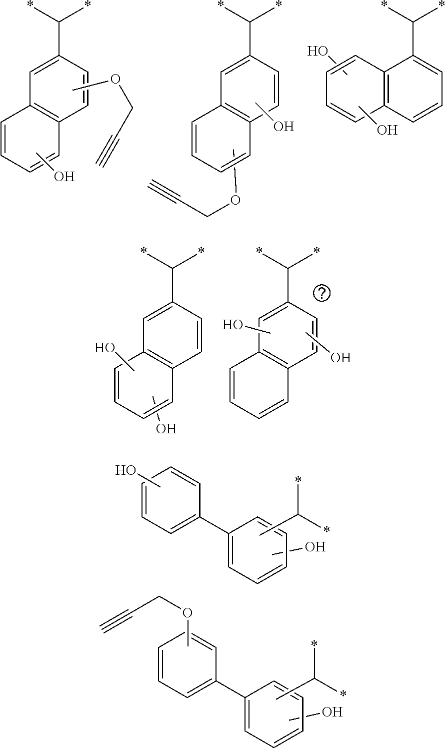

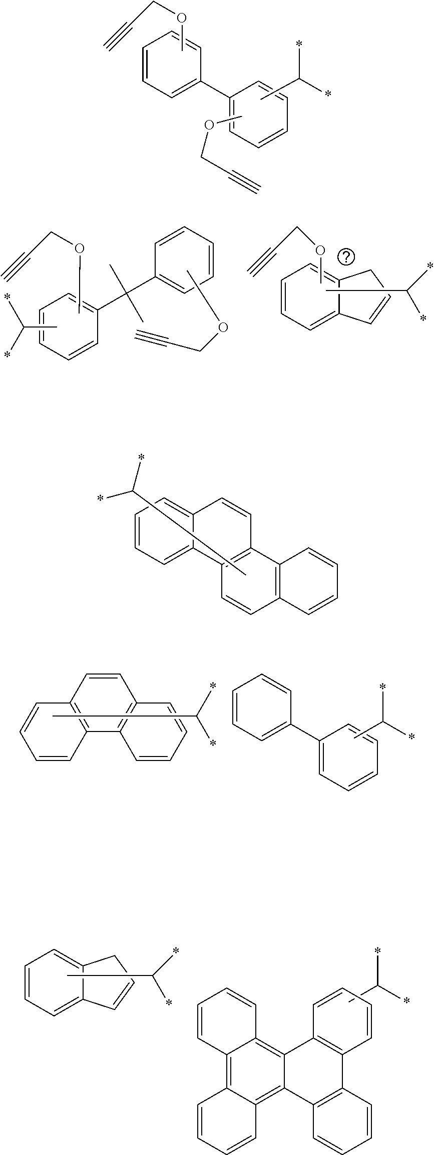

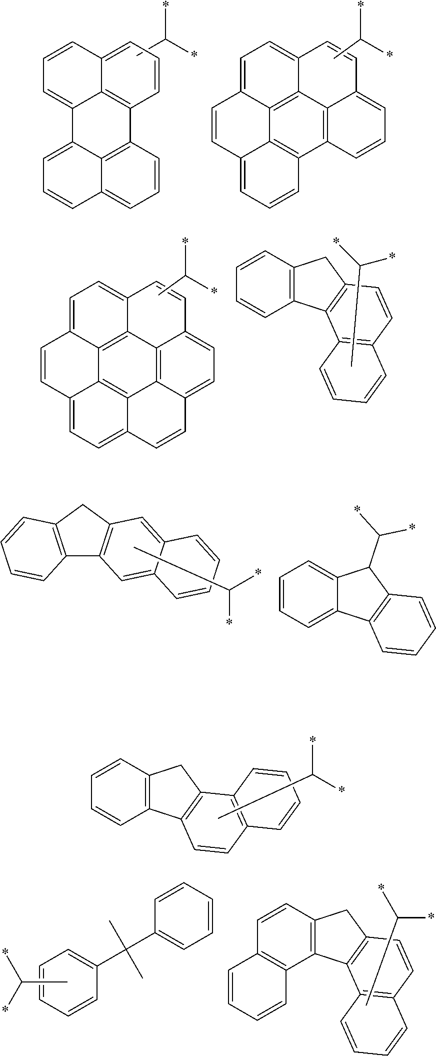

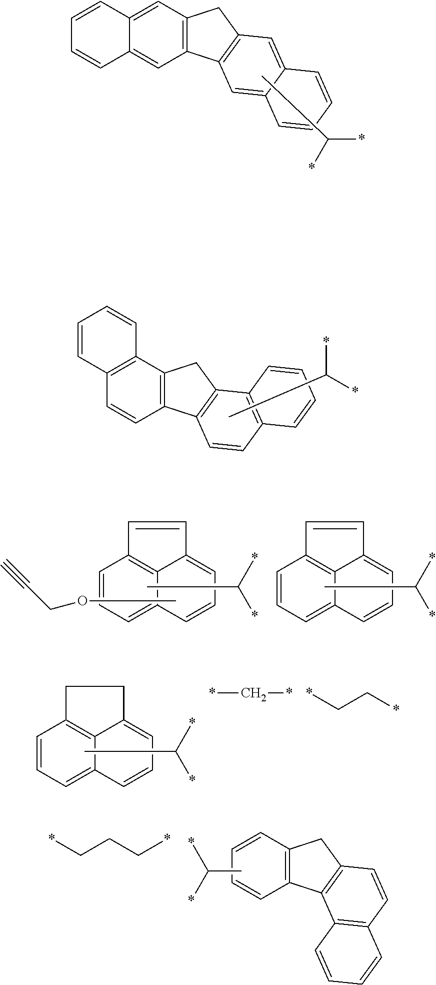

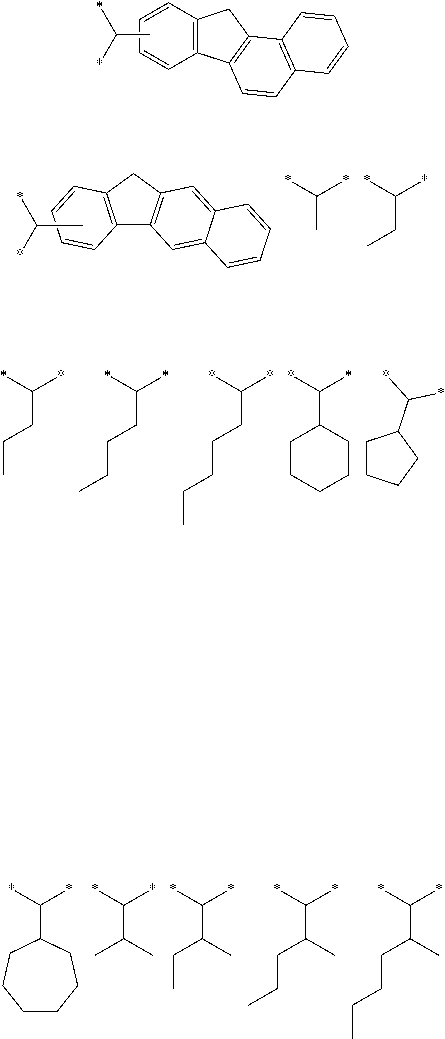

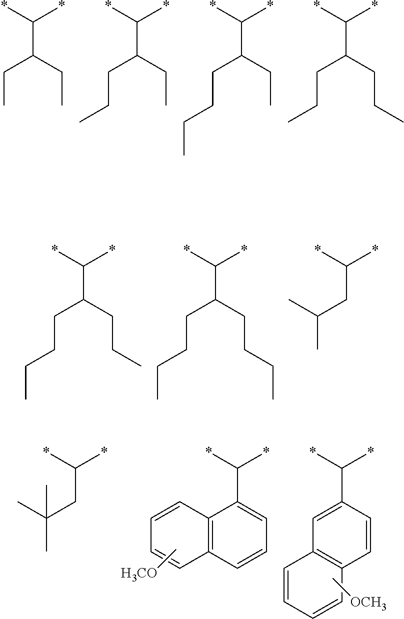

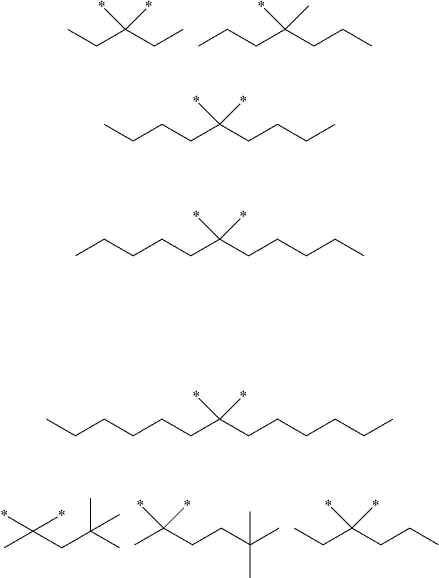

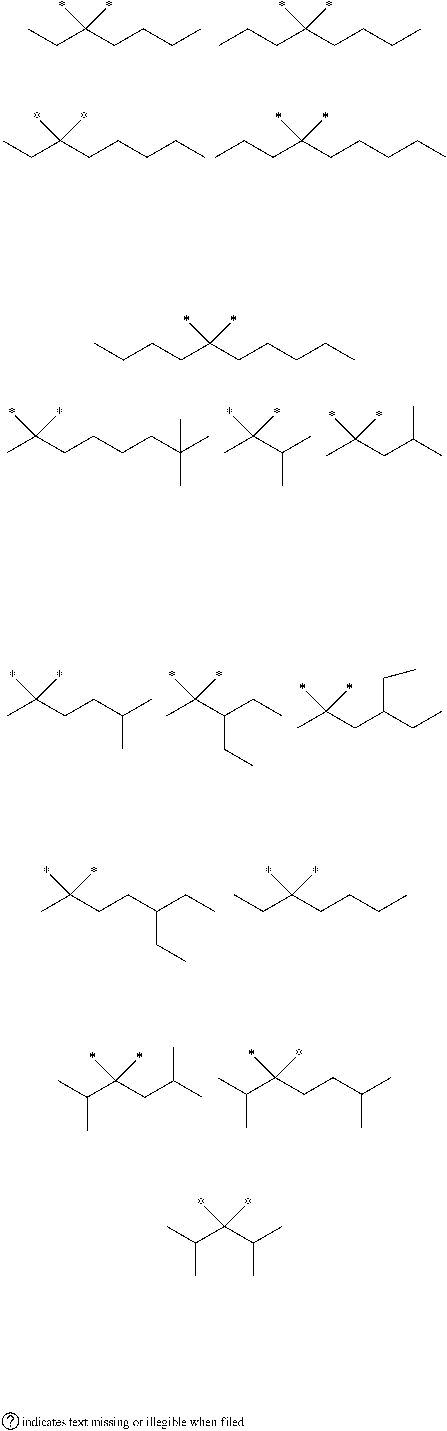

(2-4-4)
(2-4-4-1)

The unit structures B may include the formula (III):

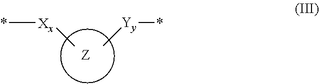

In the formula (III),
Z is an optionally substituted C4-C25 monocyclic ring or bicyclic, tricyclic, or tetracyclic condensed ring. Here, the number of carbon atoms indicates the number of carbon atoms constituting the ring skeleton of the monocyclic ring or the bicyclic, tricyclic, or tetracyclic condensed ring except substituents. When the monocyclic ring or the condensed ring is a heterocyclic ring, the number of carbon atoms does not include the number of heteroatoms constituting the heterocyclic ring.

The monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings may be aromatic monocyclic rings or non-aromatic monocyclic rings.

The monocyclic ring or the bicyclic, tricyclic, or tetracyclic condensed ring may be further condensed with one or more aromatic rings to form a pentacyclic or higher condensed ring. The number of carbon atoms in the pentacyclic or higher condensed ring is preferably 40 or less. The number of carbon atoms here indicates the number of carbon atoms constituting the ring skeleton of the pentacyclic or higher condensed ring except substituents. When the pentacyclic or higher condensed ring is a heterocyclic ring, the number of carbon atoms does not include the number of heteroatoms constituting the heterocyclic ring.

X and Y denote identical or different —CR³¹R³²— groups, and R³¹ and R³² are the same as or different from each other and each denote a hydrogen atom or a C1-C6 hydrocarbon group.

The letters x and y indicate the numbers of X and Y, respectively, and are each independently 0 or 1.

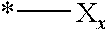

is bonded to any carbon atom (referred to as “carbon atom 1”) constituting any of the non-aromatic monocyclic rings in Z (when x=1) or extends from the carbon atom 1 (when x=0).

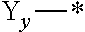

is bonded to any carbon atom (referred to as “carbon atom 2”) constituting any of the non-aromatic monocyclic rings in Z (when y=1) or extends from the carbon atom 2 (when y=0). The carbon atom 1 and the carbon atom 2 may be the same as or different from each other. The carbon atom 1 and the carbon atom 2 different from each other may belong to the same non-aromatic monocyclic ring or may belong to different non-aromatic monocyclic rings.

Furthermore, the formula (III) may optionally contain a linking carbon atom other than the carbon atom 1 and the carbon atom 2 [see (2-4-4-4) described later].

When Z is a tricyclic or higher condensed ring, the one or two non-aromatic monocyclic rings having the carbon atoms 1 and 2 in the formula (III) may have any permutational positional relationship with the other monocyclic ring or rings in the condensed ring. When the carbon atom 1 and the carbon atom 2 belong to different non-aromatic monocyclic rings (referred to as the “non-aromatic monocyclic ring 1” and the “non-aromatic monocyclic ring 2”, respectively), the permutational positional relationship between the non-aromatic monocyclic ring 1 and the non-aromatic monocyclic ring 2 in the condensed ring is not limited.

(2-4-4-2)

Embodiments of the unit structures of the formula (III) include formula (III-1) illustrated below.

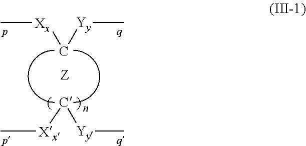

In the formula (III-1),
Z is an optionally substituted 4- to 17-membered monocyclic, bicyclic, tricyclic, or tetracyclic organic group, wherein the monocyclic ring or at least one of the monocyclic rings constituting the organic group is a non-aromatic monocyclic ring and the organic group has a maximum of four non-aromatic monocyclic rings. The remaining monocyclic ring or rings are aromatic rings. The rings may be further condensed with an additional aromatic monocyclic ring or rings to form a pentacyclic or higher polycyclic organic group.

Here, the non-aromatic monocyclic ring is a monocyclic ring that is not aromatic, and is typically an aliphatic monocyclic ring (or an aliphatic heteromonocyclic ring). The non-aromatic monocyclic ring is as described in (1-5) hereinabove.

Examples of the aromatic monocyclic rings and the aromatic rings include those illustrated in (1-3) hereinabove. For example, optionally substituted benzene rings, naphthalene rings, anthracene rings, and pyrene rings are preferable. Examples of the substituents include those illustrated in (1-3) hereinabove.

The formula (III-1) illustrates individual carbon atoms C and C′ [linking carbon atoms described in (1-1)] among the atoms constituting the ring moiety of the non-aromatic monocyclic ring. Of these carbon atoms, the linking carbon atom C is always present but the linking carbon atom C′ is optional. The letter n in the formula (III-1) indicating the number of C′ is 0 to 2. Preferably, n is 0.

X, Y, X′, and Y′ denote identical or different —CR¹R²— groups. R¹ and R² are the same as or different from each other and each denote a hydrogen atom or a C1-C3 hydrocarbon group. These linking groups are optional. That is, x, y, x′, and y′ indicating the numbers (0 or 1) of X, Y, X′, and Y′, respectively, may be all 0.

The letters p, q, p′, and q′ indicate the numbers of a valence bond and each independently denote 0 or 1. When the number is 0, the valence bond is meant to be replaced with a hydrogen atom.

In principle, these valence bonds are bonded to aromatic rings in dissimilar structures having an aromatic ring (corresponding to the unit structures A or C). At a polymer terminal, however, the valence bond is bonded to a polymer terminal group [see (2-4-7) described later].

To form a polymer chain, at least two valence bonds are necessary. When n is 0, p and q are 1. When n is 1, assuming that at least one valence bond extends from each of C and C′ (the linking carbon atoms), at least one of p or q, and at least one of p′ or q′ are each 1. When n is 2, similarly, at least one of p or q, and at least one of p′ or q′ in each C′ are each 1.

When the unit structure has two or more valence bonds, the extra valence bond(s) will be bonded, for example, to a polymer terminal group or to an aromatic ring in other polymer chain to form a crosslink.

(2-4-4-3)

Two or three identical or differing structures of the formula (III-1) may be bonded to a divalent or trivalent linking group to form a dimer or trimer structure.

In this case, either of the valence bonds p and q in each structure of the formula (III-1) is bonded to the linking group. Furthermore, n is not 0, and one valence bond is provided from the linking carbon atom C and at least one valence bond is provided from the linking carbon atom C′.

For example, among the unit structures usable as the unit structures A, those having two or three aromatic rings may be used as such linking groups. Examples thereof include divalent or trivalent linking groups of the following formulas:

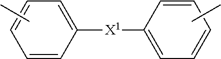

[X¹ denotes a single bond, a methylene group, an oxygen atom, a sulfur atom, or —N(R¹)—, and R¹ denotes a hydrogen atom or a C1-C20 hydrocarbon group (that may be a chain hydrocarbon or a cyclic hydrocarbon (that may be aromatic or non-aromatic)).]

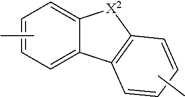

[X² denotes a methylene group, an oxygen atom, or —N(R²)—, and R² denotes a hydrogen atom, a C1-C10 aliphatic hydrocarbon group, or a C5-C20 aromatic hydrocarbon group.]

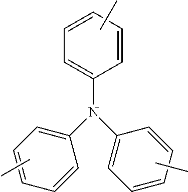

Examples further include a divalent linking group of formula below that can undergo an addition reaction of an acetylide with a ketone to form a covalent bond with the linking carbon atom.

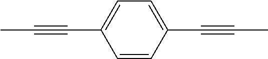

(2-4-4-4)

Some specific examples of the organic groups including a structure represented by the formula (III) are illustrated below. It is needless to mention that the illustrated structures may be part of the whole unit structure.

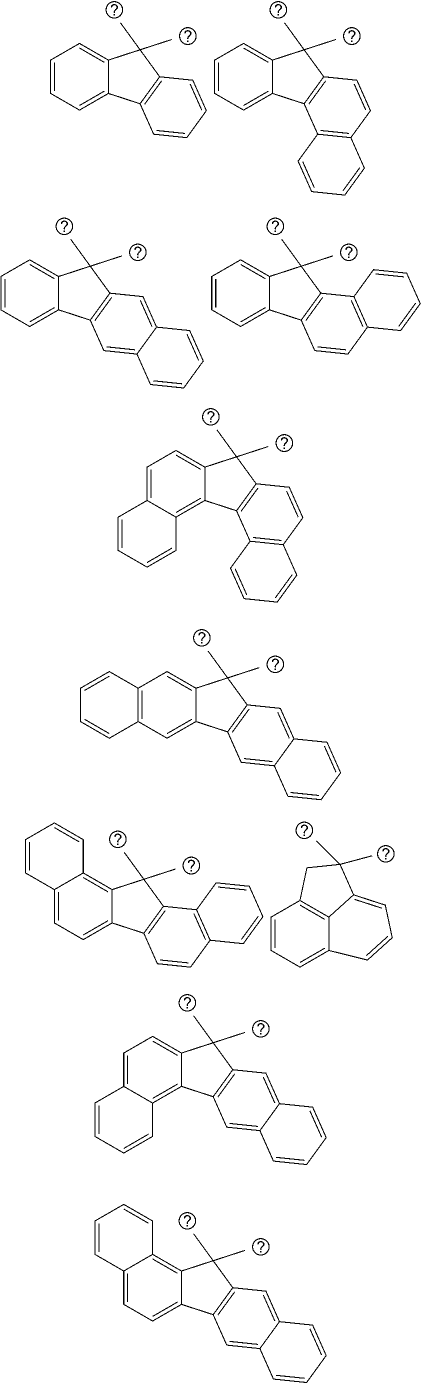

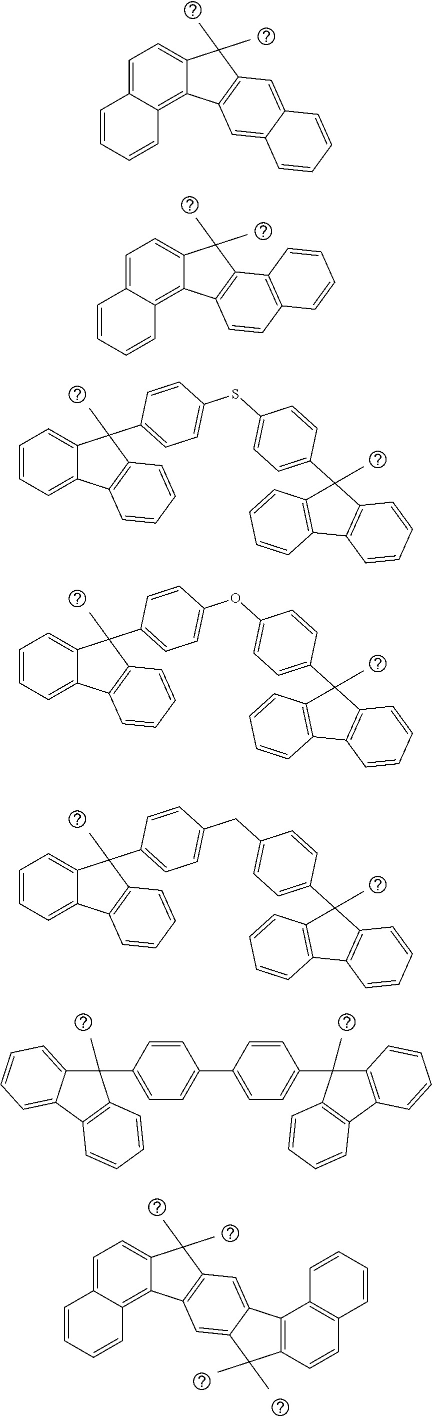

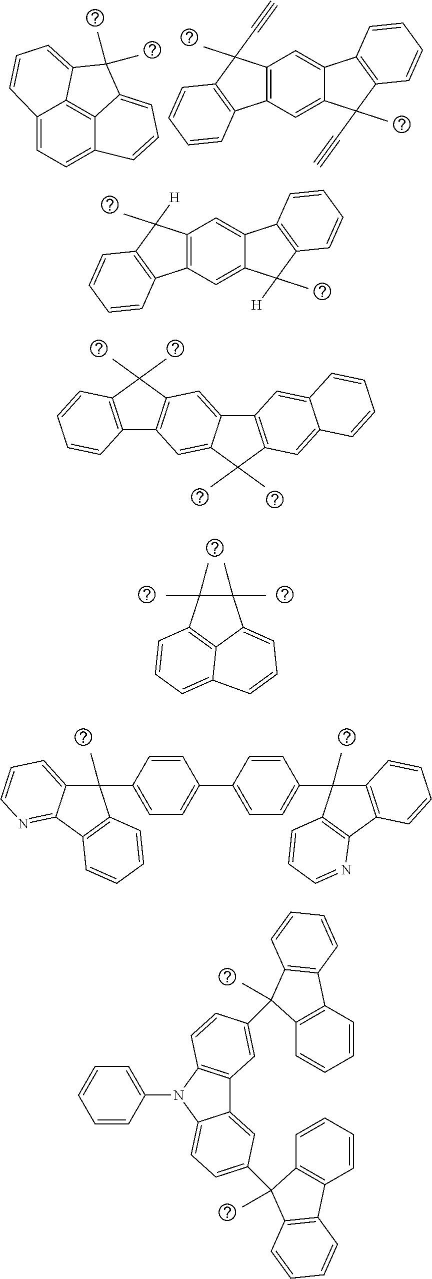

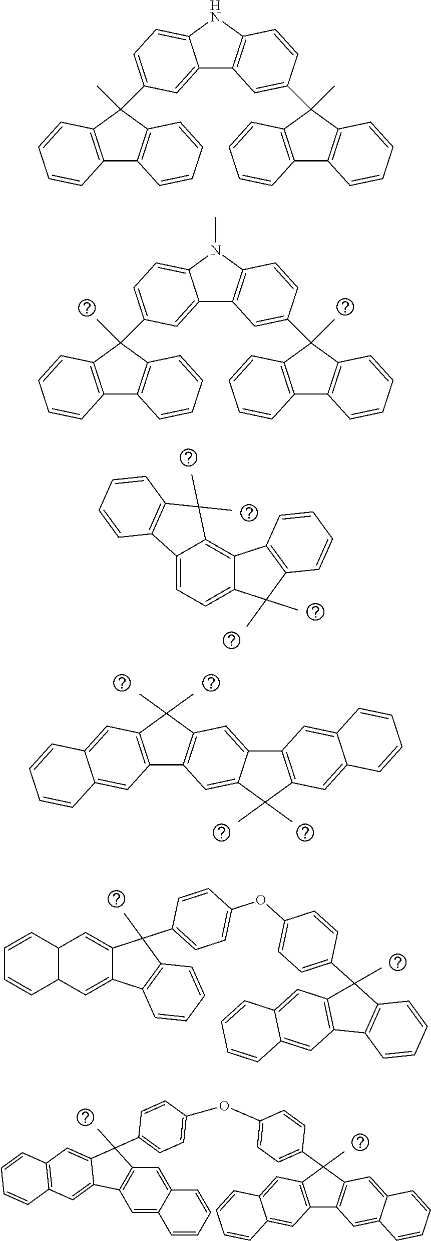

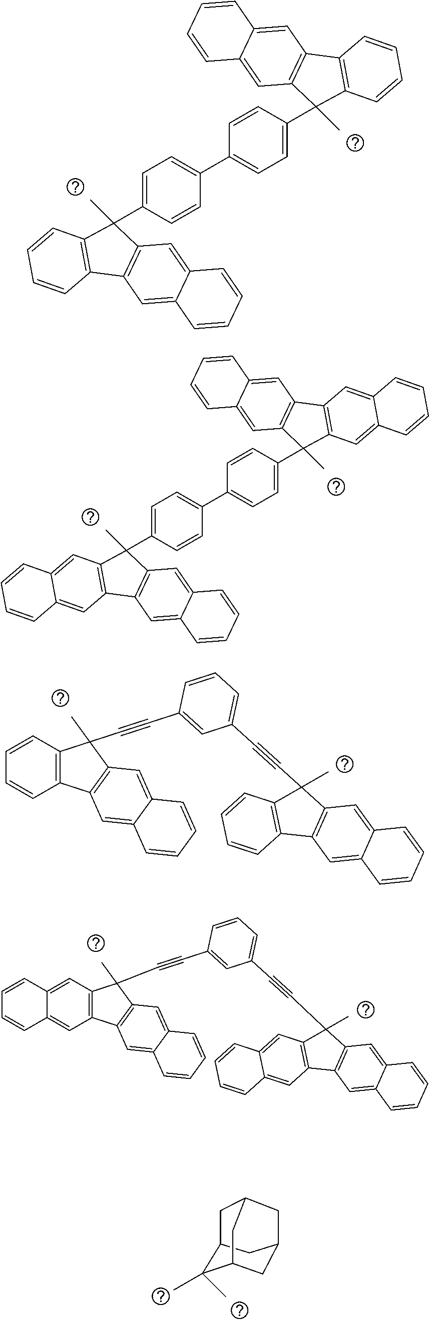

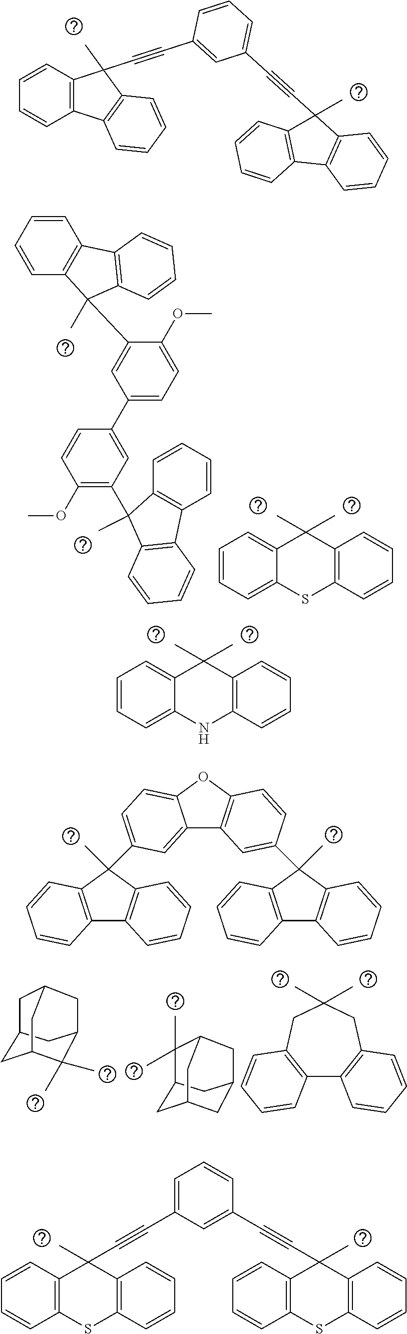

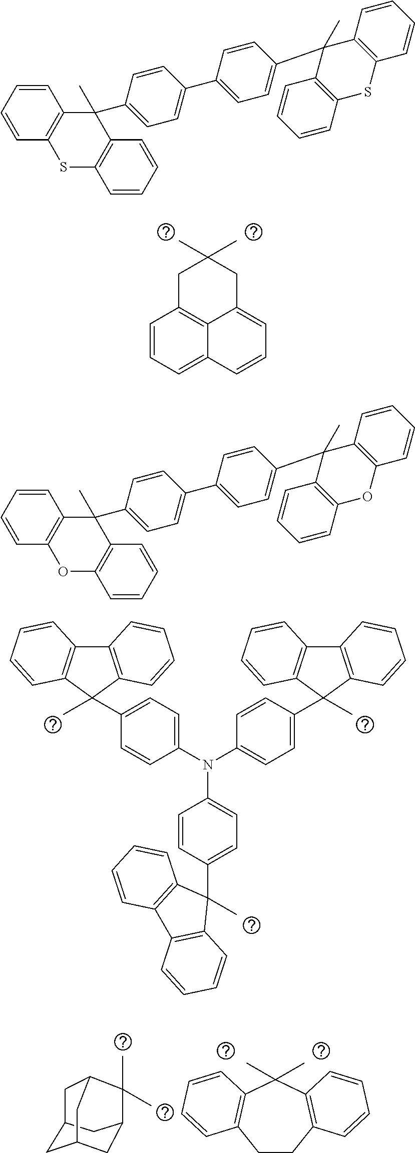

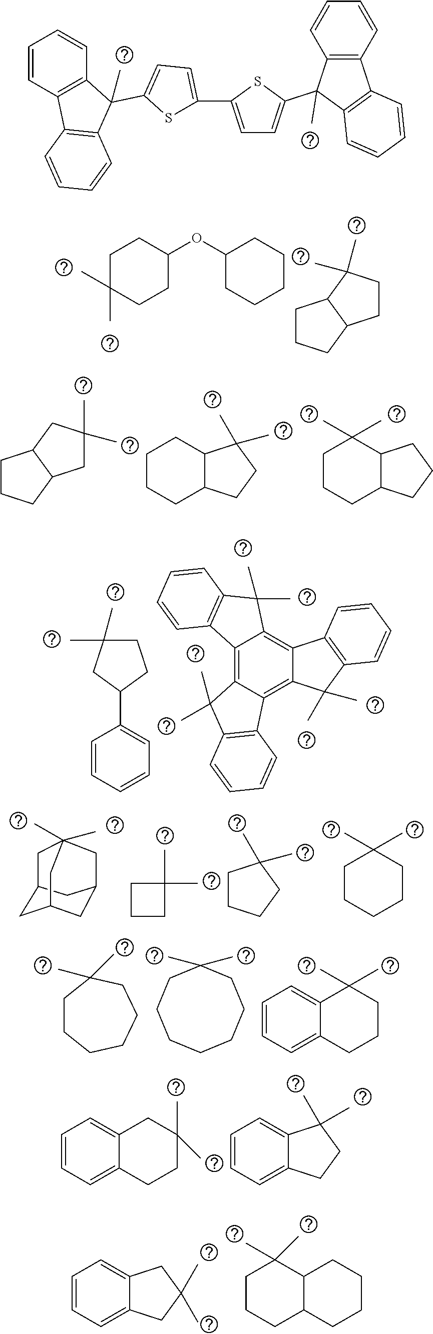

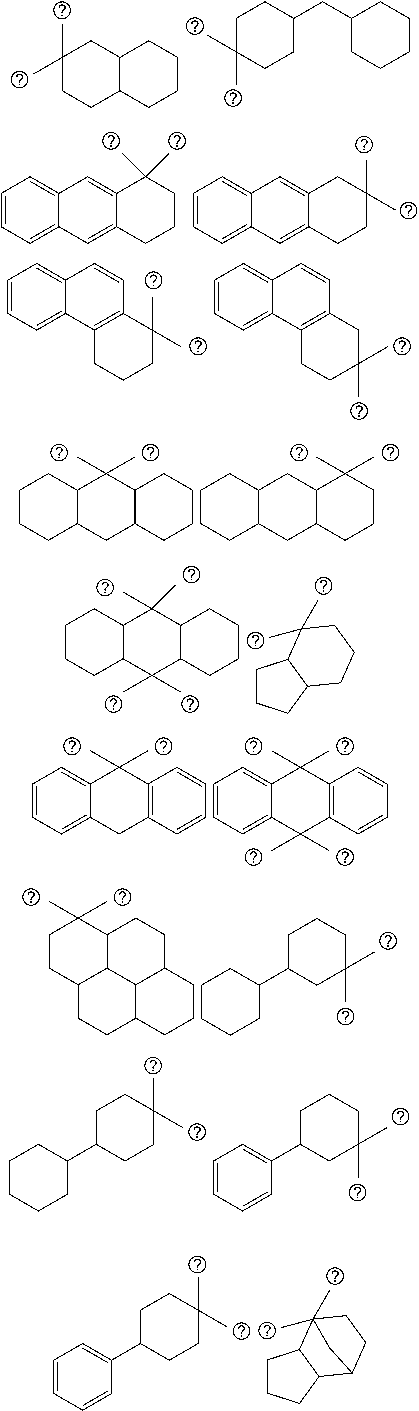

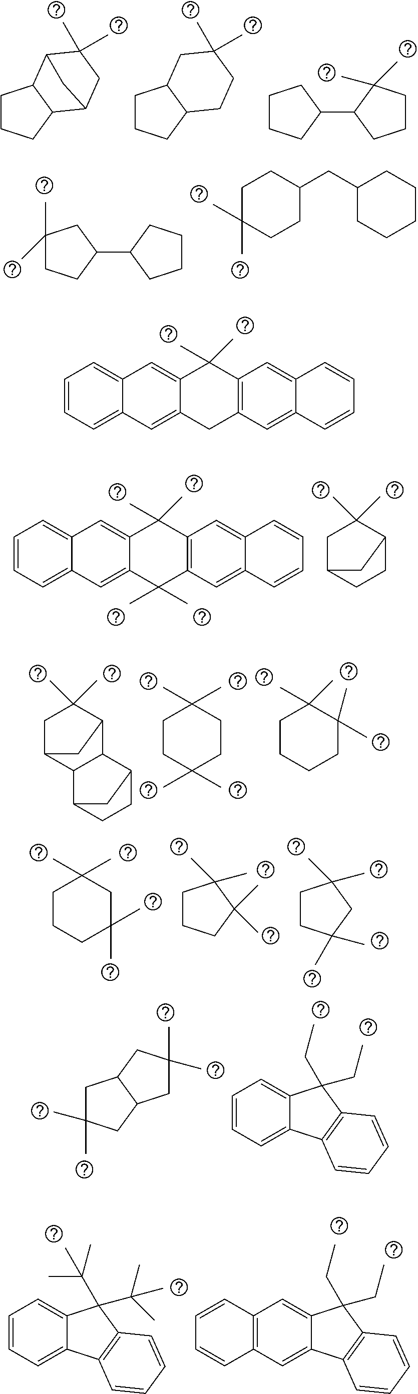

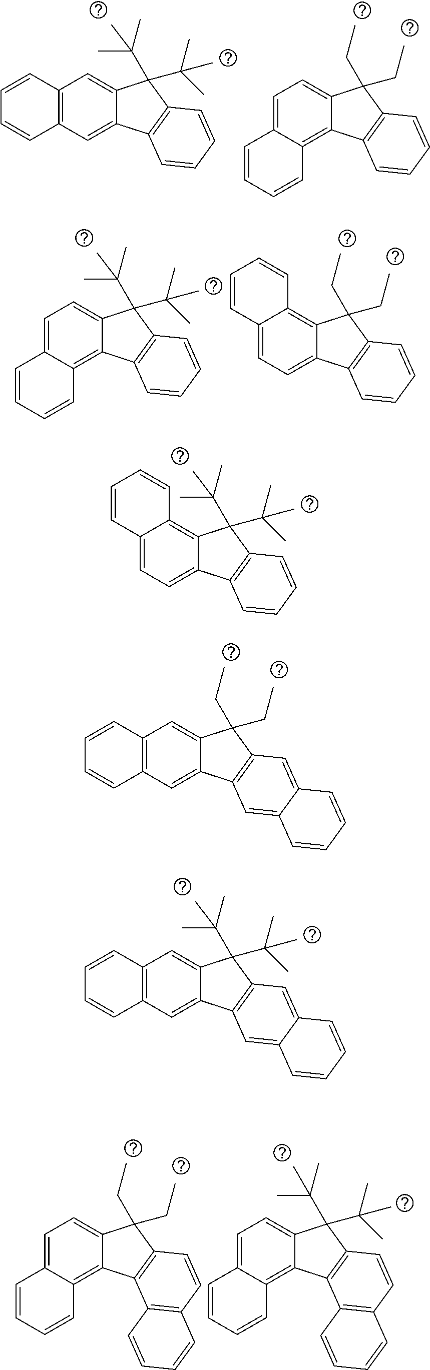

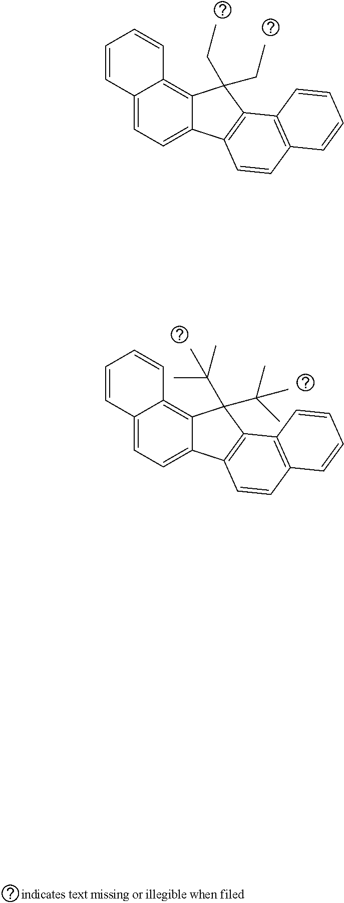

(2-4-5)
(2-4-5-1)

The unit structures B may include the formula (IV):

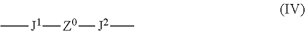

In this case, the “aromatic ring”, the term “substituted”, and the “aliphatic ring” in the definition of Z⁰ in the formula (IV) are the same as described in (1-3) and (1-5).

Examples of the organic groups including two aromatic ring residues or aliphatic ring residues connected to each other via a single bond include divalent residues, such as biphenyl, cyclohexylphenyl, and bicyclohexyl.

In the definition of J¹ and J², the “divalent organic group” is preferably a C1-C6 linear or branched alkylene group optionally substituted with a substituent, such as a hydroxyl group or a halo group (for example, fluorine). Examples of the linear alkylene groups include methylene group, ethylene group, propylene group, butylene group, pentylene group, and hexylene group.

(2-4-5-2)

Two or three identical or differing structures of the formula (IV) may be bonded to a divalent or trivalent linking group to form a dimer or trimer structure. In this case, either of the two valence bonds in each structure of the formula (IV) is bonded to the linking group.

For example, among the unit structures usable as the unit structures A, those having two or three aromatic rings may be used as such linking groups.

Specific examples of the divalent or trivalent linking groups include those illustrated in (2-4-4-3) hereinabove.

(2-4-5-3)

Embodiments of the formula (IV) include those in which the unit structure contains an aromatic ring. In this embodiment, the aromatic ring in the formula (IV) may be bonded to the other unit structure B while one of the valence bonds in the formula (IV) may be bonded to the aromatic ring in the unit structure A. The resultant structure may be regarded as a single unit structure C equivalent to a composite unit structure A-B and may replace at least one composite unit structure AB.

That is, the unit structures including a structure represented by the formula (IV) may include such unit structures C. In this case, the remaining valence bond in the formula (IV) will be bonded, for example, to a polymer terminal group or to an aromatic ring in other polymer chain to form a crosslink.

Embodiments of such unit structures C will be described in more detail with respect to formula (V) in (2-4-6) later.

(2-4-5-4)

Some specific examples of the unit structures including a structure represented by the formula (IV) are illustrated below. * indicates a bonding site to the unit structure A. It is needless to mention that the illustrated structures may be part of the whole unit structure.

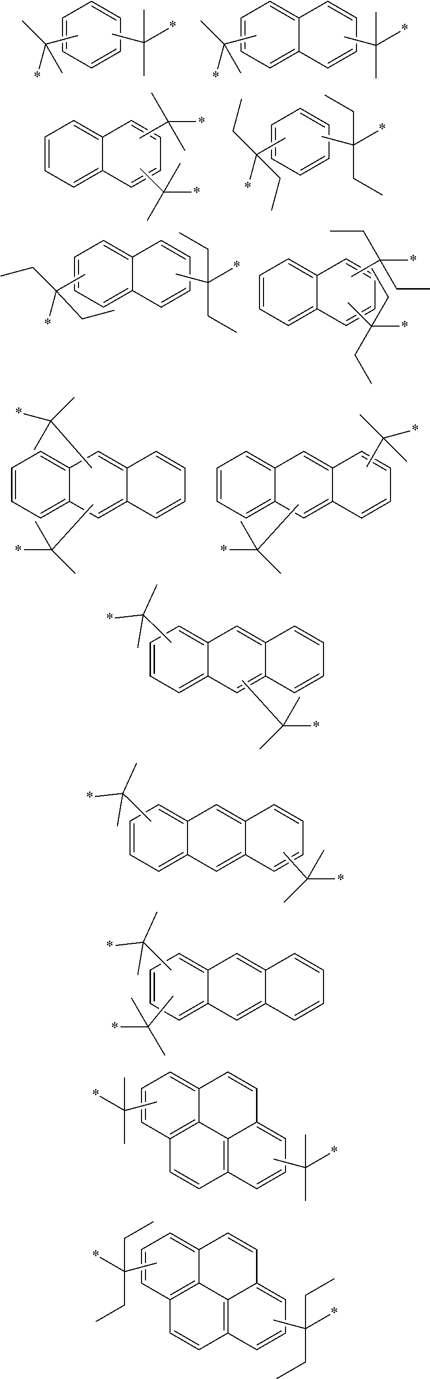

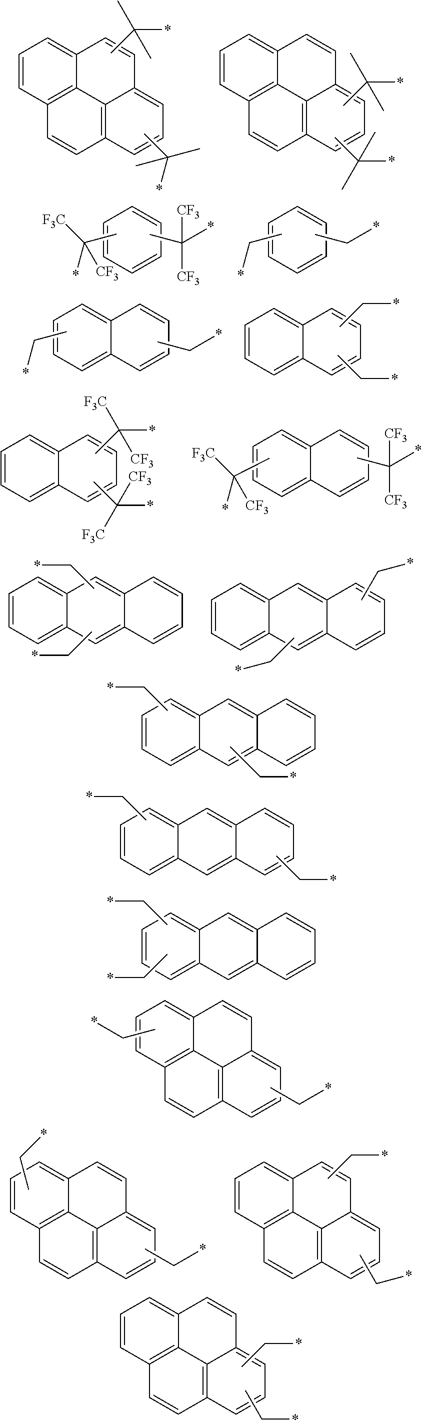

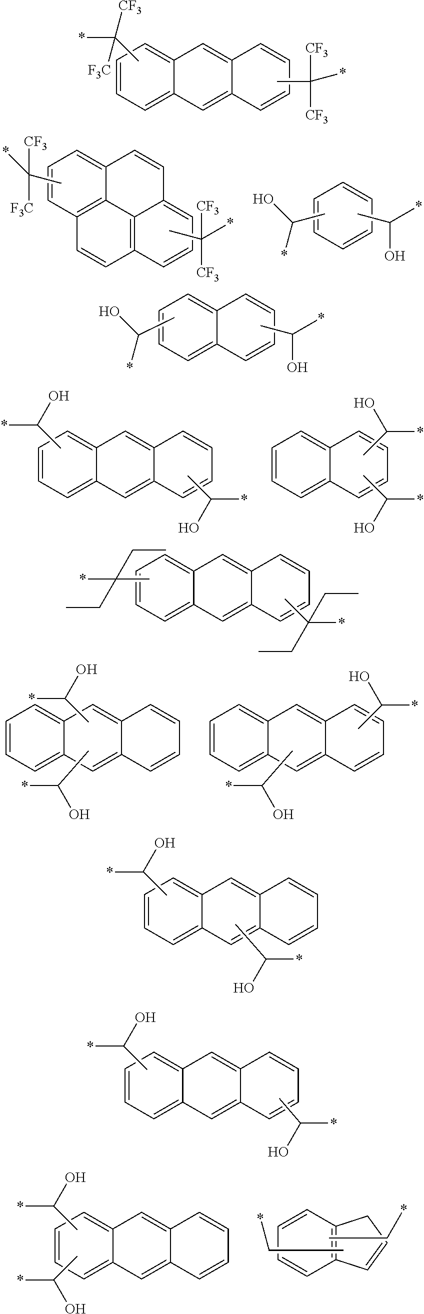

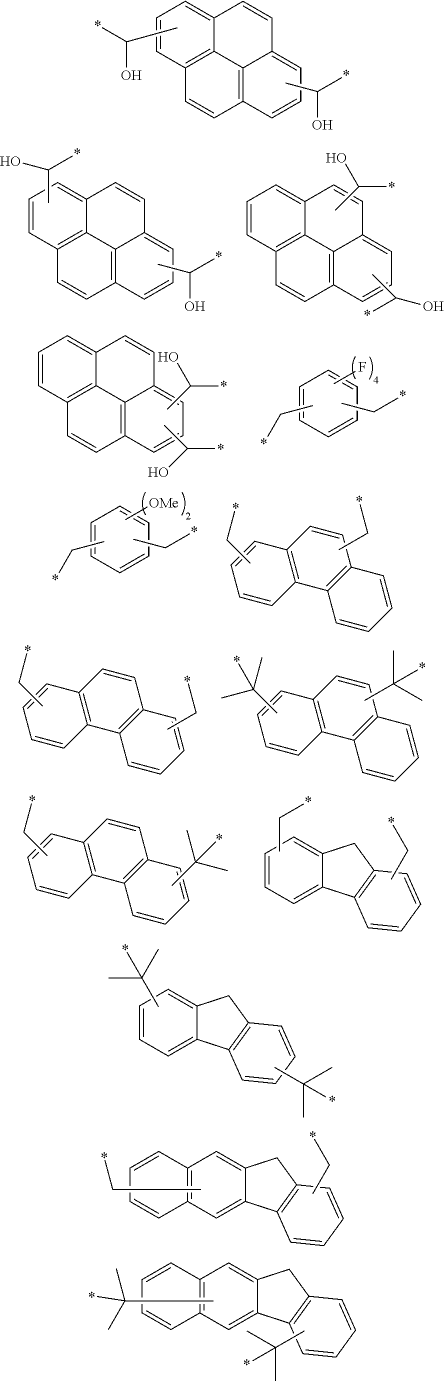

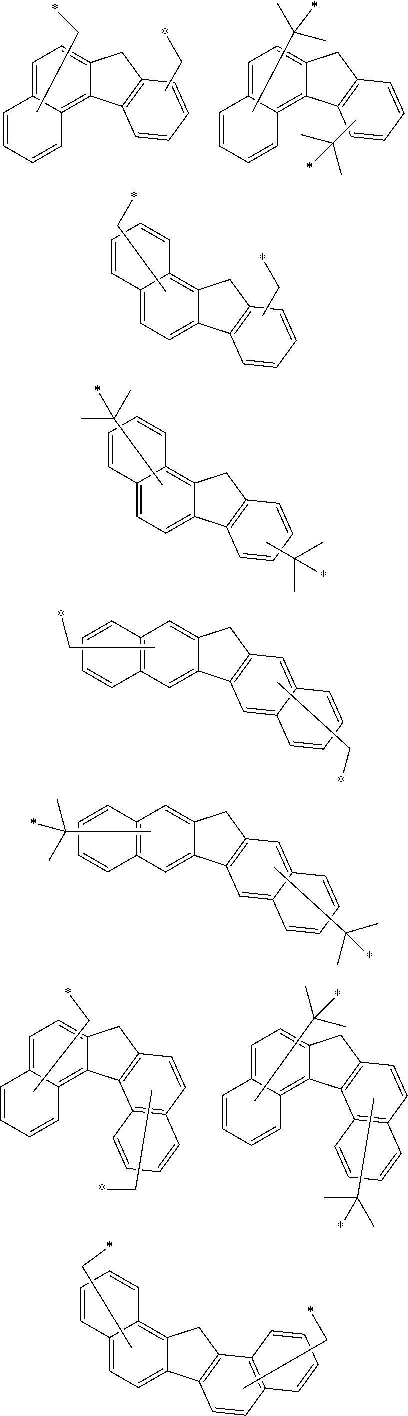

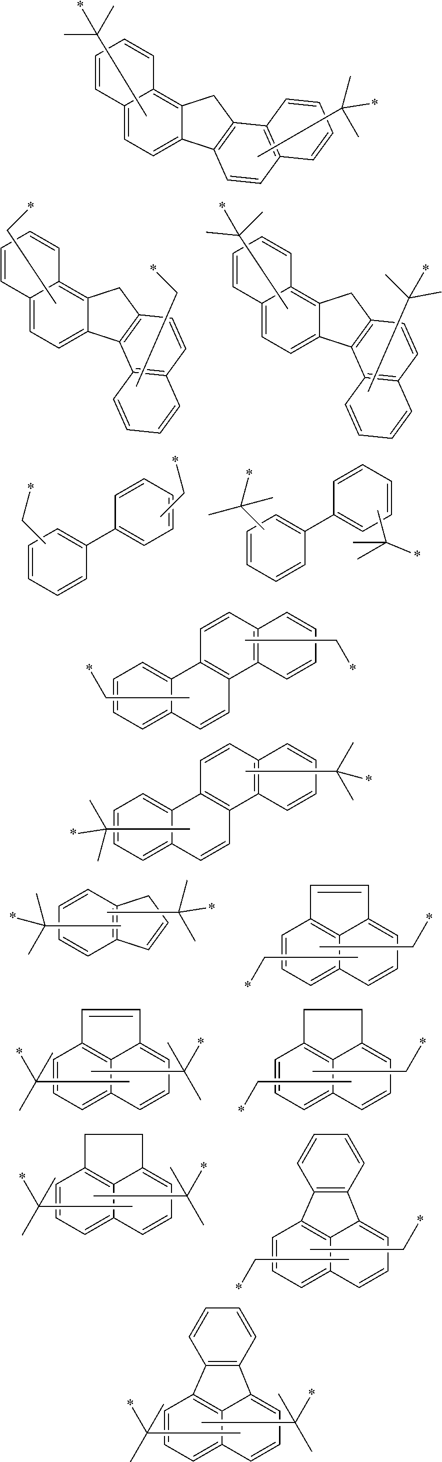

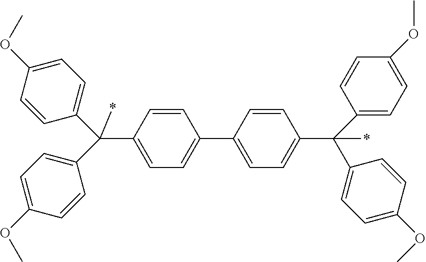 [SMILES: *C(c1ccc(OC)cc1)(c1ccc(OC)cc1)c1ccc(-c2ccc(C(*)(c3ccc(OC)cc3)c3ccc(OC)cc3)cc2)cc1]

(2-4-6)
(2-4-6-1)

Z in the formula (III) may contain an aromatic ring Ar¹. Unit structures of such formula (III) include a structure represented by formula (V) below. Similarly to the embodiments described in (2-4-3-3) and (2-4-5-3), such a unit structure may be regarded as a single unit structure C equivalent to a composite unit structure A-B and may replace at least part of the composite unit structures A-B.

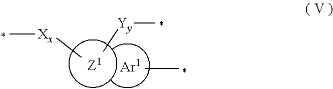

In the formula (V),
Z¹ denotes at least one non-aromatic monocyclic ring; Ar¹ denotes at least one aromatic monocyclic ring forming a condensed ring with the non-aromatic monocyclic ring in Z¹; and the whole of Z¹ and Ar¹ is an optionally substituted C8-C25 bicyclic, tricyclic, tetracyclic, or pentacyclic condensed ring. The number of carbon atoms here indicates the number of carbon atoms constituting the ring skeleton of the bicyclic, tricyclic, or tetracyclic condensed ring except substituents. When the bicyclic, tricyclic, or tetracyclic condensed ring is a heterocyclic ring, the number of carbon atoms does not include the number of heteroatoms constituting the heterocyclic ring.

The bicyclic, tricyclic, tetracyclic, or pentacyclic organic group may be further condensed with one or more aromatic rings to form a hexacyclic or higher ring. The number of carbon atoms in the hexacyclic or higher condensed ring is preferably 40 or less. The number of carbon atoms here indicates the number of carbon atoms constituting the ring skeleton of the pentacyclic or higher condensed ring except substituents. When the hexacyclic or higher condensed ring is a heterocyclic ring, the number of carbon atoms does not include the number of heteroatoms constituting the heterocyclic ring.

In the cyclic organic group, the one, or two or more non-aromatic monocyclic rings in Z¹ may have any permutational positional relationship with the one, or two or more aromatic monocyclic rings in Ar¹. When, for example, Z¹ contains two or more non-aromatic monocyclic rings and Ar¹ contains two or more aromatic monocyclic rings, the non-aromatic monocyclic rings in Z¹ and the aromatic monocyclic rings in Ar¹ may be condensed alternately.

X, Y, x, and y are the same as defined in the formula (III).

Embodiments of the formula (V) include formula (V-1) below:

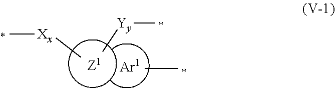

[In the formula (V-1),
Z¹, Ar¹, X, Y, x, and y are the same as defined in the formula (V), and
T denotes a polymer terminal.]

When one valence bond of the linking carbon atom is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in the formula (V-1), the unit structure may be regarded as a single unit structure C equivalent to a composite unit structure A-B and may replace at least one composite unit structure A-B. That is, the aromatic ring in the formula (V-1) [Ar¹ in the formula (V-1)] may be bonded to the other unit structure B and the remaining valence bond of the linking carbon atom illustrated in the formula (V-1) may be bonded to the aromatic ring in the unit structure A, thereby extending the polymer chain.

Embodiments of the formula (V) further include unit structures including a structure of formula (V-2) below that are unit structures C equivalent to composite unit structures A-B.

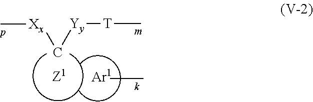

In the formula (V-2),
Z¹ denotes at least one non-aromatic monocyclic ring; Ar¹ denotes at least one aromatic monocyclic ring; and the whole of Z¹ and Ar¹ is a cyclic organic group that is an optionally substituted 8- to 17-membered bicyclic or higher condensed ring. In the cyclic organic group, the aromatic monocyclic rings and the non-aromatic monocyclic rings may be arranged in any manner and in any order.

Here, the “non-aromatic monocyclic ring”, the “aromatic monocyclic ring”, and the “aromatic ring” are as described in (1-3) and (1-5) hereinabove.

Any of the non-aromatic monocyclic ring or rings contains the carbon atom C illustrated in the formula (V-2) [the linking carbon atom described in (1-1)] among the atoms constituting the ring moiety.

X and Y denote identical or different —CR¹R²— groups. R¹ and R² are the same as or different from each other and each denote a hydrogen atom or a C1-C3 hydrocarbon group. These linking groups are optional. That is, x and y indicating the numbers (0 or 1) of X and Y, respectively, may be all 0.

T denotes a polymer terminal group or an aromatic ring residue Ar². The aromatic ring residue is as described in (2-4-4-1) hereinabove.

The letter p denotes one valence bond for forming a covalent bond with the aromatic ring in the unit structure A (or an aromatic ring in the unit structure C).

On the other hand, k and m denote the numbers of valence bonds for forming a covalent bond with the unit structure B (or the unit structure C). The letter k is 0 to 2, m is 0 or 1, and at least one of k or m is not 0 (when k and m are 0, the valence bonds are meant to be replaced with hydrogen atoms).

Thus, the unit structure of the formula (V-2) may be regarded as a single unit structure C equivalent to a composite unit structure A-B and may replace at least part of the composite unit structures A-B.

When k is 2 or when k is 1 and m is 1, the extra valence bond will be bonded to a polymer terminal group or will form a crosslink with other polymer chain.

(2-4-6-2)

The unit structures C including a structure of the formula (V), in particular, (V-1) or (V-2), will be described based on more specific structures.

For example, in the structure below, T is a terminal hydrogen atom. When the valence bonds are indicated by p and k₁ or by p and k₂, the unit structure may serve as a single unit structure C equivalent to a composite unit structure A-B.

Incidentally, the unit structure may also function as a unit structure A when the valence bonds are indicated by k₁ and k₂.

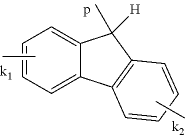

Furthermore, in the following exemplary structure, T is a phenyl group. When the valence bonds are indicated by p and k₁, by p and k₂, or by p and m, this illustrative structure may serve as a single unit structure C equivalent to a composite unit structure A-B.

Incidentally, the unit structure may also function as a unit structure A when the valence bonds are indicated by k₁ and k₂, by k₁ and m, or by k₂ and m.

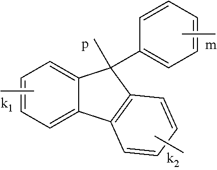

(2-4-6-3)

Some specific examples of the unit structures C of the formula (V) (unit structures equivalent to composite unit structures A-B) are illustrated below. * indicates a bonding site to the unit structure A.

While the unit structures C have, on any of the aromatic rings in the structure, a valence bond that bonds to the unit structure B, the specific examples below omit such a valence bond. It is needless to mention that the illustrated structures may be part of the whole unit structure.

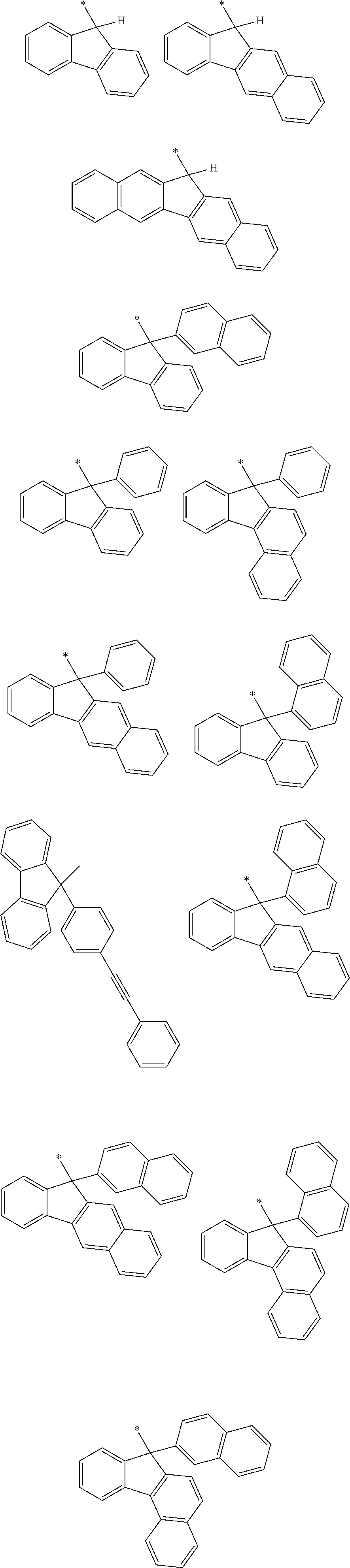

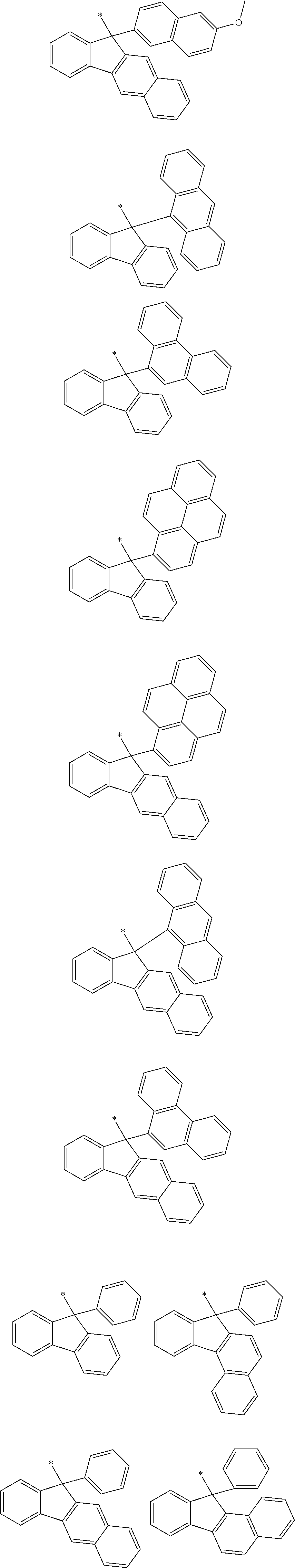

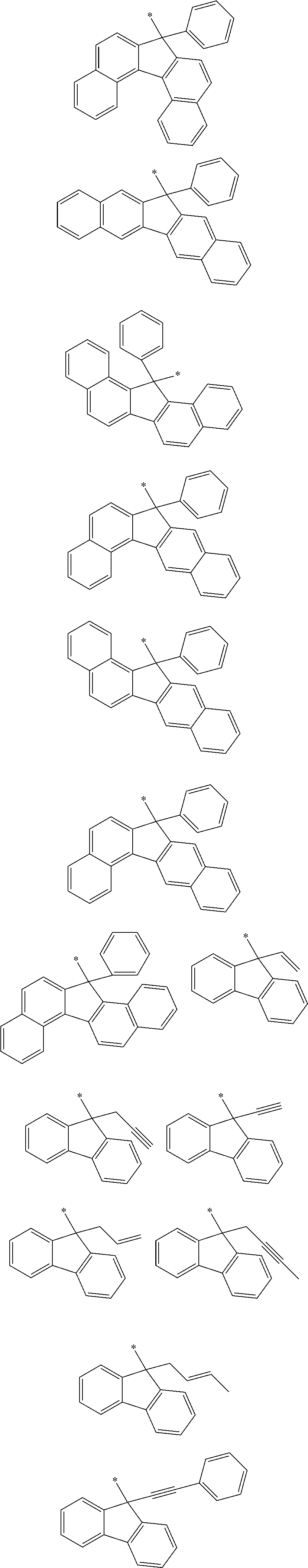

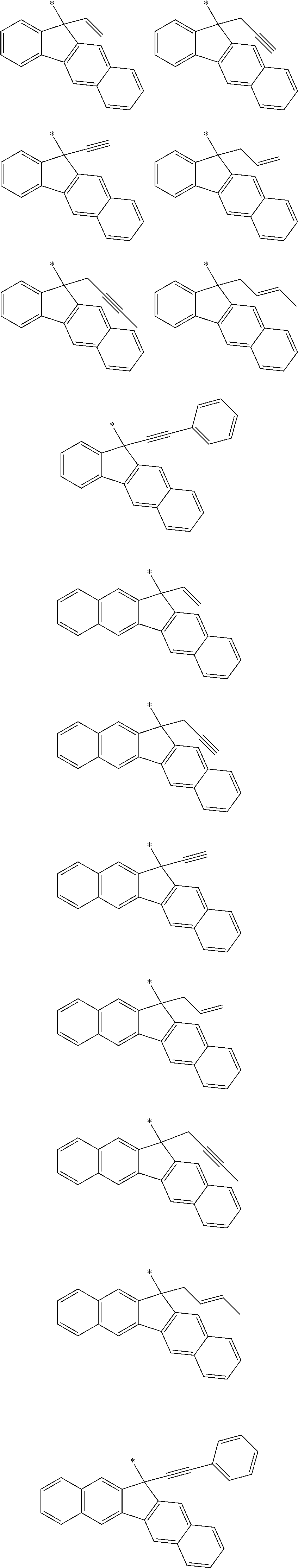

The above specific illustrations without the valence bond on the aromatic ring can serve as specific examples of the polymer terminals.

(2-4-7)

At a polymer terminal, the unit structure B forms a covalent bond with a polymer terminal group. The polymer terminal group may or may not be an aromatic ring derived from the unit structure A.

Examples of the polymer terminal groups include optionally substituted C6-C30 aromatic ring residues, optionally substituted C1-C10 unsaturated hydrocarbon groups, hydroxyl group, and hydrogen atom.

### (2-5. Novolac Resin Synthesis Methods)

The novolac resin according to an aspect of the present invention may be prepared by a known method.

For example, the novolac resin may be prepared by condensing an aromatic ring-containing compound represented by H-A-H with an oxygen-containing compound represented by, for example, OHC—B, O═C—B, HO—B—OH, or RO—B—OR. In the above formulas, -A- corresponds to a unit structure A, —C(B)— or —B— corresponds to a unit structure B, and R denotes an alkyl group having about 1 to 3 carbon atoms. The aromatic ring-containing compound and the oxygen-containing compound may be each a single compound or a combination of two or more compounds. In the condensation reaction, the oxygen-containing compound may be used in an amount of 0.1 to 10 mol, preferably 0.1 to 2 mol, per mol of the aromatic ring-containing compound.

A catalyst may be used in the condensation reaction, with examples including mineral acids, such as sulfuric acid, phosphoric acid, and perchloric acid, organic sulfonic acids, such as p-toluenesulfonic acid, p-toluenesulfonic acid monohydrate, methanesulfonic acid, and trifluoromethanesulfonic acid, and carboxylic acids, such as formic acid and oxalic acid. The amount in which the catalyst is used varies depending on the type of the catalyst used, but is usually 0.001 to 10,000 parts by mass, preferably 0.01 to 1,000 parts by mass, and more preferably 0.05 to 100 parts by mass with respect to 100 parts by mass of the aromatic ring-containing compound (when plural, the total of the aromatic ring-containing compounds).

The condensation reaction may be carried out without a solvent but is usually performed using a solvent. The solvent is not particularly limited as long as it can dissolve the reaction substrates and does not inhibit the reaction. Examples include 1,2-dimethoxyethane, diethylene glycol dimethyl ether, propylene glycol monomethyl ether, propylene glycol monomethyl ether acetate, tetrahydrofuran, tetrahydropyran, 4-methyltetrahydropyran, dioxane, 1,2-dichloromethane, 1,2-dichloroethane, toluene, N-methylpyrrolidone, and dimethylformamide. The condensation reaction temperature is usually 40° C. to 200° C., and preferably 100° C. to 180° C. The reaction time varies depending on the reaction temperature but is usually 5 minutes to 50 hours, and preferably 5 minutes to 24 hours.

The weight average molecular weight of the novolac resin according to an aspect of the present invention is usually 500 to 100,000, preferably 600 to 50,000, 700 to 10,000, or 800 to 8,000.

### 3. Resist Underlayer Film Forming Compositions [7]]

(3-1)

A resist underlayer film forming composition according to an aspect of the present invention includes a thermal acid generator, a self-crosslinkable polymer [1], and a solvent. The composition may optionally further contain a crosslinking agent and a surfactant.

The self-crosslinkable polymer [1] is as described in [2. Self-crosslinkable polymers [1]] hereinabove.

### (3-2: Thermal Acid Generators)

(3-2-1)

Any thermal acid generator may be used as long as the advantageous effects of the present invention are not impaired. Preferably, a thermal acid activator of formula (1) below may be used.

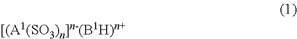

In the formula (1),

A¹ is an optionally substituted, linear, branched, or cyclic, saturated or unsaturated, aliphatic hydrocarbon group, or an optionally substituted aromatic ring residue, and is preferably a methyl group, a trifluoromethyl group, a naphthyl group, a norbornanylmethyl group, a dimethylphenyl group, or a tolyl group.

Here, the “aromatic ring” and the “residue” are as described in (1-3) and (1-2), respectively.

In the formula (1), n indicates the number of the sulfonate anion groups and is 1 or 2, preferably 1.

In the formula (1), B¹ denotes one, or two or more kinds of counter bases and is a monoacidic base or a monoacidic base moiety of a diacidic base or a triacidic base. When B¹ is a diacidic base or a triacidic base, the structure is such that two or three moieties each corresponding to B¹ are covalently bonded to one another.

A¹ and B¹ may be connected via a single bond or a linking group. Among the counter base or bases B¹, at least one or more bases preferably have a higher pKa than pyridine.

Specific examples of the bases having a higher pKa than pyridine, preferably a pKa of 6.5 or more, in the present invention include N-methylmorpholine, N,N-diethylaniline, N-isobutylmorpholine, and N-allylmorpholine.

For example, pKa may be measured by potentiometric titration [see, for example, S. Xu et al., “Dissociation constants of alkanolamines”, Can. J. Chem. 71, 1048 (1993)] in water, preferably in water at 25° C. The values of pKa thus measured are compared. Reference may be made to other literature, such as R. Linnell, J. Org. Chem. 1960, 25, 2, 290-290; “Dai Yuukikagaku Bekkan 2 (Great Organic Chemistry, Special Volume 2), Yuukikagaku Teisuu Binran (Handbook of constants in organic chemistry)”, supervised by Munio Kotake, p. 584 (1963), (Asakura Publishing Co., Ltd.); H. K. Hall Jr. et al., Tetrahedron Letters 53 (2012) 1830-1832.

(3-2-2)

The counter base or bases B¹ in the formula (1) described in (3-2-1) are preferably each R^{I}R^{II}R^{III}N

[wherein
R^{I} and R^{II} each independently denote a hydrogen atom, an optionally substituted, linear or branched, saturated or unsaturated, aliphatic hydrocarbon group,
R^{I} and R^{II} optionally form a ring together via a heteroatom or without a heteroatom, or optionally form a ring together via an aromatic ring, and the heteroatom is preferably an oxygen atom, a nitrogen atom, or a sulfur atom,
R^{III} denotes a hydrogen atom, an optionally substituted aromatic ring residue, or an optionally substituted, linear or branched, saturated or unsaturated, aliphatic hydrocarbon group, and
when R^{I} and R^{II} do not form a ring together, R^{III} is a hydrogen atom or an optionally substituted aromatic ring residue].

The counter base or bases B¹ in the formula (1) of the component (a) are more preferably each a base represented by:

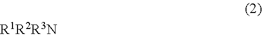

[in the formula (2),
R¹ and R² each independently denote an optionally substituted, linear or branched, saturated or unsaturated, aliphatic hydrocarbon group, and
R³ denotes a hydrogen atom or an optionally substituted aromatic group, and preferably denotes an optionally substituted phenyl, naphthyl, anthracenyl, pyrenyl, or phenanthrenyl group] or
a cyclic amine compound represented by formula (3) below:

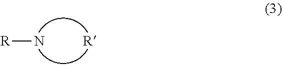

[in the formula (3),
R is:
   a hydrogen atom;
   a nitro group, a cyano group, an amino group, a carboxyl group, a hydroxyl group, an amide group, an aldehyde group, a (meth)acryloyl group, a halogen atom (for example, a fluorine atom, a chlorine atom, a bromine atom, or an iodine atom), or a C1-C10 alkyl group, a C2-C10 alkenyl group, a C2-C10 alkynyl group, a C1-C10 hydroxyalkyl group, a C6-C40 aryl group, an ether bond-containing organic group, a ketone bond-containing organic group, or an ester bond-containing organic group each of which is optionally substituted with a C1-C10 alkoxy group; or
   a group including a combination of the above groups, and
R′ is an aromatic ring condensed with a ring in the cyclic amine in the formula (3) or is:

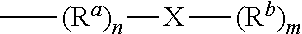

wherein R^{a} and R^{b} each independently denote an optionally substituted alkylene group,
X is O, S, SO₂, CO, CONH, COO, or NH, and
n and m are each independently 2, 3, 4, 5, or 6].

R in the formula (3) is preferably a hydrogen atom, a methyl group, an ethyl group, an isobutyl group, an allyl group, or a cyanomethyl group.

Furthermore, R′ in the formula (3) is preferably represented by:

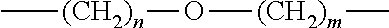

wherein n and m are each independently 2, 3, 4, 5, or 6.
(3-2-3)

Examples of the “linear or branched, saturated aliphatic hydrocarbon group” in the definition of A¹ in the formula (1) described in (3-2-1), or in the definitions of R^{I}, R^{II}, and R^{III} in R^{I}R^{II}R^{III}N or in the definitions of R¹ and R² in R¹R²R³N described in (3-2-2) include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

Examples of the “cyclic saturated aliphatic hydrocarbon group” for A¹ in the formula (1) described in (3-2-1) include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

Examples of the “linear or branched, unsaturated aliphatic hydrocarbon group” in the definition of A¹ in the formula (1) described in (3-2-1), in the definitions of R^{I}, R^{II} and R^{III} in R^{I}R^{II}R^{III}N described in (3-2-2), or in the definitions of R¹ and R² in the formula (2) include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, and 1-i-propyl-2-propenyl group.

Examples of the “cyclic unsaturated aliphatic hydrocarbon group” in the definition of A¹ in the formula (1) described in (3-2-1) include 1-cyclopentenyl group, 2-cyclopentenyl group, 3-cyclopentenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

The “aromatic ring residue” in the definition of A¹ in the formula (1) described in (3-2-1) or in the definition of R in the formula (3) described in (3-2-2) may be an aromatic hydrocarbon group, with examples including phenyl group, o-methylphenyl group, m-methylphenyl group, p-methylphenyl group, 2,3-dimethylphenyl group, 2,4-dimethylphenyl group, 2,5-dimethylphenyl group, 2,6-dimethylphenyl group, 3,4-dimethylphenyl group, 3,5-dimethylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, 9-phenanthryl group, 1-pyrenyl group, 2-pyrenyl group, and 3-pyrenyl group.

Furthermore, the “aromatic ring residue” in the definition of A¹ in the formula (1) described in (3-2-1) may be an aromatic heterocyclic ring residue, with examples including furanyl group, thiophenyl group, pyrrolyl group, imidazolyl group, pyranyl group, pyridinyl group, pyrimidinyl group, pyrazinyl group, pyrrolidinyl group, piperidinyl group, piperazinyl group, morpholinyl group, quinuclidinyl group, indolyl group, purinyl group, quinolinyl group, isoquinolinyl group, chromenyl group, thianthrenyl group, phenothiazinyl group, phenoxazinyl group, xanthenyl group, acridinyl group, phenazinyl group, and carbazolyl group.

Examples of the “aromatic ring” or the “aromatic ring” in the definition of Rui in R^{I}R^{II}R^{III}N or in the definition of R³ in R¹R²R³N are the same as described above.

In the definition of A¹ in the formula (1) described in (3-2-1), in the definitions of R^{I}, R^{II}, and R^{III} in R^{I}R^{II}R^{III}N described in (3-2-2), in the definitions of R¹, R², and R³ in the formula (2) described in (3-2-2), or in the definitions of R^{a} and R^{b} described in (3-2-2), the phrase “optionally substituted” means that a substituent may be present. Examples thereof include nitro group, amino group, cyano group, sulfo group, hydroxyl group, carboxyl group, aldehyde group, propargylamino group, propargyloxy group, halogen atoms, C1-C10 alkoxy groups, C1-C10 alkyl groups, C2-C10 alkenyl groups, C2-C10 alkynyl groups, C6-C40 aryl groups, ether bond-containing organic groups, ketone bond-containing organic groups, ester bond-containing organic groups, and combinations thereof.

The ether bond-containing organic groups, the ketone bond-containing organic groups, and the ester bond-containing organic groups may be exemplified by the groups described later in (3-2-4).

Examples of the “alkoxy group” in the definition of R in the formula (3) described in (3-2-2) include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

Examples of the “alkylene group” in the definition of R in the formula (3) or in the definitions of R^{a} and R^{b} described in (3-2-2) include alkylene groups derived from the alkyl groups described as the “linear or branched, saturated aliphatic hydrocarbon groups” and the “cyclic saturated aliphatic hydrocarbon groups” in this section (3-2-3) by replacing a hydrogen atom with an additional valence bond.

Examples of the “alkenyl group” in the definition of R in the formula (3) described in (3-2-2) include the “linear or branched, unsaturated aliphatic hydrocarbon groups” and the “cyclic unsaturated aliphatic hydrocarbon groups” described in this section (3-2-3).

Examples of the “hydroxyalkyl group” in the definition of R in the formula (3) described in (3-2-2) include the following organic groups. In the formulas, * indicates a valence bond on the carbon atom.

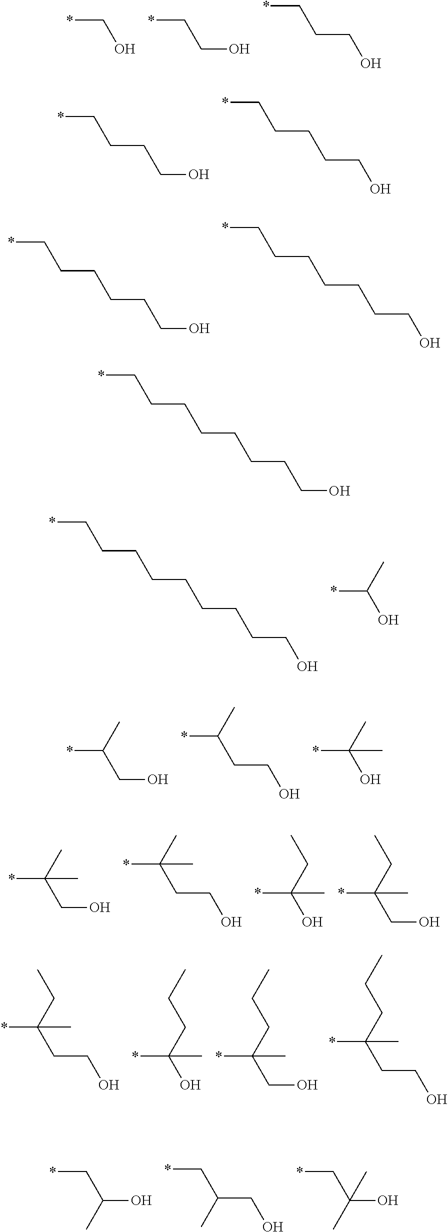

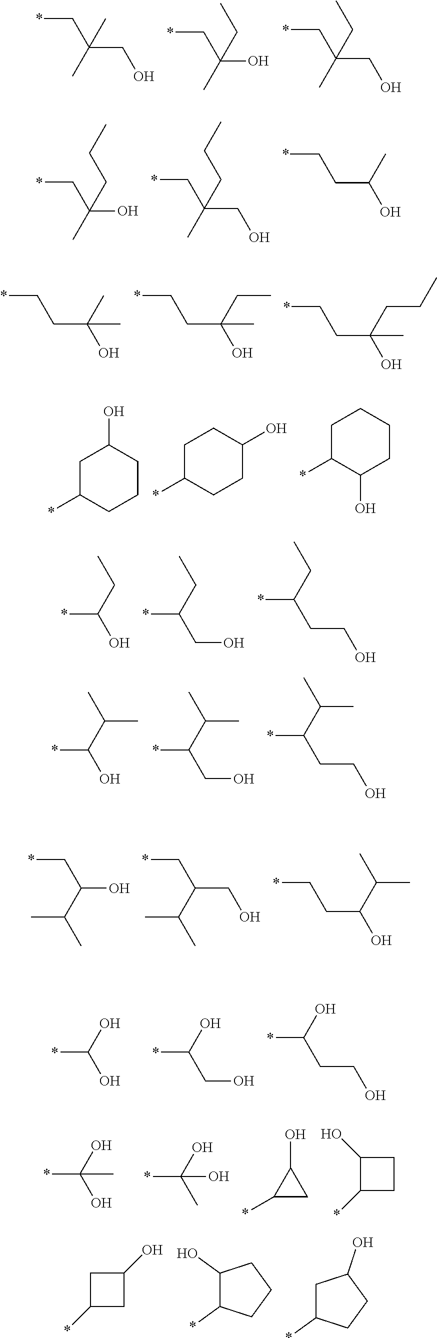

The “alkynyl group” in the definition of R in the formula (3) described in (3-2-2) may be such that an aliphatic hydrocarbon chain contains a carbon-carbon triple bond (at an end of the chain or in the middle of the chain) and optionally further contains a heteroatom (such as an oxygen atom or a nitrogen atom) or may be such that a plurality of alkynyl groups are connected to one another. Examples include the following organic groups. In the formulas, * indicates a valence bond on the carbon atom.

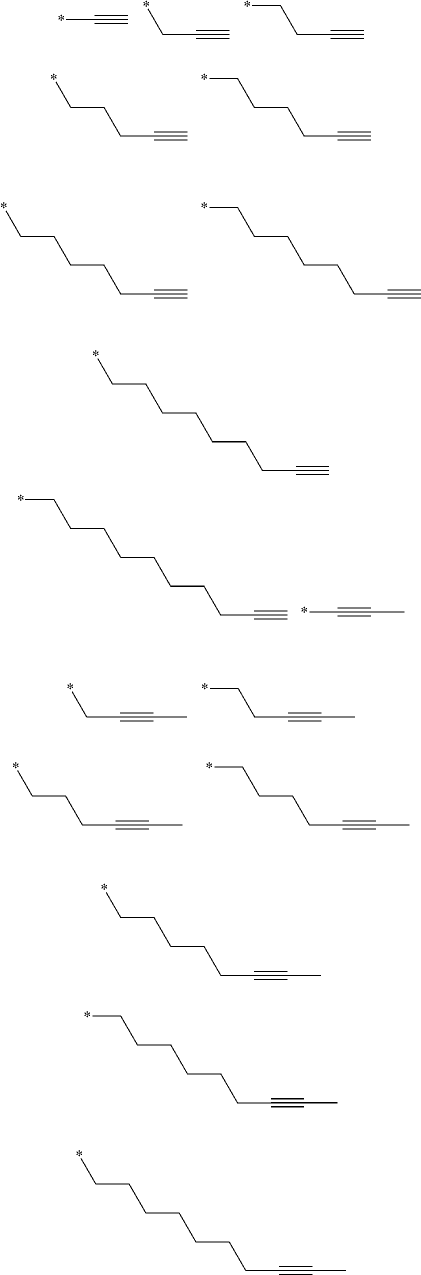

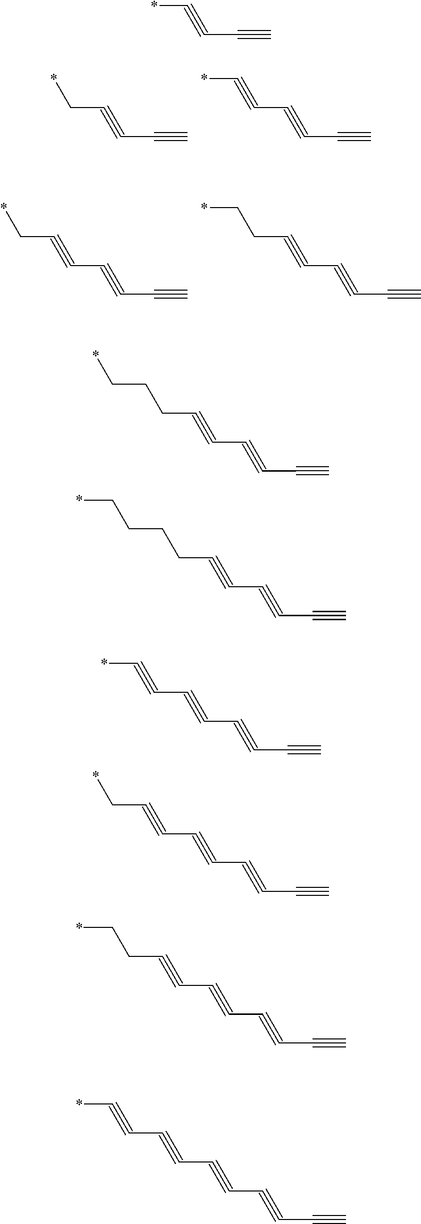

The following examples show embodiments in which a heteroatom is bonded in the middle of the chain of R.

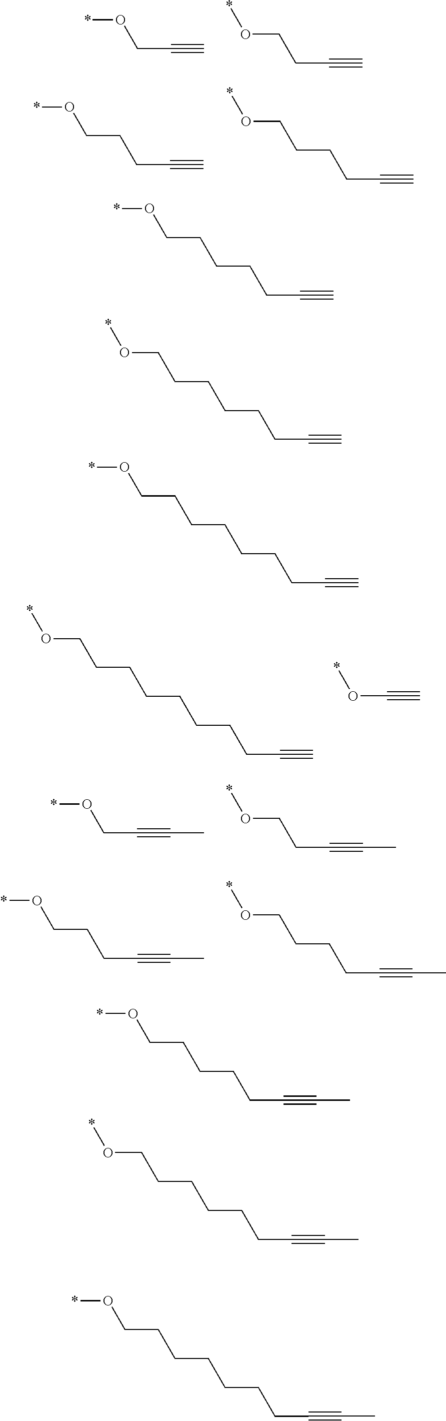

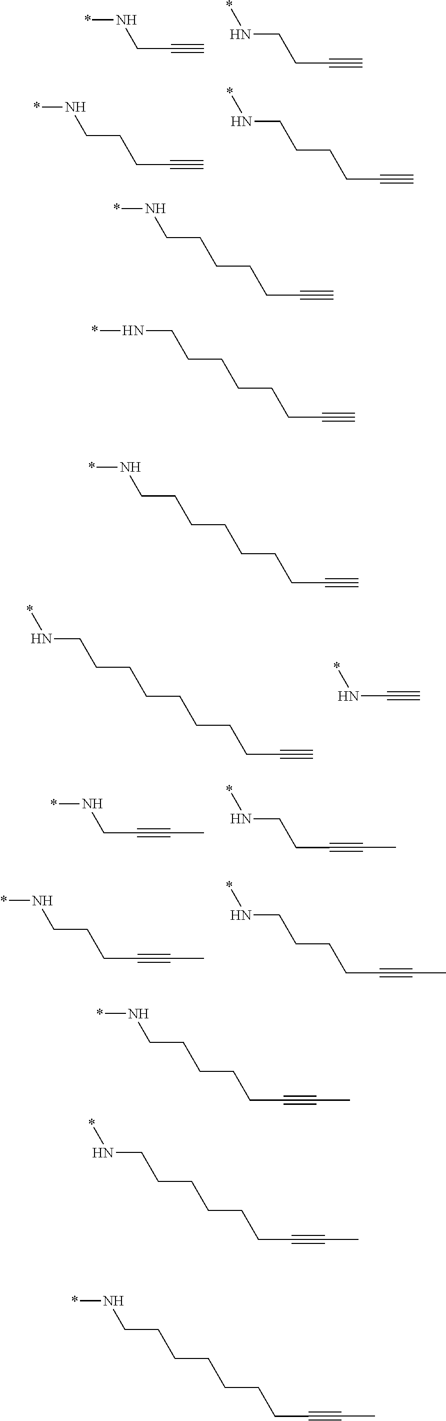

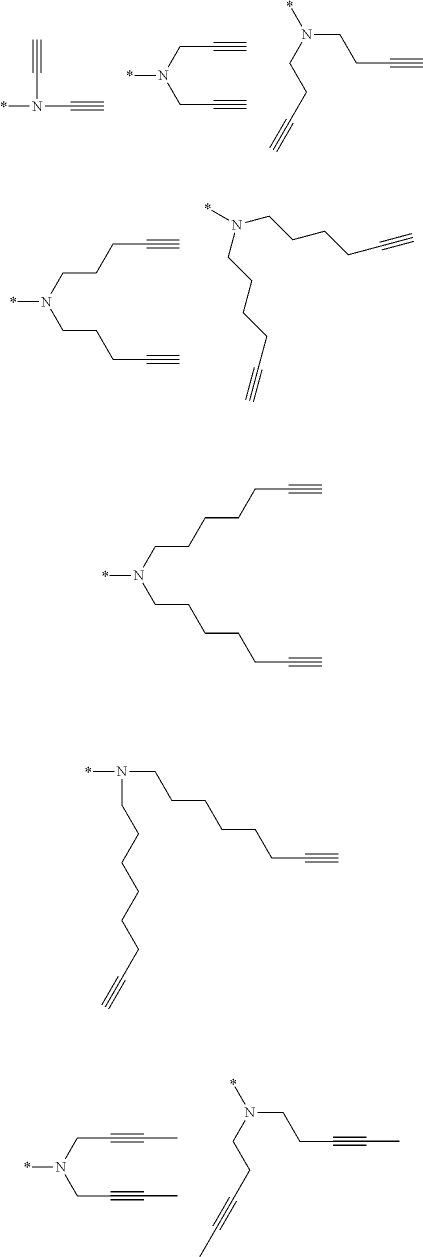

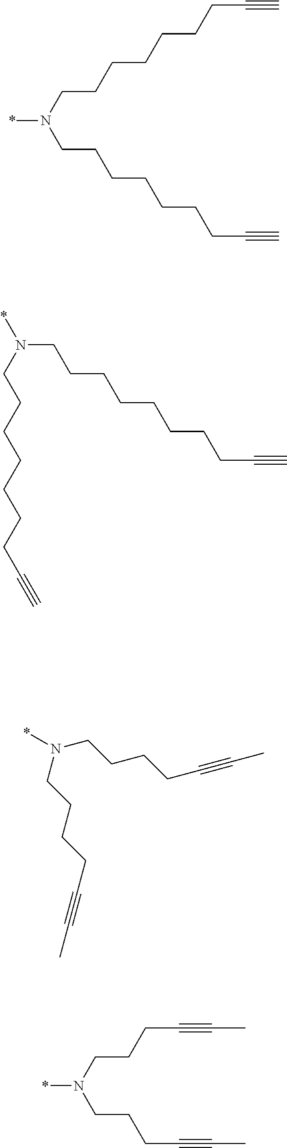 [SMILES: *N(CCCCCCCC#C)CCCCCCCC#C ; *N(CCCCCCCC#C)CCCCCCCCC#C ; *N(CCCCC#CC)CCCCC#CC ; *N(CCCC#CC)CCCC#CC]

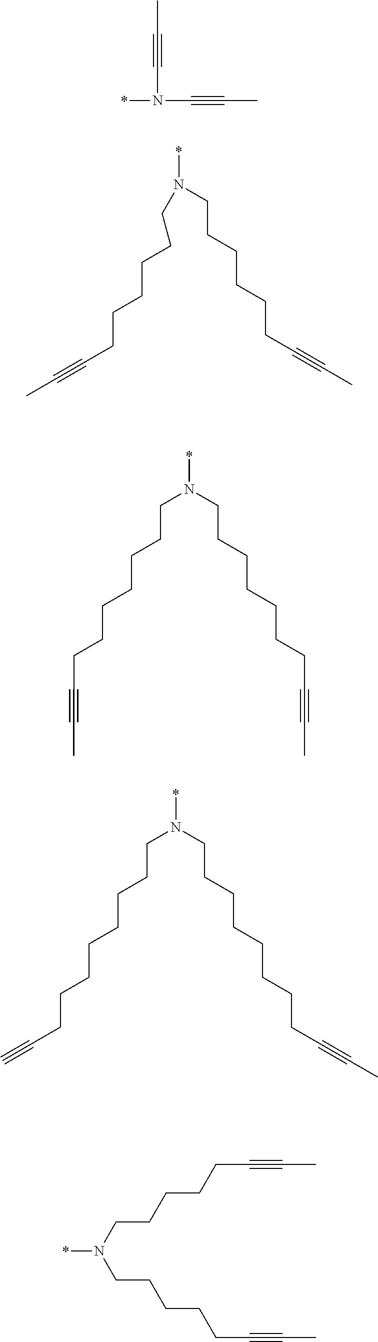

(3-2-4)

The “ether bond-containing organic group” in the definition of R in the formula (3) described in (3-2-2) may be a residue of an ether compound represented by R¹¹—O—R¹¹ (R¹¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ether bond-containing organic groups include those containing a methoxy group, an ethoxy group, or a phenoxy group.

The “ketone bond-containing organic group” in the definition of R in the formula (3) described in (3-2-2) may be a residue of a ketone compound represented by R²¹—C(═O)—R²¹ (R²¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ketone bond-containing organic groups include those containing an acetoxy group or a benzoyl group.

The “ester bond-containing organic group” in the definition of R in the formula (3) described in (3-2-2) may be a residue of an ester compound represented by R³¹—C(═O)O—R³¹ (R³¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ester bond-containing organic groups include those containing a methyl ester, an ethyl ester, or a phenyl ester.

(3-2-5)

Examples of the thermal acid generators represented by the formula (1) include, but are not limited to, those that appropriately combine at least one of the exemplary counter base cations illustrated below and at least one of the exemplary sulfonate anions illustrated below so that the charges are neutralized.

### (3-2-5-1: Examples of Counter Base Cations)

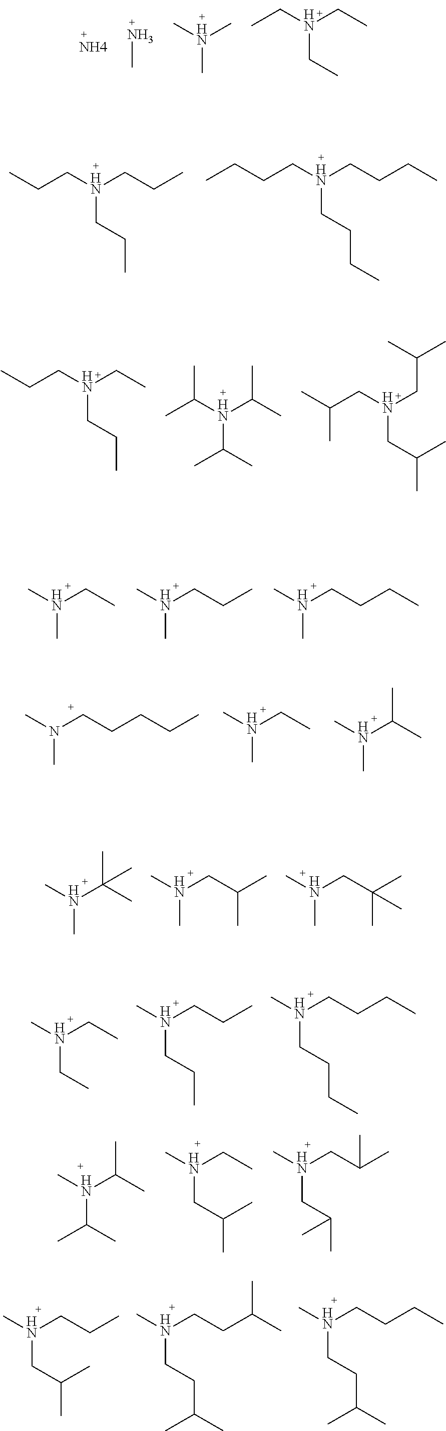

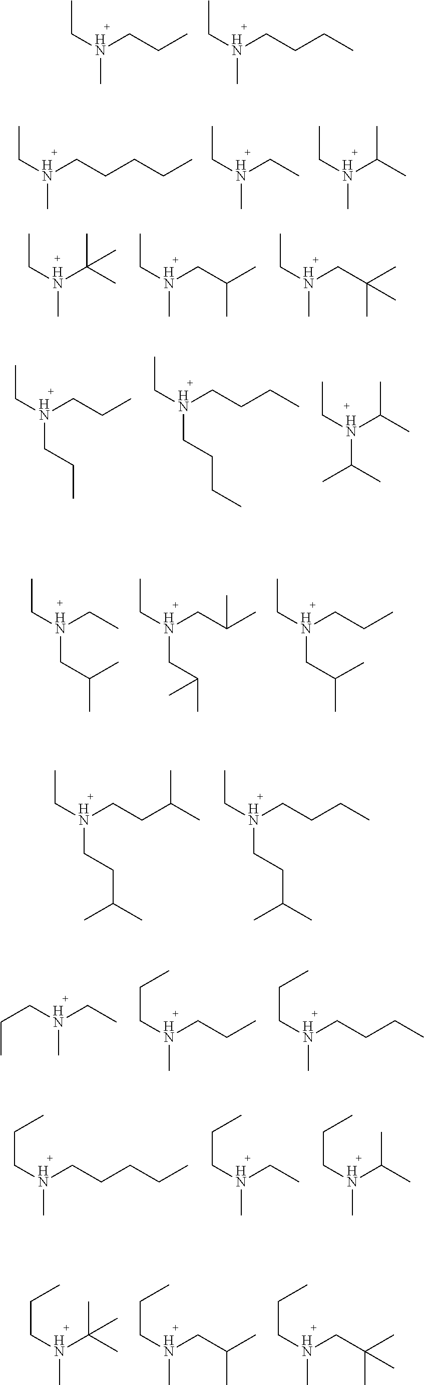

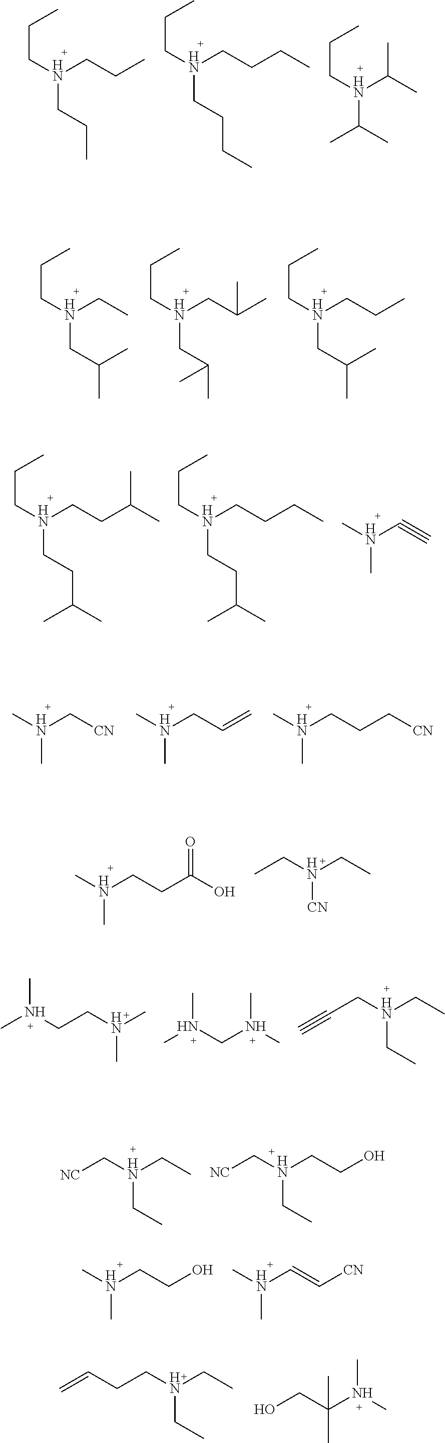

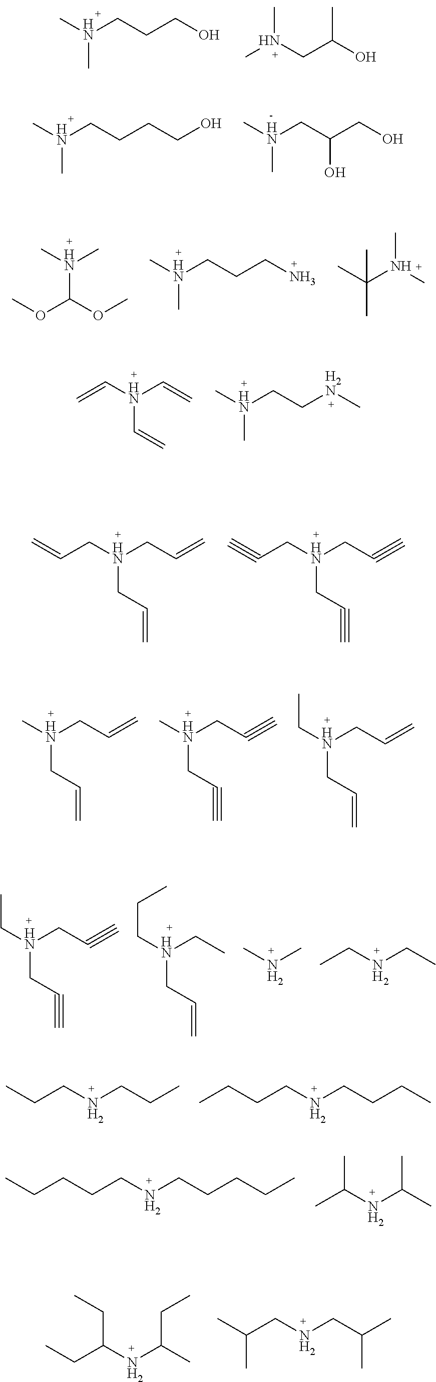

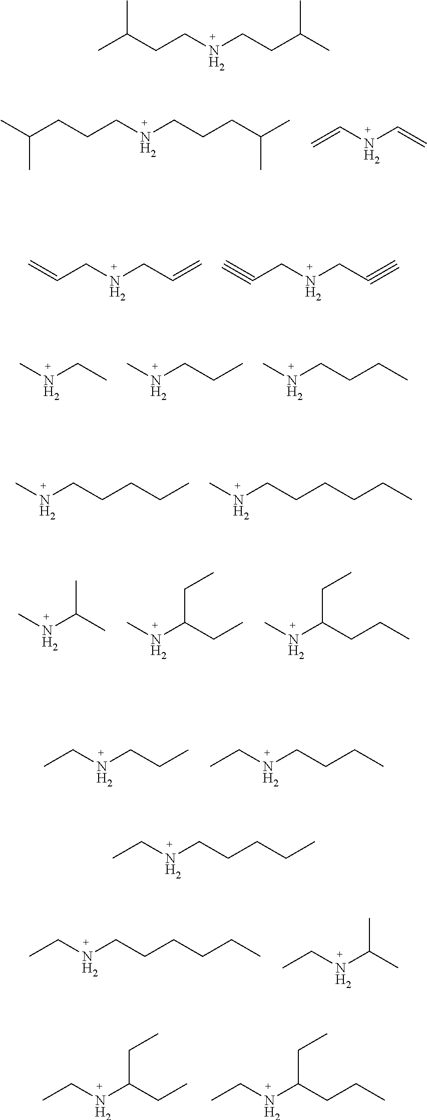

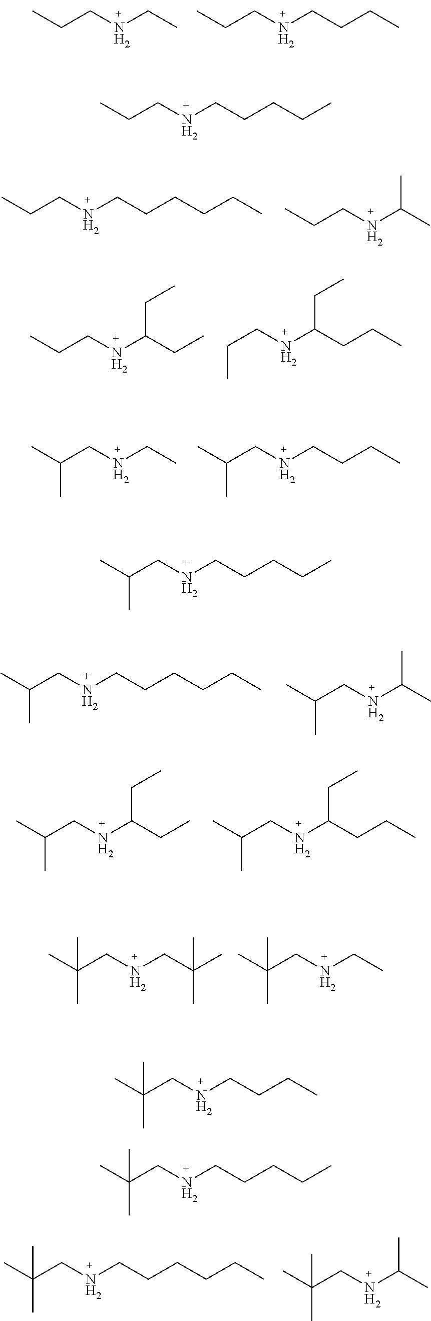

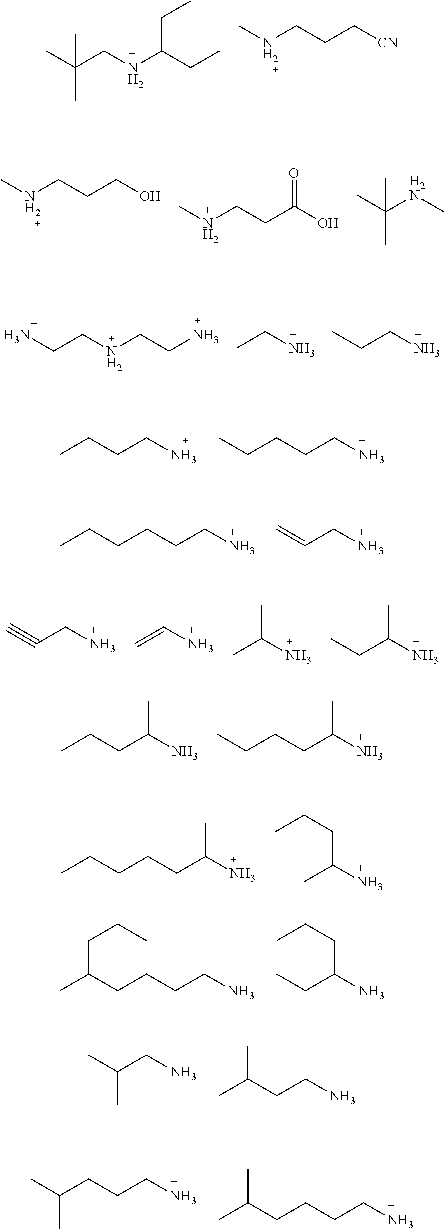

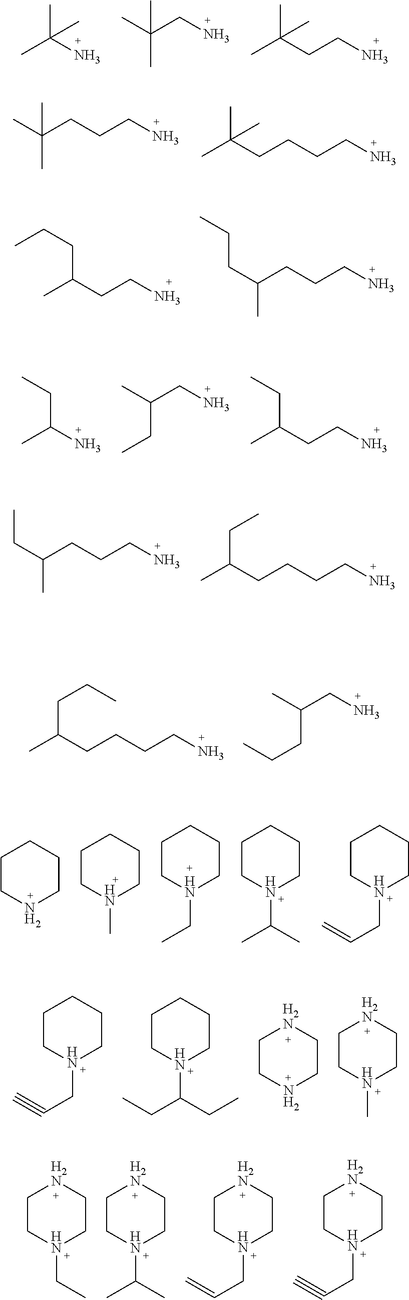

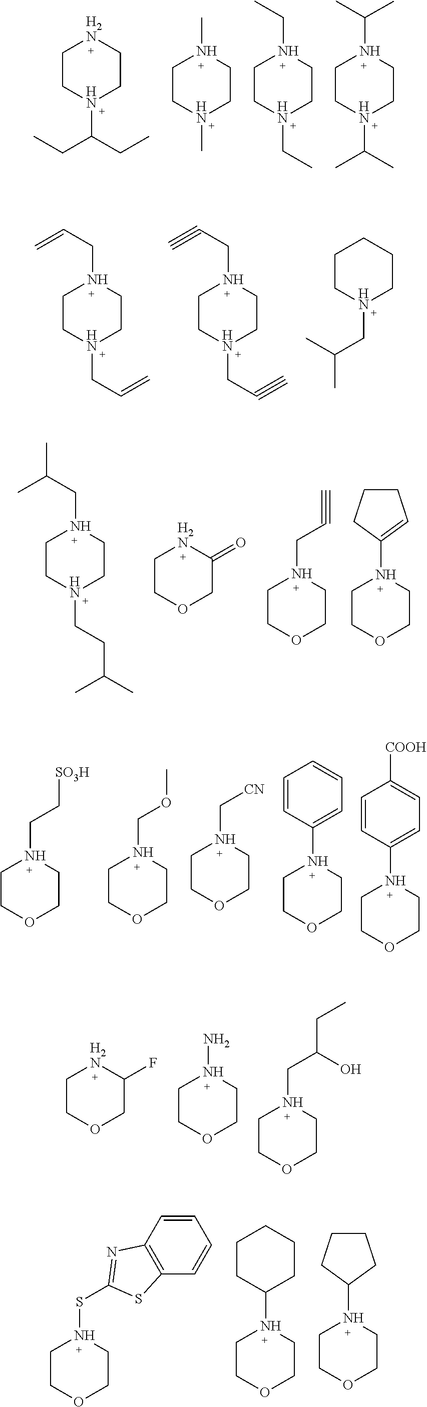

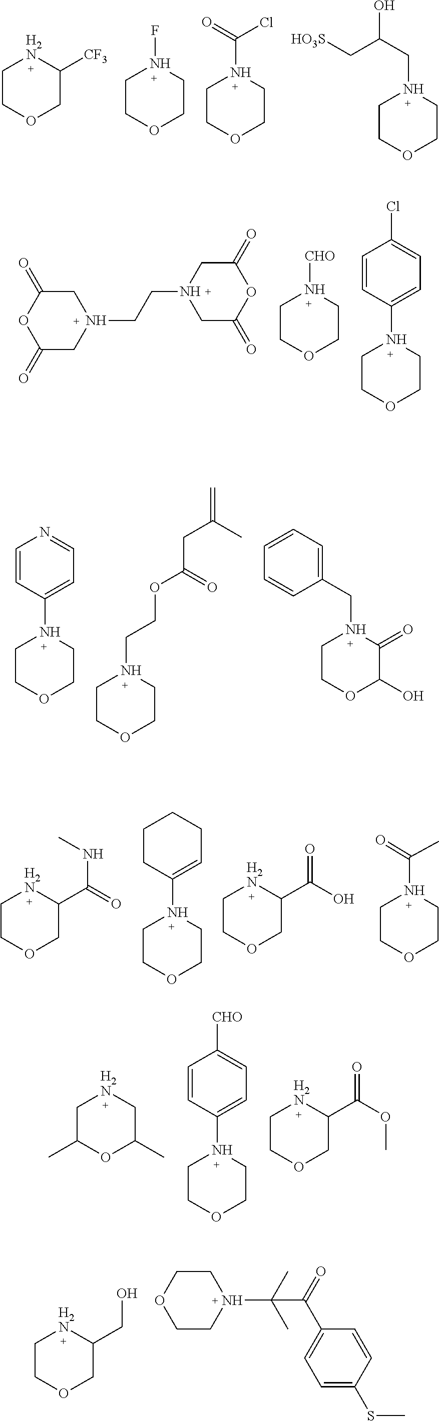

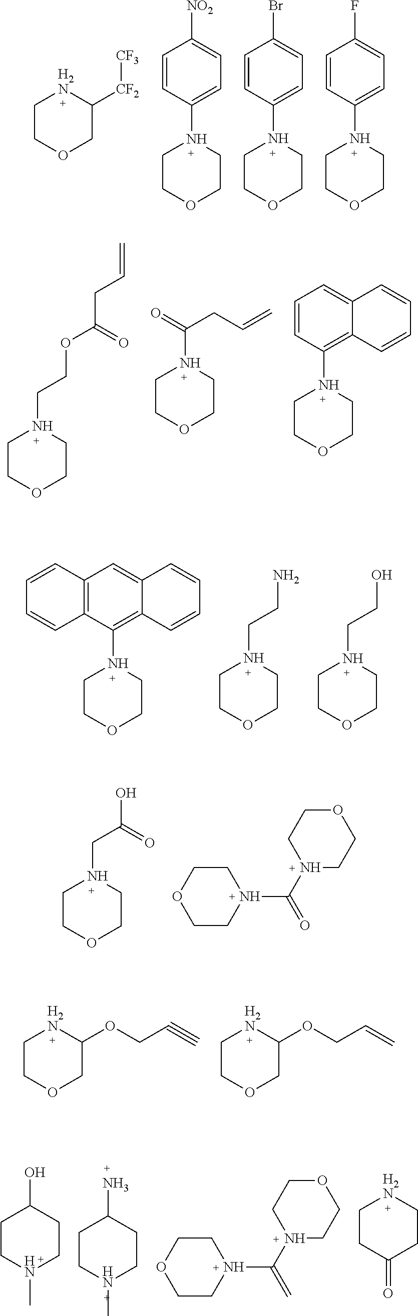

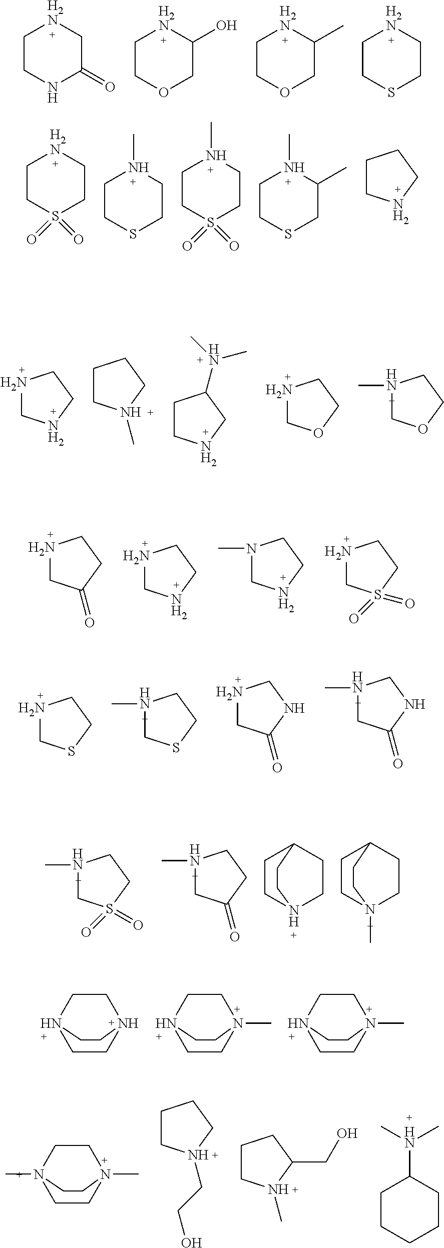

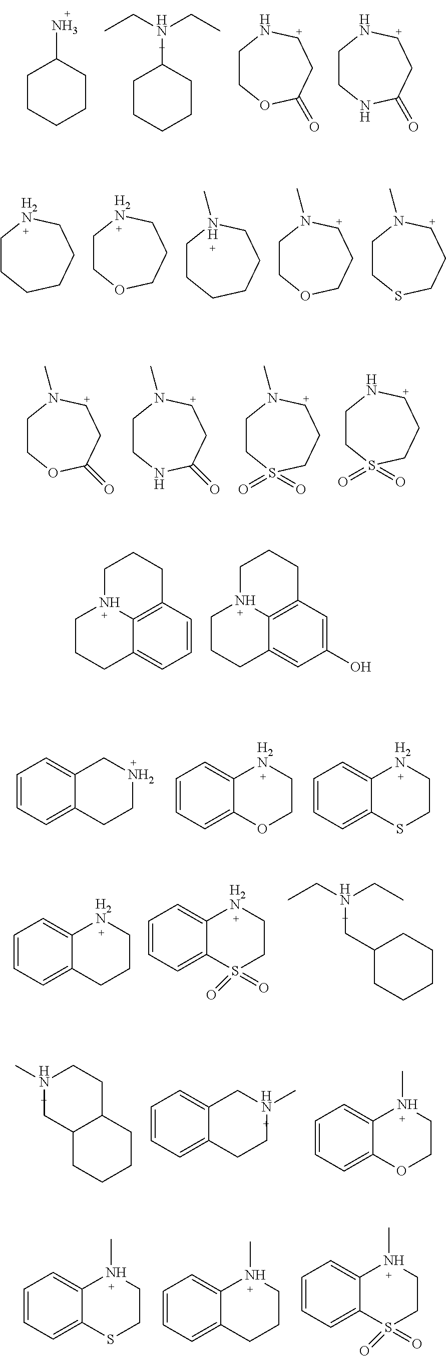

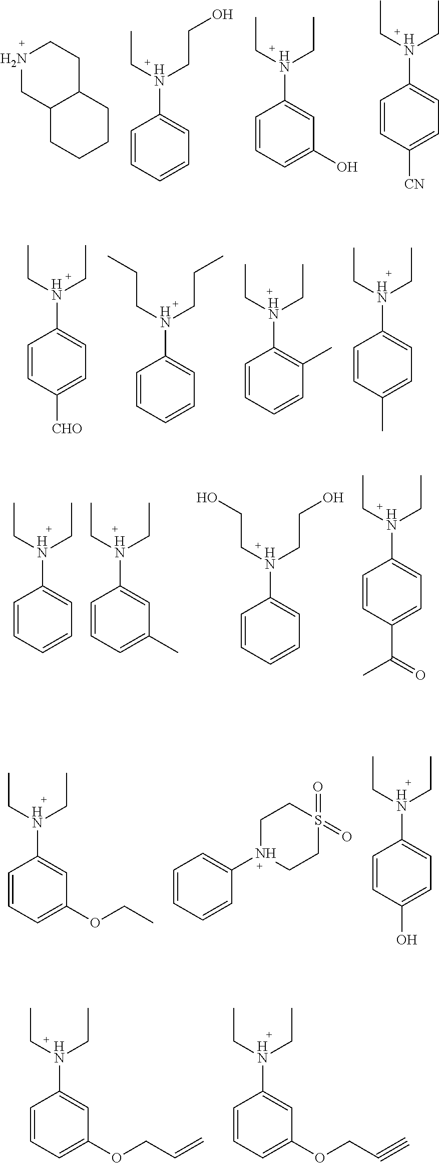

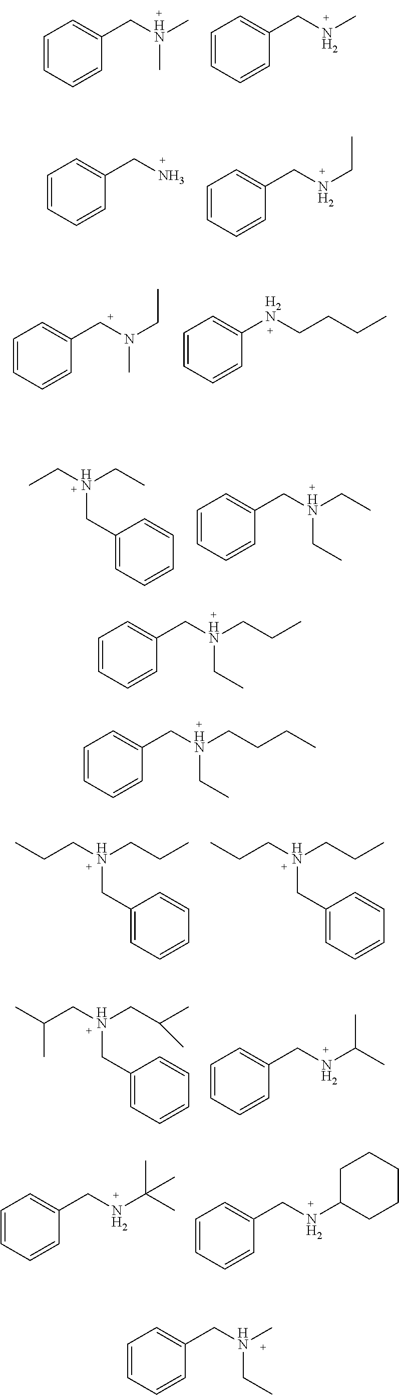

### (3-2-5-2: Examples of Sulfonate Anions)

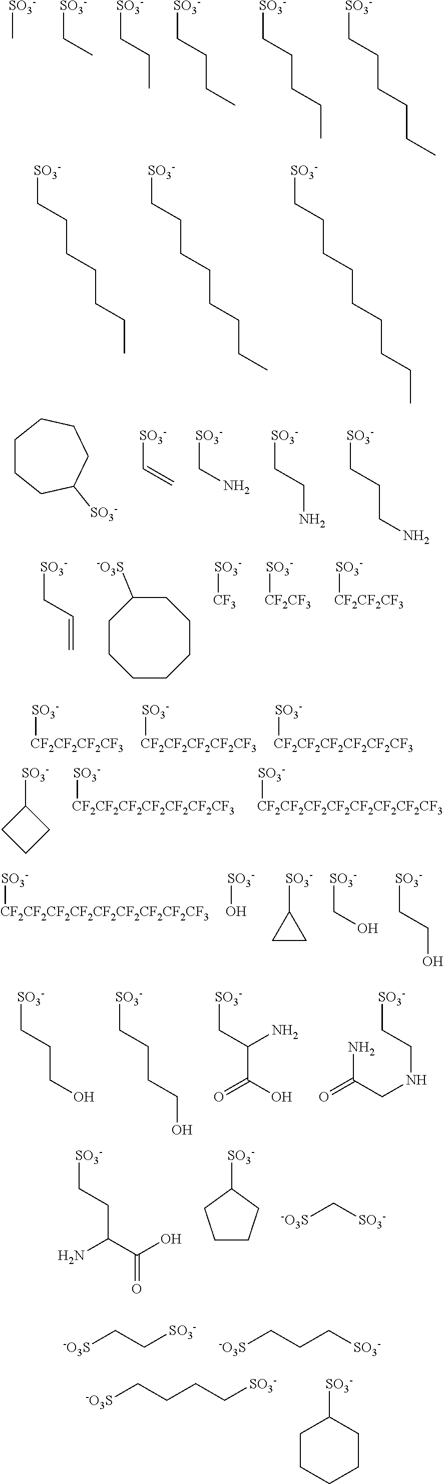

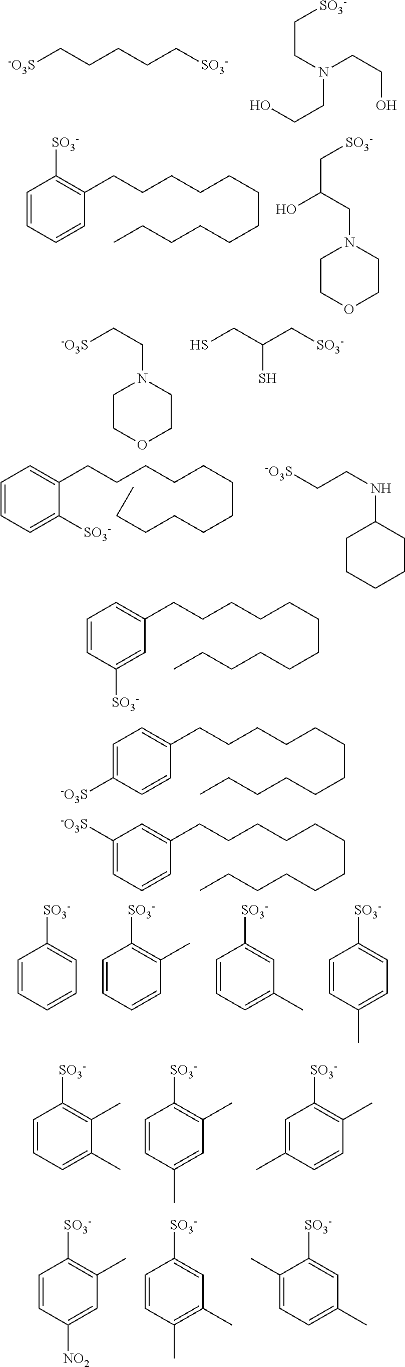

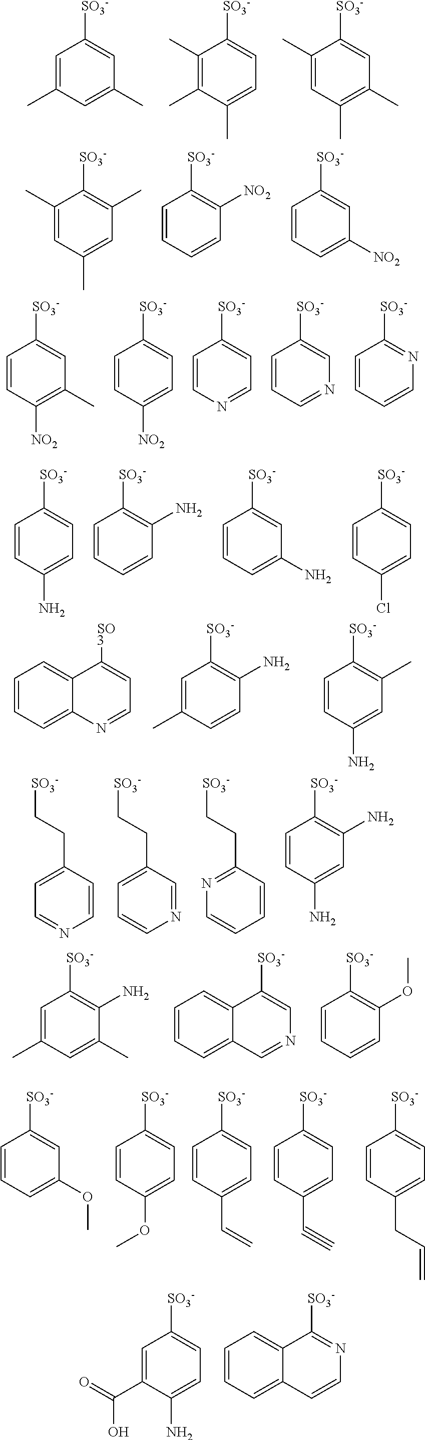

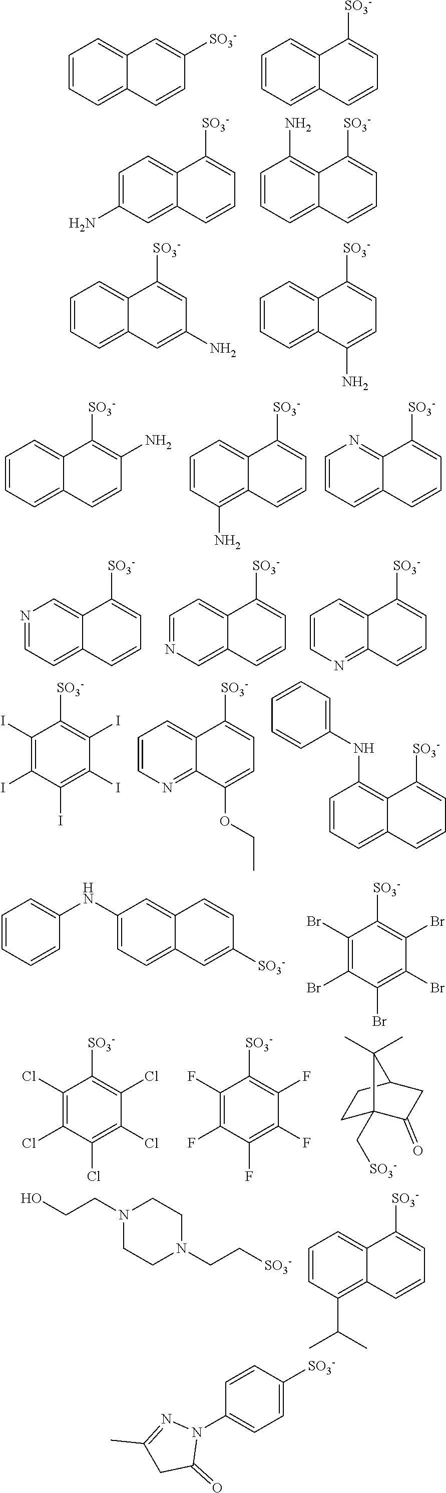

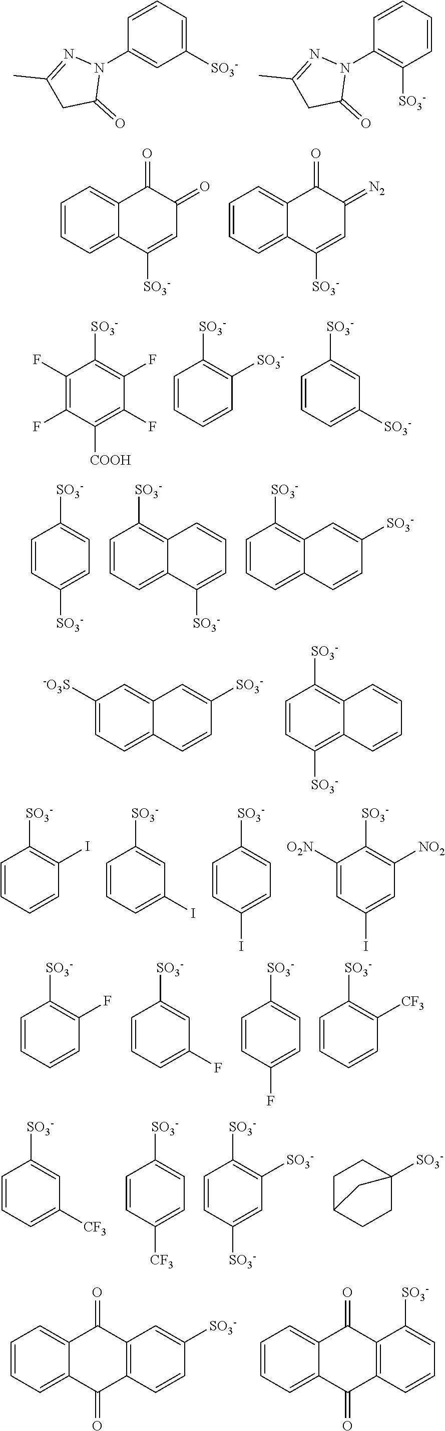

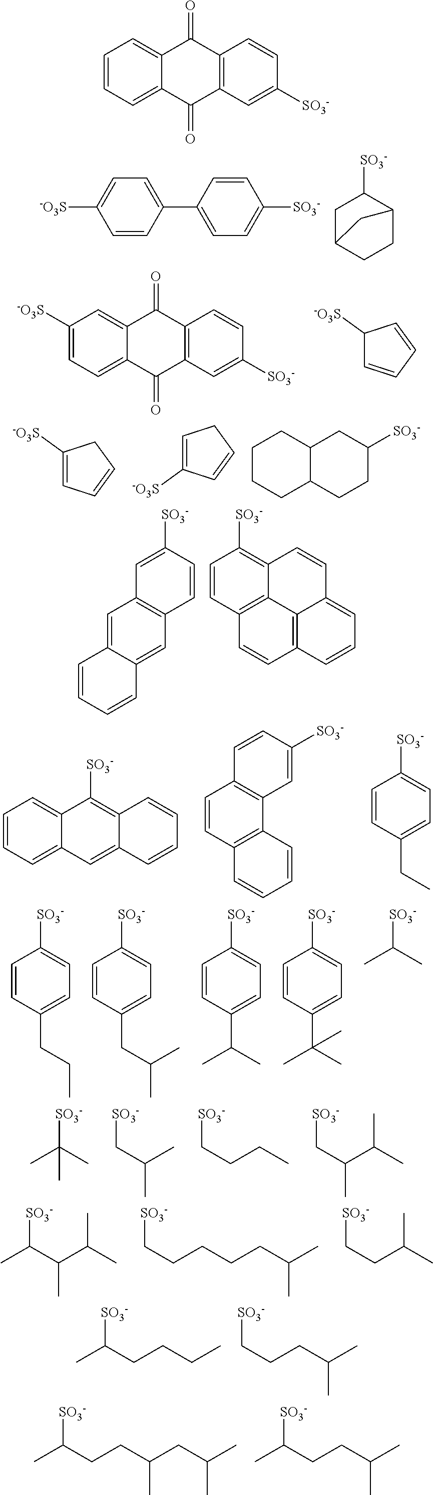

(3-2-6)

More specific examples of the thermal acid generators include, but are not limited to, the following combinations of a counter base cation and a sulfonate anion.

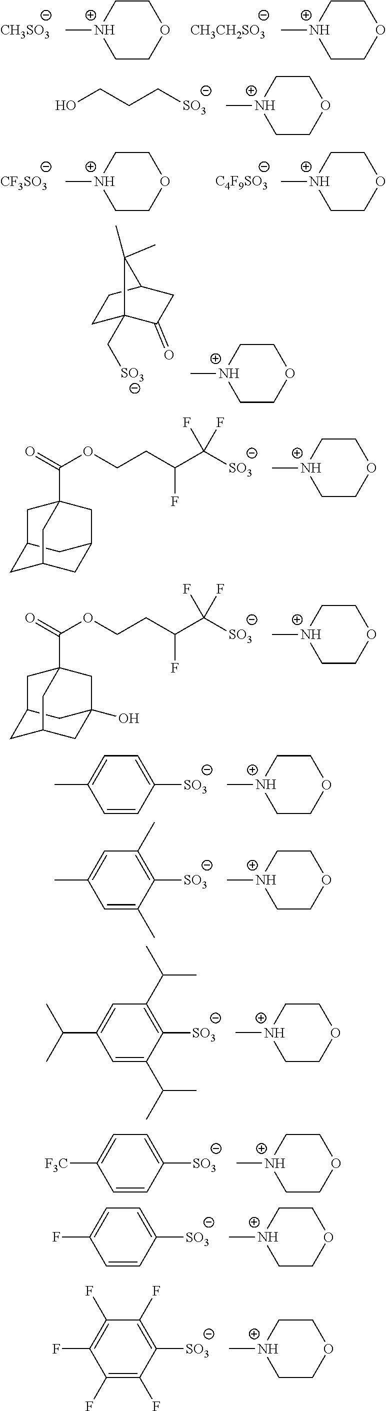

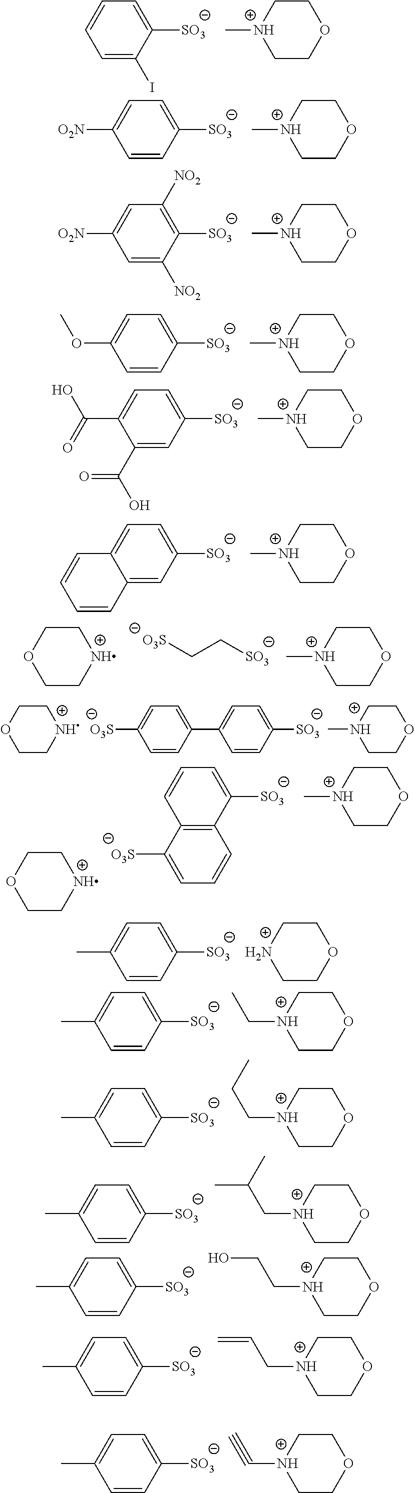

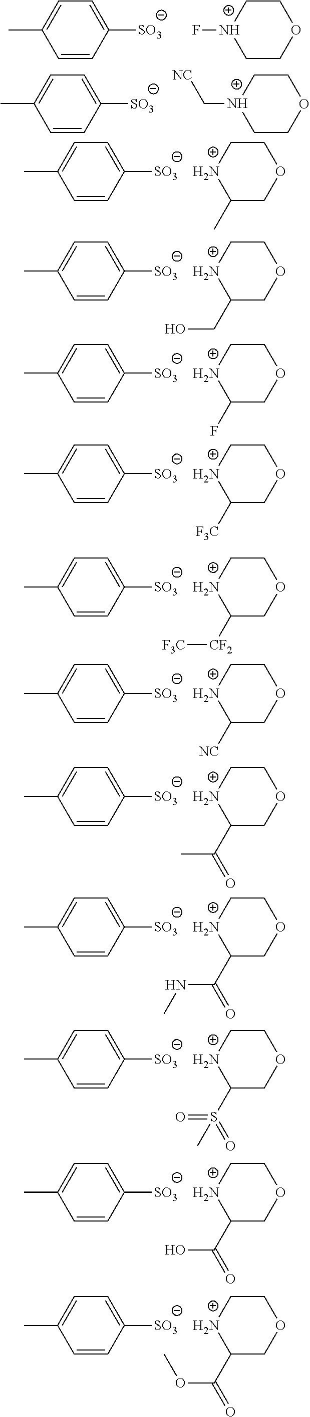

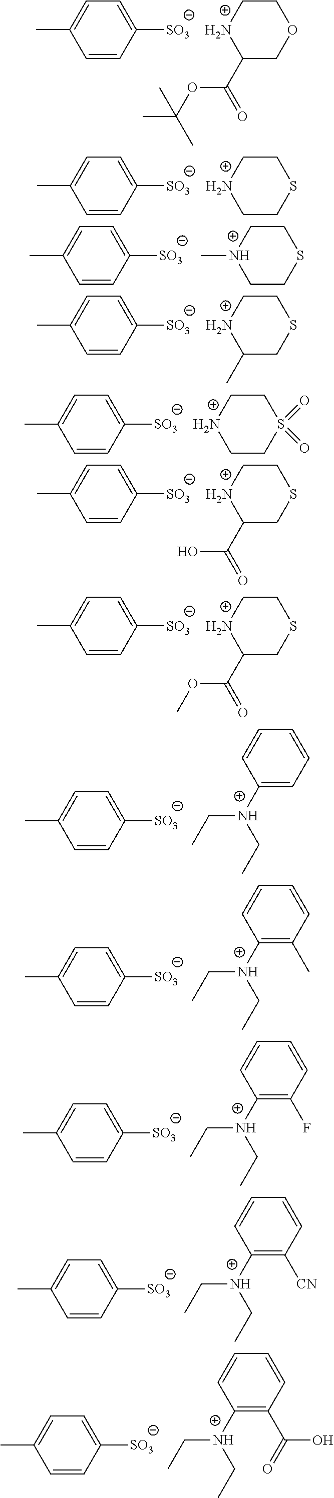

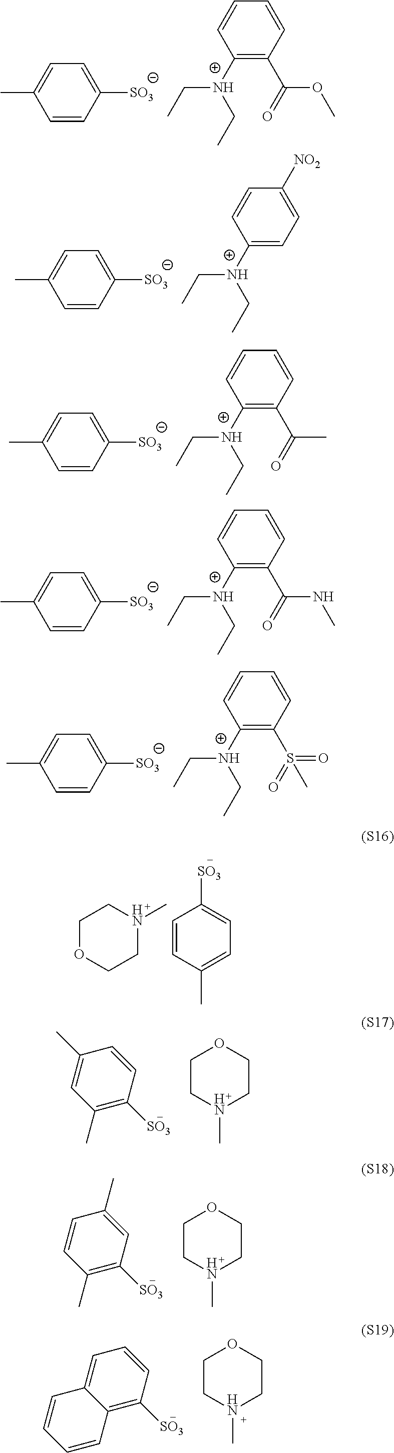

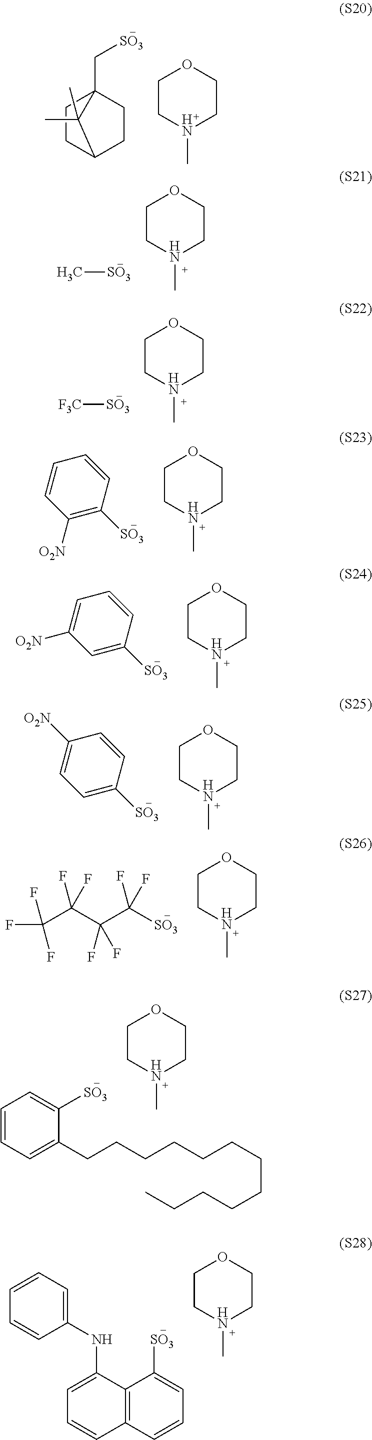

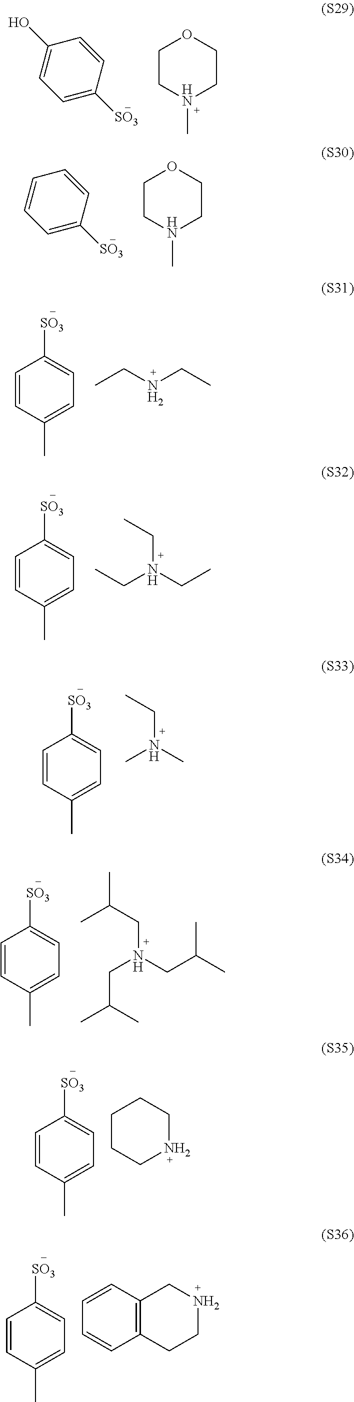

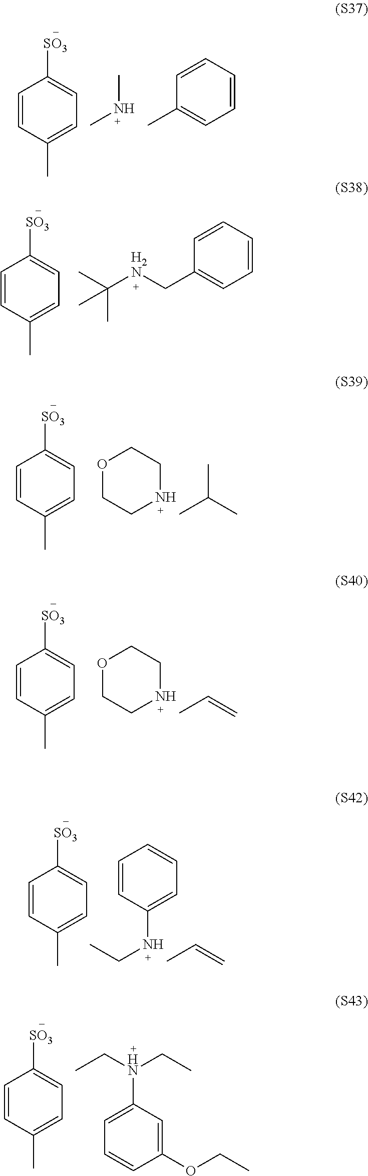

(3-2-7)

The amount of the thermal acid generator is 0.0001 to 20 mass %, preferably 0.0005 to 10 mass %, and more preferably 0.01 to 3 mass % based on the total solid content in the resist underlayer film forming composition.

In an embodiment of the thermal acid generator according to the present invention, the thermal decomposition onset temperature, that is, the thermal acid generation temperature is preferably 50° C. or above, more preferably 100° C. or above, and still more preferably 150° C. or above, and is preferably 400° C. or below.

### (3-3: Solvents)

(3-3-1)

The resist underlayer film forming composition according to an aspect of the present invention includes a solvent.

The solvent is not particularly limited as long as it can dissolve the thermal acid generator, the self-crosslinkable polymer [1], and optional components that are added as required. When, in particular, the composition is used as a uniform nanoimprinting solution, it is recommended to use a solvent commonly used in lithographic processes in consideration of the coating performance of the composition.

Examples of such solvents include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol monomethyl ether, diethylene glycol monoethyl ether, diethylene glycol dimethyl ether, diethylene glycol diethyl ether, diethylene glycol dipropyl ether, diethylene glycol dibutyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclopentanone, cyclohexanone, N,N-dimethylformamide, N-methylacetamide, N,N-dimethylacetamide, N-methylpyrrolidone, 4-methyl-2-pentanol, and γ-butyrolactone. These solvents may be used singly, or two or more may be used in combination.

(3-3-2)

In order to dissolve uniformly the thermal acid generator, the self-crosslinkable polymer [1], and optional components (such as an aminoplast crosslinking agent or a phenoplast crosslinking agent), it is preferable that the solvent include a compound having an alcoholic hydroxyl group or a compound having a group capable of forming an alcoholic hydroxyl group. Preferred examples of such solvents include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monopropyl ether, propylene glycol monomethyl ether acetate, propylene glycol monoethyl ether, propylene glycol monoethyl ether acetate, propylene glycol propyl ether acetate, cyclopentanone, cyclohexanone, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate.

Among these, propylene glycol solvents (such as propylene glycol monomethyl ether), oxyisobutyric acid ester solvents (such as methyl 2-hydroxy-2-methylpropionate), and butylene glycol solvents are preferable. Among such solvents, propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, methyl 2-hydroxy-2-methylpropionate, ethyl lactate, and cyclohexanone are more preferable, and propylene glycol monomethyl ether, propylene glycol monomethyl ether acetate, methyl 2-hydroxy-2-methylpropionate, ethyl lactate, and cyclohexanone are the most preferable.

(3-3-3)

Furthermore, the composition may include a solvent having a boiling point of 160° C. or above. For example, use may be made of the compound illustrated below that is described in WO 2018/131562 (A1).

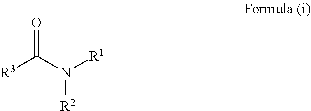

(R¹, R², and R³ in the formula (i) each denote a hydrogen atom or a C1-C20 alkyl group optionally interrupted with an oxygen atom, a sulfur atom, or an amide bond, and are the same as or different from one another and are optionally bonded to one another to form a ring structure.)

Alternatively, 1,6-diacetoxyhexane (boiling point: 260° C.) and tripropylene glycol monomethyl ether (boiling point: 242° C.) described in JP 2021-84974 A, and various high boiling point solvents described in paragraph 0082 of the same publication may be suitably used.

Alternatively, dipropylene glycol monomethyl ether acetate (boiling point: 213° C.), diethylene glycol monoethyl ether acetate (boiling point: 217° C.), diethylene glycol monobutyl ether acetate (boiling point: 247° C.), dipropylene glycol dimethyl ether (boiling point: 171° C.), dipropylene glycol monomethyl ether (boiling point: 187° C.), dipropylene glycol monobutyl ether (boiling point: 231° C.), tripropylene glycol monomethyl ether (boiling point: 242° C.), γ-butyrolactone (boiling point: 204° C.), benzyl alcohol (boiling point: 205° C.), propylene carbonate (boiling point: 242° C.), tetraethylene glycol dimethyl ether (boiling point: 275° C.), 1,6-diacetoxyhexane (boiling point: 260° C.), dipropylene glycol (boiling point: 230° C.), and 1,3-butylene glycol diacetate (boiling point: 232° C.) described in JP 2019-20701 A, and various high boiling point solvents described in paragraphs 0023 to 0031 of the same publication may be suitably used.

### (3-4: Optional Components)

Where necessary, the resist underlayer film forming composition according to the present invention may include additives, such as crosslinking agents, surfactants, light absorbers, rheology modifiers, and adhesion aids, in addition to the above components.

### (3-4-1: Aminoplast Crosslinking Agents)

Exemplary aminoplast crosslinking agents include highly alkylated, alkoxylated, or alkoxyalkylated melamines, benzoguanamines, glycolurils, ureas, and polymers thereof. Preferably, the crosslinking agents have at least two crosslinking substituents, with examples including methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. Condensates of these compounds may also be used.

Furthermore, highly heat-resistant crosslinking agents may be used as the crosslinking agents. Compounds that contain a crosslinking substituent having an aromatic ring (for example, a benzene ring or a naphthalene ring) in the molecule may be preferably used as the highly heat-resistant crosslinking agents.

Preferably, the crosslinking agent is at least one selected from the group consisting of tetramethoxymethylglycoluril and hexamethoxymethylmelamine.

The aminoplast crosslinking agents may be used singly, or two or more may be used in combination. The aminoplast crosslinking agent may be produced by a method known per se or deemed as known or may be purchased from the market. The amount in which the aminoplast crosslinking agent is used varies depending on factors, such as the coating solvent that is used, the base substrate that is used, the solution viscosity that is required, and the film shape that is required, but is 0.001 mass % or more, 0.01 mass % or more, 0.05 mass % or more, 0.5 mass % or more, or 1.0 mass % or more, and is 80 mass % or less, 50 mass % or less, 40 mass % or less, 20 mass % or less, or 10 mass % or less, based on the total solid content in the resist underlayer film forming composition according to an aspect of the present invention.

Some specific examples are illustrated below:

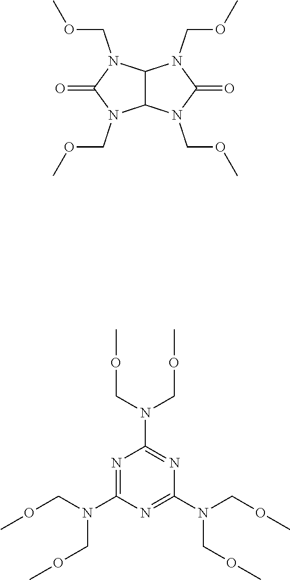

### (3-4-2: Phenoplast Crosslinking Agents)

Exemplary phenoplast crosslinking agents include highly alkylated, alkoxylated, or alkoxyalkylated aromatic compounds, and polymers thereof. Preferably, the crosslinking agents have at least two crosslinking substituents in the molecule, with examples including 2,6-dihydroxymethyl-4-methylphenol, 2,4-dihydroxymethyl-6-methylphenol, bis(2-hydroxy-3-hydroxymethyl-5-methylphenyl)methane, bis(4-hydroxy-3-hydroxymethyl-5-methylphenyl)methane, 2,2-bis(4-hydroxy-3,5-dihydroxymethylphenyl)propane, bis(3-formyl-4-hydroxyphenyl)methane, bis(4-hydroxy-2,5-dimethylphenyl)formylmethane, and α,α-bis(4-hydroxy-2,5-dimethylphenyl)-4-formyltoluene. Condensates of these compounds may also be used.

Furthermore, highly heat-resistant crosslinking agents may be used as the crosslinking agents. Compounds that contain a crosslinking substituent having an aromatic ring (for example, a benzene ring or a naphthalene ring) in the molecule may be preferably used as the highly heat-resistant crosslinking agents.

The phenoplast crosslinking agents may be used singly, or two or more may be used in combination. The phenoplast crosslinking agent may be produced by a method known per se or deemed as known or may be purchased from the market.

The amount in which the phenoplast crosslinking agent is used varies depending on factors, such as the coating solvent that is used, the base substrate that is used, the solution viscosity that is required, and the film shape that is required, but is 0.001 mass % or more, 0.01 mass % or more, 0.05 mass % or more, 0.5 mass % or more, or 1.0 mass % or more, and is 80 mass % or less, 50 mass % or less, 40 mass % or less, 20 mass % or less, or 10 mass % or less, based on the total solid content in the resist underlayer film forming composition according to an aspect of the present invention.

Examples of such compounds, in addition to those described above, include compounds that have a partial structure of formula (4) below, and polymers or oligomers that have a repeating unit of formula (5) below.

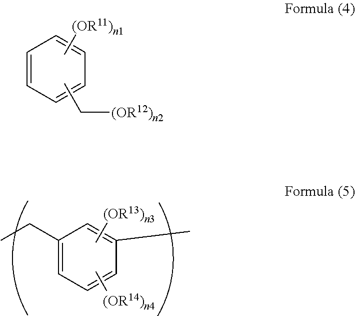

R¹¹, R¹², R¹³, and R¹⁴ are each a hydrogen atom or a C1-C10 alkyl group. Examples of the alkyl groups include those described hereinabove. n1 is an integer of 1 to 4, n2 is an integer of 1 to (5−n1), and (n1+n2) is an integer of 2 to 5. n3 is an integer of 1 to 4, n4 is 0 to (4−n3), and (n3+n4) is an integer of 1 to 4. The number of the repeating unit structures in the oligomers and the polymers may be in the range of 2 to 100, or 2 to 50.

Some specific examples are illustrated below:

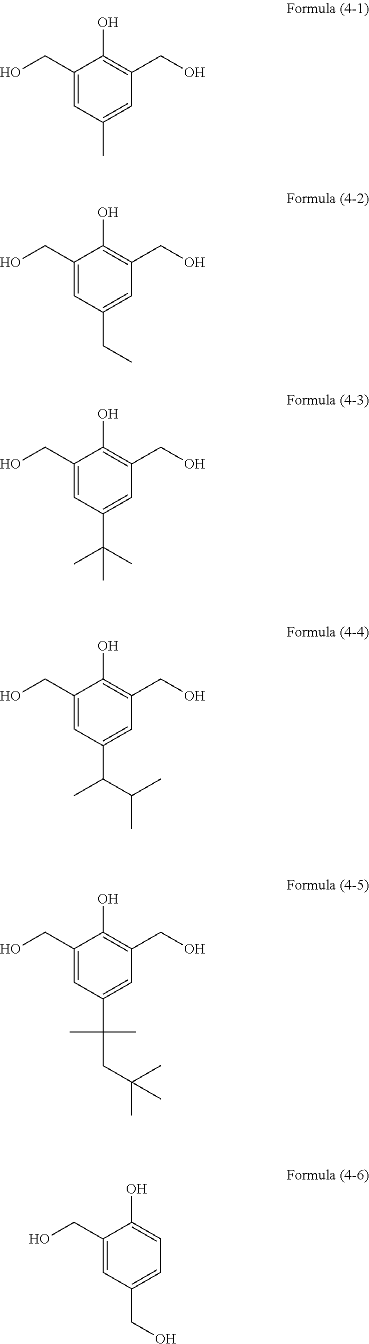 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)(C)CC(C)(C)c1cc(CO)c(O)c(CO)c1 ; OCc1ccc(O)c(CO)c1]

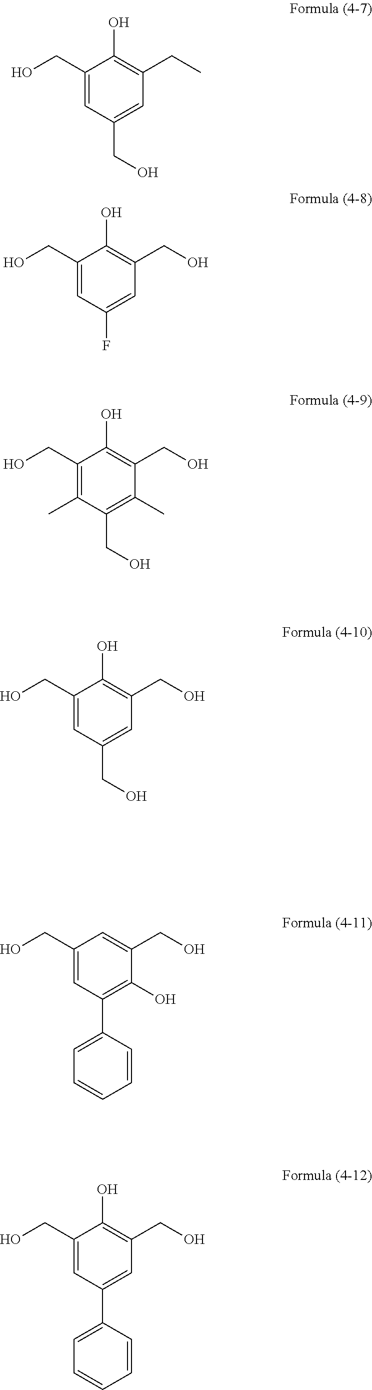 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

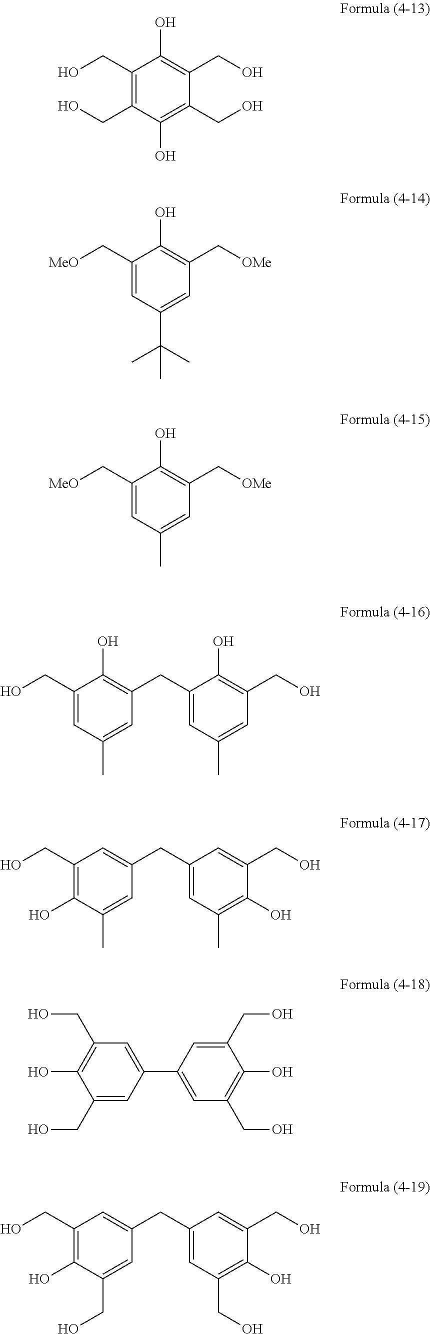

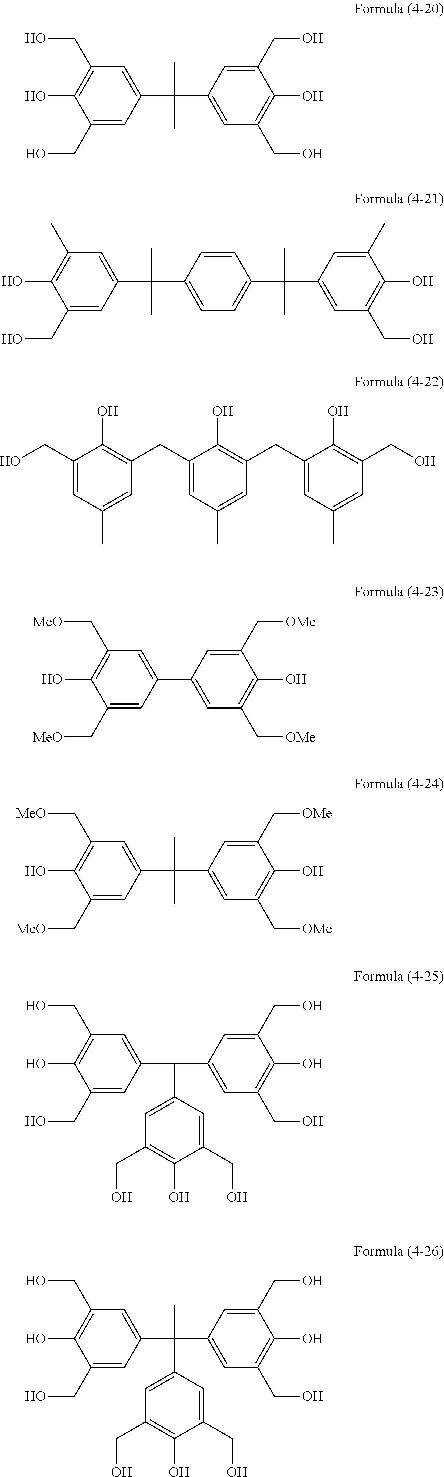

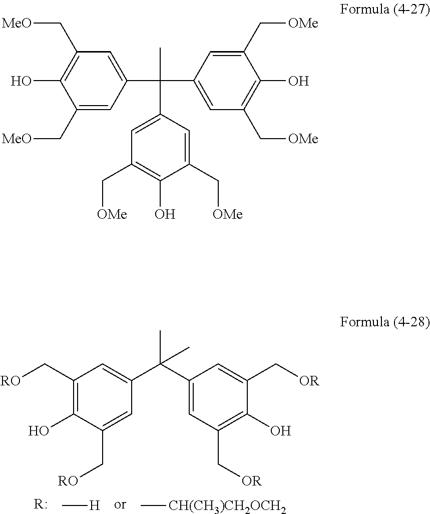

### (3-4-3: Surfactants)

To reduce the occurrence of defects, such as pinholes or striation, and to further enhance the applicability to surface unevenness, the resist underlayer film forming composition according to an aspect of the present invention may include a surfactant.

Examples of the surfactants include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkyl aryl ethers, such as polyoxyethylene octyl phenol ether and polyoxyethylene nonyl phenol ether, polyoxyethylene/polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine surfactants, such as EFTOP series EF301, EF303, and EF352 (product names, manufactured by Tohkem Products Corp.), MEGAFACE series F171, F173, R-30, and R-40 (product names, manufactured by DIC CORPORATION), FLUORAD series FC430 and FC431 (product names, manufactured by Sumitomo 3M Ltd.), ASAHI GUARD AG710, and SURFLON series S-382, SC101, SC102, SC103, SC104, SC105, and SC106 (product names, manufactured by AGC Inc.); and organosiloxane polymer KP341 (manufactured by Shin-Etsu Chemical Co., Ltd.). The amount in which the surfactant is added is usually 2.0 mass % or less, and preferably 1.0 mass % or less relative to the total solid content in the resist underlayer film forming composition according to an aspect of the present invention. The surfactants may be added singly, or two or more may be added in combination.

### (3-4-4: Other Additives)

In order to promote the crosslinking reaction, the resist underlayer film forming composition according to an aspect of the present invention may contain a catalyst in addition to the crosslinking catalyst, namely, the thermal acid generator of, for example, the formula (1). Examples of such additional catalysts include acidic compounds, such as citric acid; thermal acid generators, such as 2,4,4,6-tetrabromocyclohexadienone, benzoin tosylate, 2-nitrobenzyl tosylate, and organic sulfonic acid alkyl esters; onium salt photoacid generators, such as bis(4-t-butylphenyl)iodonium trifluoromethanesulfonate and triphenylsulfonium trifluoromethanesulfonate; halogen-containing compound-based photoacid generators, such as phenyl-bis(trichloromethyl)-s-triazine; and sulfonic acid-based photoacid generators, such as benzoin tosylate and N-hydroxysuccinimide trifluoromethanesulfonate.

Some example light absorbers that may be suitably used include commercially available light absorbers described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorber is usually added in a proportion of 10 mass % or less, preferably 5 mass % or less relative to the total solid content in the resist underlayer film forming composition according to the present invention.

A rheology modifier may be added mainly to enhance the fluidity of the resist underlayer film forming composition and thereby, particularly in the baking step, to enhance the uniformity in thickness of a resist underlayer film and to increase the filling performance of the resist underlayer film forming composition with respect to the inside of holes. Specific examples thereof include phthalic acid derivatives, such as dimethyl phthalate, diethyl phthalate, diisobutyl phthalate, dihexyl phthalate, and butyl isodecyl phthalate; adipic acid derivatives, such as di-n-butyl adipate, diisobutyl adipate, diisooctyl adipate, and octyl decyl adipate; maleic acid derivatives, such as di-n-butyl maleate, diethyl maleate, and dinonyl maleate; oleic acid derivatives, such as methyl oleate, butyl oleate, and tetrahydrofurfuryl oleate; and stearic acid derivatives, such as n-butyl stearate and glyceryl stearate. The rheology modifier is usually added in a proportion of less than 30 mass % relative to the total solid content in the resist underlayer film forming composition according to the present invention.

An adhesion aid may be added mainly to enhance the adhesion between the resist underlayer film forming composition and a substrate or a resist and thereby to prevent the detachment of the resist particularly during development. Specific examples thereof include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, dimethylvinylethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as vinyltrichlorosilane, 7-chloropropyltrimethoxysilane, 7-aminopropyltriethoxysilane, and 7-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. The adhesion aid is usually added in a proportion of less than 5 mass %, preferably less than 2 mass % relative to the total solid content in the resist underlayer film forming composition according to the present invention.

The solid content in the resist underlayer film forming composition according to an aspect of the present invention is 0.1 to 70 mass % or 0.1 to 60 mass %. The solid content is the content of all the components except the solvent in the resist underlayer film forming composition. The proportion of the crosslinkable resin in the solid content may be 1 to 99.9 mass %, or 50 to 99.9 mass %, or 50 to 95 mass %, or 50 to 90 mass %.

### 4: Resist Underlayer Films [16]

A resist underlayer film may be formed as described below using the resist underlayer film forming composition [7] according to an aspect of the present invention.

The resist underlayer film forming composition [7] according to an aspect of the present invention is applied with an appropriate technique, such as a spinner or a coater, onto a semiconductor device substrate (such as, for example, a silicon wafer substrate, a silicon dioxide-coated substrate (a SiO₂ substrate), a silicon nitride substrate (a SiN substrate), a silicon oxynitride substrate (a SiON substrate), a titanium nitride substrate (a TiN substrate), a tungsten substrate (a W substrate), a glass substrate, an ITO substrate, a polyimide substrate, or a low-dielectric constant material (low-k material)-coated substrate), and the coating is baked using a heating device, such as a hot plate, to form a resist underlayer film. The baking conditions are appropriately selected from baking temperatures of 80° C. to 600° C. and amounts of baking time of 0.3 to 60 minutes. The baking temperature is preferably 150° C. to 400° C., more preferably 150° C. to 350° C., and the baking time is preferably 0.5 to 2 minutes. The atmosphere gas at the time of baking may be air or an inert gas, such as nitrogen or argon. In an embodiment, in particular, the oxygen concentration is preferably 1% or less. Here, the film thickness of the underlayer film that is formed is, for example, 10 to 1000 nm, or 20 to 500 nm, or 30 to 400 nm, or 50 to 300 nm. Furthermore, replicas (mold replicas) of a quartz imprinting mold may be produced by using quartz substrates as the substrates.

Furthermore, an adhesion layer and/or a silicone layer containing 99 mass % or less, or 50 mass % or less of Si may be formed on the resist underlayer film according to an aspect of the present invention by application or deposition. For example, an adhesion layer described in JP 2013-202982 A or JP 5827180 B2 may be formed, or a silicon-containing resist underlayer film (inorganic resist underlayer film) forming composition described in WO 2009/104552 (A1) may be applied by spin coating. Furthermore, a Si-based inorganic material film may be formed by such a method as a CVD method.

The resist underlayer film forming composition [7] according to an aspect of the present invention may be applied onto a semiconductor substrate having a stepped region and a stepless region (a so-called non-planar substrate) and may be baked to reduce the difference in height between the stepped region and the stepless region.

### 5: Methods for Manufacturing Semiconductor Devices [18] to [21]

(5-1)
(i)

A method for manufacturing a semiconductor device according to an aspect of the present invention includes:
a step of forming a resist underlayer film from the resist underlayer film forming composition [7] according to an aspect of the present invention;
a step of forming a resist film on the resist underlayer film;
a step of forming a resist pattern by irradiation of the resist film with light or electron beam followed by development;
a step of etching the resist underlayer film through the resist pattern and thereby patterning the resist underlayer film; and
a step of processing a semiconductor substrate through the resist underlayer film having been patterned.
   (ii)

A method for manufacturing a semiconductor device according to another aspect of the present invention includes:
a step of forming a resist underlayer film from the resist underlayer film forming composition [7] according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern and thereby patterning the hard mask;
a step of etching the resist underlayer film through the hard mask having been patterned and thereby patterning the resist underlayer film; and
a step of processing a semiconductor substrate through the resist underlayer film having been patterned.
   (iii)

A method for manufacturing a semiconductor device according to another aspect of the present invention includes:
a step of forming a resist underlayer film from the resist underlayer film forming composition [7] according to an aspect of the present invention;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask; and
a step of processing a semiconductor substrate through the resist underlayer film having been patterned.
   (iv)

A method for manufacturing a semiconductor device according to another aspect of the present invention includes:
a step of forming a resist underlayer film from the resist underlayer film forming composition [7] according to an aspect of the present invention;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing a semiconductor substrate through the deposited film (the spacer) having been patterned.
   (5-2)

The step of forming a resist underlayer film from the resist underlayer film forming composition according to an aspect of the present invention is as described in [4: Resist underlayer films [16]].

A hard mask, such as a silicon-containing film, may be formed as a second resist underlayer film on the resist underlayer film resulting from the above step, and a resist pattern may be formed thereon. The second resist underlayer film may be a coating film or may be a SiON film, a SiN film, or a SiO₂ film formed by a deposition method, such as CVD or PVD. Furthermore, a bottom anti-reflective coating (BARC) as a third resist underlayer film may be formed on the second resist underlayer film. The third resist underlayer film may be a resist shape correction film having no antireflection function.

In the step of forming a resist pattern, the exposure is performed through a mask (a reticle) for forming a predetermined pattern or is carried out by direct drawing. For example, g-line, i-line, KrF excimer laser, ArF excimer laser, EUV, or electron beam may be used as the exposure source. After the exposure, post exposure baking is performed as required. Subsequently, the latent image is developed with a developing solution (for example, a 2.38 mass % aqueous tetramethylammonium hydroxide solution, or butyl acetate), and the pattern is further rinsed with a rinsing solution or pure water to remove the developing solution used. Subsequently, post-baking is performed to dry the resist pattern and to enhance the adhesion with respect to the substrate.

The etching step following the resist pattern formation is performed by dry etching. The etching gas used for dry etching may be, for example, CHF₃, CF₄, or C₂F₆ for the second resist underlayer film (the organopolysiloxane film), may be, for example, O₂, N₂O, or NO₂ for the first resist underlayer film formed from the resist underlayer film forming composition of the present invention, and may be, for example, CHF₃, CF₄, or C₂F₆ for the surface having a step, or a concave portion and/or a convex portion. Furthermore, argon, nitrogen, or carbon dioxide may be mixed with the above gases.

(5-3)

The resist film may be patterned by a nanoimprinting method or a self-assembled film method.

In a nanoimprinting method, a resist composition is molded with a patterned mold that is transparent to the irradiation light. In a self-assembled film method, a pattern is formed using a self-assembled film that naturally forms a regular structure on the order of nanometers, for example, a diblock polymer (such as polystyrene-polymethyl methacrylate).

In a nanoimprinting method, a silicon layer (a hard mask layer) may be optionally formed by application or deposition on the resist underlayer film before the application of a curable composition for forming a resist film. An adhesion layer may be formed on the resist underlayer film or the silicon layer (the hard mask layer) by application or deposition, and a curable composition for forming a resist film may be applied onto the adhesion layer.

(5-4)

Wet etching is sometimes performed for the purposes of simplifying the process step and reducing the damage to the workpiece substrate. This leads to smaller variations in processing dimensions and smaller pattern roughness, and enables processing of substrates with a high yield. Thus, the removal of the hard mask in (5-1) (iii) and (iv) may be performed by either etching or using an alkaline chemical solution. When, in particular, an alkaline chemical solution is used, the components are not particularly limited but the solution preferably includes any of the following alkaline components.

Examples of the alkaline components include tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, and (2-hydroxyethyl)trimethylammonium hydroxide, monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine, triisopropanolamine, tetrahydrofurfurylamine, N-(2-aminoethyl)piperazine, 1,8-diazabicyclo[5.4.0]undecene-7, 1,4-diazabicyclo[2.2.2]octane, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]nonene-5. From the point of view of handling in particular, tetramethylammonium hydroxide and tetraethylammonium hydroxide are particularly preferable, and an inorganic base may be used in combination with the quaternary ammonium hydroxide. Preferred inorganic bases are alkali metal hydroxides, such as potassium hydroxide, sodium hydroxide, and rubidium hydroxide, with potassium hydroxide being more preferable.

### EXAMPLES

### [Synthesis of Polymers]

Compounds A, compounds B, catalysts C, solvents D, and reprecipitation solvents E described below were used for the synthesis of structural formulas (S1) to (S12) as polymers before the introduction of alkoxymethyl groups, such as MOM groups (methoxymethyl groups).

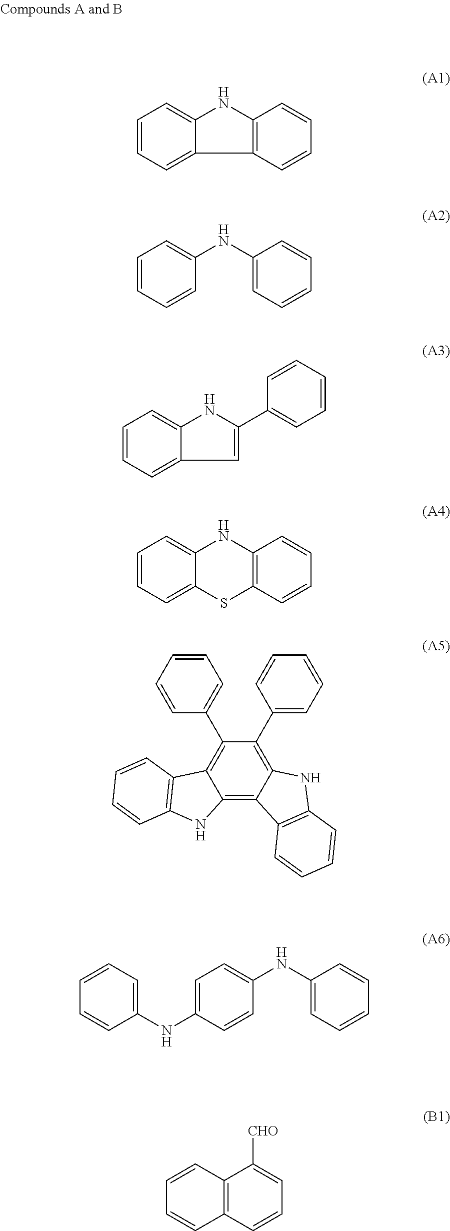

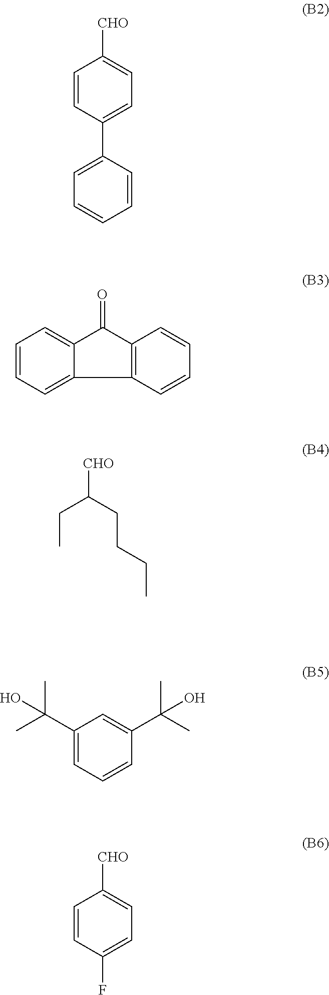

### Catalysts C, Solvents D, and Reprecipitation Solvents E

Methanesulfonic acid: C1
3-Mercaptopropionic acid: C2
1,4-Dioxane: D1
4-Methyltetrahydrofuran (MTHF): D2
Propylene glycol monomethyl ether acetate (=PGMEA): D3
Methanol: E1
Water: E2

### Synthesis Example 1

A flask was charged with 18.0 g of carbazole, 16.8 g of 1-naphthaldehyde, 8.28 g of methanesulfonic acid, 0.9 g of 3-mercaptopropionic acid, and 100.5 g of 1,4-dioxane. Subsequently, the mixture was reacted in a nitrogen atmosphere under reflux for about 2 hours. After the reaction was discontinued, the product was reprecipitated from methanol and was dried to give a resin (S1). The polystyrene-equivalent weight average molecular weight Mw measured by GPC was about 3,170.

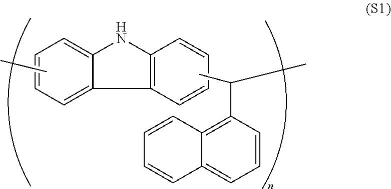

### Synthesis Examples 1 to 12

Polymers before the introduction of MOM groups were synthesized while changing the types of the compounds A, the compounds B, the catalysts C, the solvents D, and the reprecipitation solvents E. The experimental procedures were the same as in Synthesis Example 1. The conditions adopted in the synthesis of polymers (S1) to (S12) are described below.

TABLE 1

| Syn. Ex. | Structural formula | Compounds | Catalysts | Solvents | Temp./time | Reprecipitation |
|---|---|---|---|---|---|---|
| 1 | S1 | A1/B1 | C1/C2 | D1 | Reflux/ | E1 |
| | | 18.0 g/ 16.8 g | 8.28 g/0.9 g | 100.5 g | 2 hr | |
| 2 | S2 | A1/B3 | C1/C2 | D2 | Reflux/ | E1 |
| | | 18.0 g/19.4 g | 20.7 g/2.3 g | 89.2 g | 1.5 hr | |
| 3 | S3 | A1/B4 | C1/C2 | D1 | Reflux/ | E1/E2 |
| | | 18.0 g/13.8 g | 8.28 g/0.9 g | 93.5 g | 23 hr | |
| 4 | S4 | A1/B5 | C1/C2 | D1 | Reflux/ | E1 |
| | | 18.0 g/20.9 g | 8.28 g/0.9 g | 110.1 g | 23 hr | |
| 5 | S5 | A2/B2 | C1 | D3 | 115° C./ | E1 |
| | | 10.0 g/10.8 g | 0.1 g | 62.7 g | 6 hr | |
| 6 | S6 | A3/B1 | C1/C2 | D2 | Reflux/ | E1 |
| | | 18.0 g/14.6 g | 7.16 g/0.8 g | 92.7 g | 2 hr | |
| 7 | S7 | A3/B3/B5 | C1/C2 | D2 | Reflux/ | E1 |
| | | 18.0 g/8.4 g/9.1 g | 17.9 g/2.0 g | 62.8 g | 6 hr | |
| 8 | S8 | A3/B5 | C1/C2 | D2 | Reflux/ | E1 |
| | | 18.0 g/18.1 g | 17.9 g/2.0 g | 64.3 g | 23 hr | |
| 9 | S9 | A4/B1/B5 | C1/C2 | D2 | Reflux/ | E1 |
| | | 18.0 g/7.1 g/8.8 g | 3.5 g/0.4 g | 75.1 g | 4 hr | |
| 10 | S10 | A4/B4 | C1/C2 | D2 | Reflux/ | E1 |
| | | 18.0 g/11.6 g | 6.9 g/0.8 g | 61.3 g | 1.5 hr | |
| 11 | S11 | A5/B3 | C1/C2 | D2 | Reflux/ | E1 |
| | | 18.0 g/7.9 g | 8.5 g/0.9 g | 51.1 g | 2.5 hr | |
| 12 | S12 | A6/B6 | C1 | D3 | Reflux/ | E1/E2 |
| | | 100.0 g/47.7 g | 5.5 g | 459.7 g | 4.5 hr | |

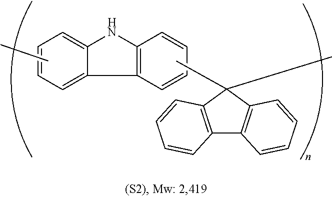

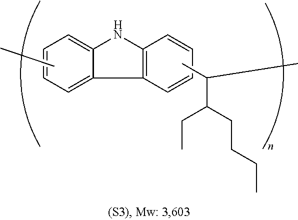

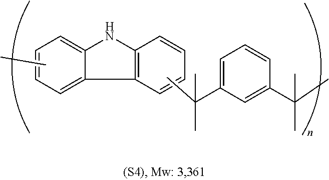

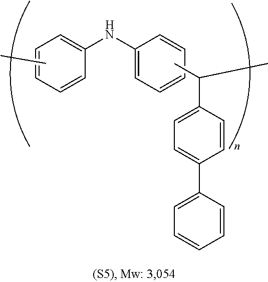

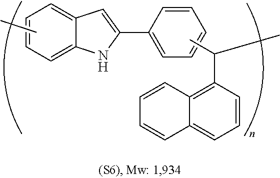

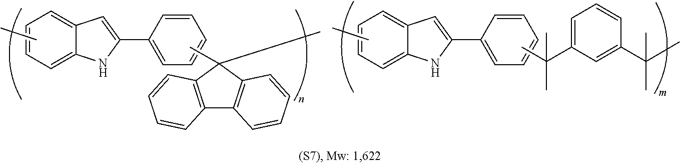

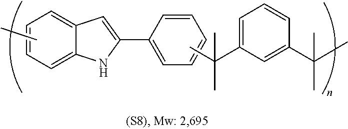

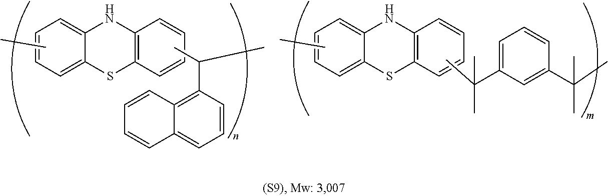

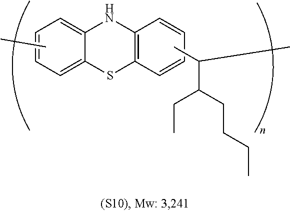

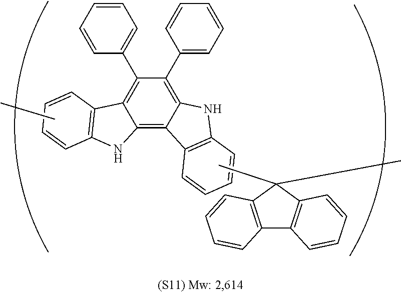

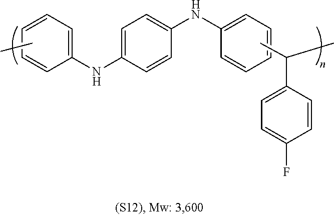

### [Synthesis of MOM Group-Containing Polymers]

MOM groups were introduced into the polymers (S1) to (S11). Structural formulas (SM1) to (SM11) as MOM group-containing polymers for use in resist underlayer films were thus synthesized.

### Synthesis Example 13

A flask was charged with 5.0 g of the polymer (S1) and 20.0 g of N,N-dimethylformamide. The mixture was cooled to 0° C. in an ice bath. Subsequently, 0.7 g of sodium hydride (55%) and 1.3 g of chloromethyl methyl ether were added, and the mixture was stirred for about 30 minutes. Subsequently, the flask was taken out from the ice bath and the mixture was aged for 22 hours while being slowly brought back to room temperature. After the reaction was discontinued, the product was reprecipitated from methanol and was dried to give a resin (SM1). The polystyrene-equivalent weight average molecular weight Mw measured by GPC was about 3,572. The resin obtained was dissolved into PGMEA or cyclohexanone (CYH), and ion exchange was performed for 4 hours using a cation exchange resin and an anion exchange resin. A target compound solution was thus obtained.

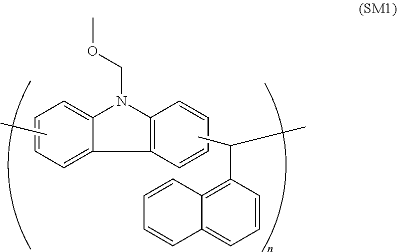

### Synthesis Examples 13 to 23

MOM group-containing polymers for use in resist underlayer films were synthesized while changing the amounts of the solvent and the base. The experimental procedures were the same as in Synthesis Example 13. The conditions adopted in the synthesis of MOM group-containing polymers (SM1) to (SM11) are described below.

TABLE 2

| Syn. Ex. | Structural formula | Polymer | Base | Solvent | MOMC1 | Temp./time |
|---|---|---|---|---|---|---|
| 13 | SM1 | S1 | 55% NaH | DMF | 1.3 g | Room temp./ |
| | | 5.0 g | 0.7 g | 20.0 g | | 22 hr |
| 14 | SM2 | S2 | 55% NaH | DMF | 1.2 g | Room temp./ |
| | | 5.0 g | 0.7 g | 20.0 g | | 20 hr |
| 15 | SM3 | S3 | 55% NaH | DMF | 1.4 g | Room temp./ |
| | | 5.0 g | 0.8 g | 20.0 g | | 22 hr |
| 16 | SM4 | S4 | 55% NaH | DMF | 1.2 g | Room temp./ |
| | | 5.0 g | 0.7 g | 20.0 g | | 19 hr |
| 17 | SM5 | S5 | 55% NaH | DMF | 2.2 g | Room temp./ |
| | | 10.0 g | 1.2 g | 40.0 g | | 18 hr |
| 18 | SM6 | S6 | 55% NaH | DMF | 1.2 g | Room temp./ |
| | | 5.0 g | 0.7 g | 20.0 g | | 21 hr |
| 19 | SM7 | S7 | 55% NaH | DMF | 0.8 g | Room temp./ |
| | | 3.5 g | 0.4 g | 42.0 g | | 2 hr |
| 20 | SM8 | S8 | 55% NaH | DMF | 0.9 g | Room temp./ |
| | | 4.0 g | 0.5 g | 32.0 g | | 4 hr |
| 21 | SM9 | S9 | 55% NaH | DMF | 0.8 g | Room temp./ |
| | | 3.5 g | 0.4 g | 42.0 g | | 2 hr |
| 22 | SM10 | S10 | 55% NaH | DMF | 1.0 g | Room temp./ |
| | | 4.0 g | 0.6 g | 32.0 g | | 4 hr |
| 23 | SM11 | S11 | 55% NaH | DMF | 2.1 g | Room temp./ |
| | | 5.0 g | 1.1 g | 20.0 g | | 20 hr |

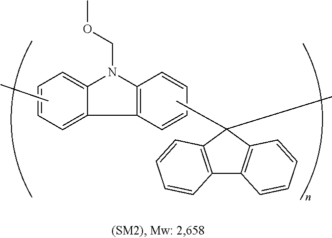

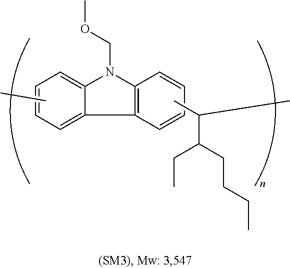

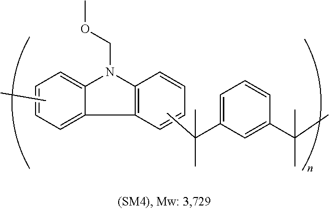

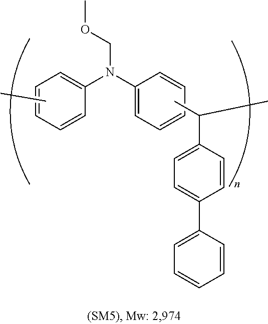

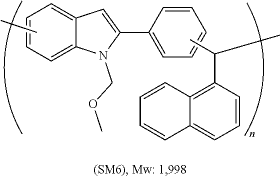

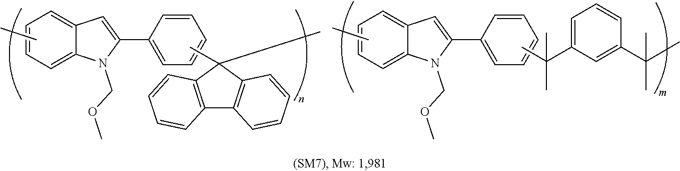

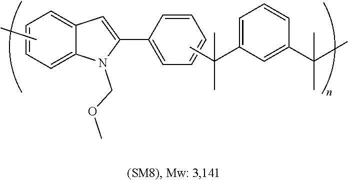

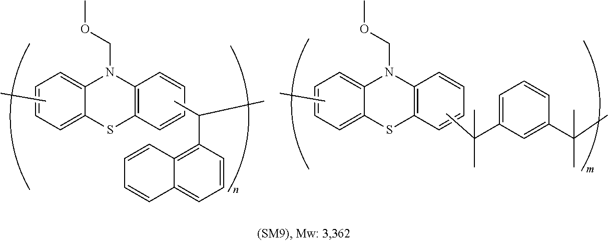

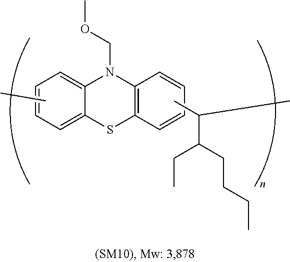

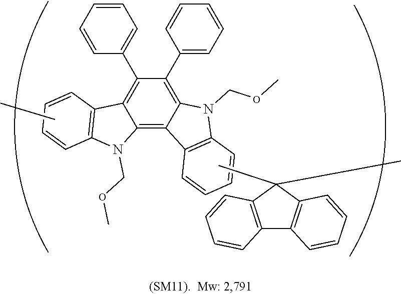

### [Preparation of Resist Underlayer Films]

The polymers (SM1) to (SM11) or the polymers (S1) to (S12), solvents (propylene glycol monomethyl ether acetate (PGMEA), propylene glycol monomethyl ether (PGME), cyclohexanone (CYH)), crosslinking agents (CR1 and CR2), acid generator (Ad1), and MEGAFACE R-30NML (manufactured by DIC CORPORATION. F1) as a surfactant were mixed in weight proportions described in the tables below (relative weights of the components except the solvents per 100 g of the polymer; the amounts of the solvents are shown as relative weights in 100 g of the whole solvent). The mixtures were filtered through a 0.1 m polytetrafluoroethylene microfilter. Resist underlayer film materials (M1 to M13 and Comparative M1 to Comparative M14) were thus prepared.

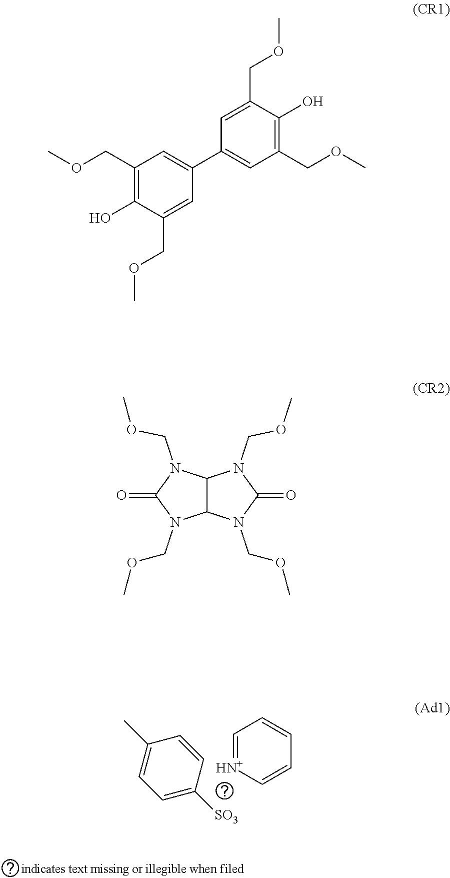

TABLE 3-1

| | | Crosslinking | Acid | | | | |
|---|---|---|---|---|---|---|---|
| Composition | Polymer | agent | generator | Surfactant | Solvents (100 in total) | | |
| M1 | Syn. Ex. 13 | None | None | F1 | PGMEA | PGME | CYH |
| | 100 | — | — | 0.1 | 30 | 0 | 70 |
| M2 | Syn. Ex. 14 | None | None | F1 | PGMEA | PGME | CYH |
| | 100 | — | — | 0.1 | 30 | 0 | 70 |
| M3 | Syn. Ex. 15 | None | None | F1 | PGMEA | PGME | CYH |
| | 100 | — | — | 0.1 | 30 | 0 | 70 |
| M4 | Syn. Ex. 16 | None | None | F1 | PGMEA | PGME | CYH |
| | 100 | — | — | 0.1 | 30 | 0 | 70 |
| M5 | Syn. Ex. 17 | None | None | F1 | PGMEA | PGME | CYH |
| | 100 | — | — | 0.1 | 30 | 0 | 70 |
| M6 | Syn. Ex. 18 | None | None | F1 | PGMEA | PGME | CYH |
| | 100 | — | — | 0.1 | 30 | 0 | 70 |
| M7 | Syn. Ex. 19 | None | None | F1 | PGMEA | PGME | CYH |
| | 100 | — | — | 0.1 | 30 | 0 | 70 |
| M8 | Syn. Ex. 20 | None | None | F1 | PGMEA | PGME | CYH |
| | 100 | — | — | 0.1 | 30 | 0 | 70 |
| M9 | Syn. Ex. 21 | None | None | F1 | PGMEA | PGME | CYH |
| | 100 | — | — | 0.1 | 30 | 0 | 70 |
| M10 | Syn. Ex. 22 | None | None | F1 | PGMEA | PGME | CYH |
| | 100 | — | — | 0.1 | 30 | 0 | 70 |
| M11 | Syn. Ex. 23 | None | None | F1 | PGMEA | PGME | CYH |
| | 100 | — | — | 0.1 | 30 | 0 | 70 |
| M12 | Syn. Ex. 15 | CR1 | Ad1 | F1 | PGMEA | PGME | CYH |
| | 100 | 5.0 | 1.0 | 0.1 | 60 | 20 | 20 |
| M13 | Syn. Ex. 16 | CR2 | Ad1 | F1 | PGMEA | PGME | CYH |
| | 100 | 5.0 | 1.0 | 0.1 | 60 | 20 | 20 |

TABLE 3-2

| | | Crosslinking | Acid | | | | |
|---|---|---|---|---|---|---|---|
| Composition | Polymer | agent | generator | Surfactant | Solvents (100 in total) | | |
| Comp. M1 | Syn. Ex. 1 | None | None | F1 | PGMEA | PGME | CYH |
| | 100 | — | — | 0.1 | 30 | 0 | 70 |
| Comp. M2 | Syn. Ex. 2 | None | None | F1 | PGMEA | PGME | CYH |
| | 100 | — | — | 0.1 | 30 | 0 | 70 |
| Comp. M3 | Syn. Ex. 3 | None | None | F1 | PGMEA | PGME | CYH |
| | 100 | — | — | 0.1 | 30 | 0 | 70 |
| Comp. M4 | Syn. Ex. 4 | None | None | F1 | PGMEA | PGME | CYH |
| | 100 | — | — | 0.1 | 30 | 0 | 70 |
| Comp. M5 | Syn. Ex. 5 | None | None | F1 | PGMEA | PGME | CYH |
| | 100 | — | — | 0.1 | 30 | 0 | 70 |
| Comp. M6 | Syn. Ex. 6 | None | None | F1 | PGMEA | PGME | CYH |
| | 100 | — | — | 0.1 | 30 | 0 | 70 |
| Comp. M7 | Syn. Ex. 7 | None | None | F1 | PGMEA | PGME | CYH |
| | 100 | — | — | 0.1 | 30 | 0 | 70 |
| Comp. M8 | Syn. Ex. 8 | None | None | F1 | PGMEA | PGME | CYH |
| | 100 | — | — | 0.1 | 30 | 0 | 70 |
| Comp. M9 | Syn. Ex. 9 | None | None | F1 | PGMEA | PGME | CYH |
| | 100 | — | — | 0.1 | 30 | 0 | 70 |
| Comp. M10 | Syn. Ex. 10 | None | None | F1 | PGMEA | PGME | CYH |
| | 100 | — | — | 0.1 | 30 | 0 | 70 |
| Comp. M11 | Syn. Ex. 11 | None | None | F1 | PGMEA | PGME | CYH |
| | 100 | — | — | 0.1 | 30 | 0 | 70 |
| Comp. M12 | Syn. Ex. 12 | CR2 | Ad1 | F1 | PGMEA | PGME | CYH |
| | 100 | 30 | 3.0 | 0.1 | 70 | 20 | 10 |
| Comp. M13 | Syn. Ex. 9 | CR2 | Ad1 | F1 | PGMEA | PGME | CYH |
| | 100 | 30 | 3.0 | 0.1 | 20 | 20 | 60 |
| Comp. M14 | Syn. Ex. 9 | CR2 | Ad1 | F1 | PGMEA | PGME | CYH |
| | 100 | 30 | 3.0 | 0.1 | 20 | 20 | 60 |

[Test of Dissolution into Resist Solvent]

The resist underlayer film materials of Examples were each applied onto a silicon wafer using a spin coater, and the coatings were baked for 60 seconds to form resist underlayer films with a film thickness of 65 nm. The resist underlayer films formed were soaked in a general-purpose thinner, specifically, PGME (propylene glycol monomethyl ether)/PGMEA=7/3 for 60 seconds and were heated at 100° C. for 30 seconds. The baking temperature giving rise to solvent resistance was determined by comparing the film thicknesses before and after the thinner immersion. At the baking temperature thus confirmed to give rise to solvent resistance, the comparative materials were baked for 60 seconds to form resist underlayer films with a film thickness of 65 nm. The resist underlayer films were subjected to the similar operation as described above to test the resistance to the solvent. The introduction of MOM groups imparts self-crosslinkability to a polymer and the polymer attains solvent resistance at a lower temperature than a polymer without the introduction of MOM groups. The rating was ∘ when 1% or less loss in film thickness after the thinner immersion was achieved at a lower baking temperature than Comparative Examples.

Furthermore, the underlayer film materials were each applied onto a silicon wafer using ACT-8 manufactured by Tokyo Electron Ltd., and the coatings were baked under nitrogen at a predetermined temperature for a predetermined time described in the table to form a resist underlayer film with a thickness of 65 nm. Similarly to the above, the resist underlayer films were soaked in PGME/PGMEA=7/3 for 60 seconds and were heated at 100° C. for 30 seconds. The film thicknesses before and after the thinner immersion were compared to examine the resistance to the solvent. The resistance was rated as ∘ when the loss in film thickness after the thinner immersion was smaller than Comparative Examples (Table 1).

TABLE 1

| | | Solvent | | |
|---|---|---|---|---|
| | | resistance | | |
| | | Under air | | |
| | | atmosphere | | Solvent |
| Ex./ | | (self-cross- | Baking | resistance |
| Comp. Ex. | Composition | linkability) | temp. | Under nitrogen |
| Ex. 1 | M1 | ∘ | 400° C./ | ∘ |
| | | | 60 sec | |
| Ex. 2 | M3 | ∘ | 400° C./ | ∘ |
| | | | 60 sec | |
| Ex. 3 | M5 | ∘ | 400° C./ | ∘ |
| | | | 60 sec | |
| Ex. 4 | M2 | ∘ | 400° C./ | ∘ |
| | | | 60 sec | |
| Ex. 5 | M4 | ∘ | 400° C./ | ∘ |
| | | | 60 sec | |
| Ex. 6 | M6 | ∘ | 400° C./ | ∘ |
| | | | 60 sec | |
| Ex. 7 | M8 | ∘ | 400° C./ | ∘ |
| | | | 60 sec | |
| Ex. 8 | M10 | ∘ | 400° C./ | ∘ |
| | | | 60 sec | |
| Ex. 9 | M9 | ∘ | 400° C./ | ∘ |
| | | | 60 sec | |
| Ex. 10 | M11 | ∘ | 400° C./ | ∘ |
| | | | 60 sec | |
| Comp. | Comp. M1 | x | 400° C./ | x |
| Ex. 1 | | | 60 sec | |
| Comp. | Comp. M3 | x | 400° C./ | x |
| Ex. 2 | | | 60 sec | |
| Comp. | Comp. M5 | x | 400° C./ | x |
| Ex. 3 | | | 60 sec | |
| Comp. | Comp. M2 | x | 400° C./ | x |
| Ex. 4 | | | 60 sec | |
| Comp. | Comp. M4 | x | 400° C./ | x |
| Ex. 5 | | | 60 sec | |
| Comp. | Comp. M6 | x | 400° C./ | x |
| Ex. 6 | | | 60 sec | |
| Comp. | Comp. M8 | x | 400° C./ | x |
| Ex. 7 | | | 60 sec | |
| Comp. | Comp. M10 | x | 400° C./ | x |
| Ex. 8 | | | 60 sec | |
| Comp. | Comp. M9 | x | 400° C./ | x |
| Ex. 9 | | | 60 sec | |
| Comp. | Comp. M11 | x | 400° C./ | x |
| Ex. 10 | | | 60 sec | |

The above results have confirmed that the introduction of MOM groups imparts self-crosslinkability to polymers that are not self-crosslinkable. The samples (Comparative Examples 1 to 10) exhibited significant dissolution in the resist solvent after being baked in air atmosphere that is adopted in general baking conditions and thus cannot serve as resist underlayer films. Thus, Comparative Examples 11 to 13 were used for comparison in the subsequent evaluations.

### [Measurement of Optical Constants]

The solutions of a resist underlayer film forming composition prepared in Comparative Examples and Examples were each applied onto a silicon wafer using a spin coater. The coatings were baked on a hot plate at a predetermined temperature for a predetermined time described in the table to form a resist underlayer film with a film thickness of 50 nm. These resist underlayer films were analyzed with a spectroscopic ellipsometer to measure the refractive index (n value) and the optical absorption coefficient (k value, also called the attenuation coefficient) at a wavelength of 193 nm (Table 2).

TABLE 2

| | | | Optical |
|---|---|---|---|
| Ex./ | | Baking | constants |
| Comp. Ex. | Composition | temp. | n/k@193 nm |
| Ex. 1 | M1 | 350° C./ | 1.36/0.37 |
| | | 60 sec | |
| Ex. 2 | M3 | 350° C./ | 1.52/0.27 |
| | | 60 sec | |
| Ex. 3 | M5 | 240° C./ | 1.46/0.69 |
| | | 60 sec | |
| Ex. 4 | M2 | 350° C./ | 1.42/0.47 |
| | | 60 sec | |
| Ex. 5 | M4 | 350° C./ | 1.52/0.55 |
| | | 60 sec | |
| Ex. 6 | M6 | 400° C./ | 1.51/0.64 |
| | | 60 sec | |
| Ex. 7 | M8 | 400° C./ | 1.52/0.59 |
| | | 60 sec | |
| Ex. 8 | M10 | 240° C./ | 1.59/0.40 |
| | | 60 sec | |
| Ex. 9 | M9 | 240° C./ | 1.52/0.55 |
| | | 60 sec | |
| Ex. 10 | M11 | 400° C./ | 1.53/0.61 |
| | | 60 sec | |
| Ex. 11 | M12 | 240° C./ | 1.54/0.25 |
| | | 60 sec | |
| Ex. 12 | M13 | 240° C./ | 1.53/0.57 |
| | | 60 sec | |
| Comp. | Comp. M12 | 400° C./ | 1.50/0.61 |
| Ex. 11 | | 60 sec | |
| Comp. | Comp. M13 | 240° C./ | 1.55/0.55 |
| Ex. 12 | | 60 sec | |
| Comp. | Comp. M14 | 400° C./ | 1.49/0.50 |
| Ex. 13 | | 60 sec | |

### [Measurement of Etching Rate]

The resist underlayer film materials of Comparative Examples and Examples were each applied onto a silicon wafer using a spin coater. The coatings were baked on a hot plate at a predetermined temperature for a predetermined time described in the table to form a resist underlayer film with a film thickness of 65 nm. The dry etching rate was measured using O₂/N₂ gas or CF₄ gas as the etching gas (Table 3). The etching resistance was evaluated as ∘ when the etching rate was lower than in Comparative Examples and as x when the etching rate was higher than in Comparative Examples.

The etching measurement involved the following etcher and etching gases:
RIE-200NL (manufactured by Samco Inc.): CF₄ 50 sccm
RIE-200NL (manufactured by Samco Inc.): O₂/N₂ 10 sccm/200 sccm

TABLE 3

| | | |
|---|---|---|
| Ex./ | Baking | Etching resistance |

| Comp. Ex. | Composition | temp. | CF₄ | O₂/N₂ |
|---|---|---|---|---|
| Ex. 1 | M1 | 350° C./ | ∘ | ∘ |
| | | 60 sec | | |
| Ex. 2 | M3 | 350° C./ | ∘ | ∘ |
| | | 60 sec | | |
| Ex. 3 | M5 | 240° C./ | ∘ | ∘ |
| | | 60 sec | | |
| Ex. 4 | M2 | 350° C./ | ∘ | ∘ |
| | | 60 sec | | |
| Ex. 5 | M4 | 350° C./ | ∘ | ∘ |
| | | 60 sec | | |
| Ex. 6 | M6 | 400° C./ | ∘ | ∘ |
| | | 60 sec | | |
| Ex. 7 | M8 | 400° C./ | ∘ | ∘ |
| | | 60 sec | | |
| Ex. 9 | M9 | 240° C./ | ∘ | ∘ |
| | | 60 sec | | |
| Ex. 10 | M11 | 400° C./ | ∘ | ∘ |
| | | 60 sec | | |
| Ex. 11 | M12 | 240° C./ | ∘ | ∘ |
| | | 60 sec | | |
| Ex. 12 | M13 | 240° C./ | ∘ | ∘ |
| | | 60 sec | | |
| Comp. | Comp. M12 | 400° C./ | x | x |
| Ex. 11 | | 60 sec | | |
| Comp. | Comp. M13 | 240° C./ | x | x |
| Ex. 12 | | 60 sec | | |
| Comp. | Comp. M14 | 400° C./ | x | x |
| Ex. 13 | | 60 sec | | |

### [Test of Applicability and Covering Performance on Non-Planar Substrates]

The covering performance was tested using a 100 nm thick SiO₂ non-planar substrate that had a trenched area (a dense pattern area) consisting of 50 nm wide trenches at 100 nm pitches. Resist underlayer films may exhibit poor applicability depending on the types of non-planar substrates. Thus, whether the material was uniformly applicable to the non-planar substrate was tested. The applicability was rated as ∘ when the material was uniformly applied. Specifically, the resist underlayer film forming compositions prepared in Comparative Examples and Examples were each applied to the substrate, and the coatings were baked on a hot plate at a predetermined temperature for a predetermined time described in the table to form a resist underlayer film with a film thickness of 65 nm. The coating film thickness was compared between at the dense area and at a pattern-free area (an open area). The flatness of the substrates was evaluated using a scanning electron microscope (5-4800) manufactured by Hitachi High-Tech Corporation by measuring the difference in film thickness between on the trenched area (the patterned area) and on the open area (the pattern-free area) of the non-planar substrate (the step height created on the coating film between the trenched area and the open area, called a bias). Here, the flatness means how small the difference (an iso-dense bias) is in the film thickness of the coating film between on the region with the pattern (the trenched area (the patterned area)) and on the region without patterns (the open area (the pattern-free area)). Flattening properties were rated as ∘ when the bias was improved compared to Comparative Examples (Table 4).

TABLE 7
(Table 4)

| Ex./ | | Film | | Type of | | Flattening |
|---|---|---|---|---|---|---|
| Comp. Ex. | Composition | thickness | Baking temp. | substrate | Applicability | properties |
| Ex. 2 | M3 | 65 nm | 350° C./60 sec | SiO₂ | ∘ | ∘ |
| Ex. 3 | M5 | 65 nm | 240° C./60 sec | SiO₂ | ∘ | ∘ |
| Ex. 5 | M4 | 65 nm | 350° C./60 sec | SiO₂ | ∘ | ∘ |
| Ex. 7 | M8 | 65 nm | 400° C./60 sec | SiO₂ | ∘ | ∘ |
| Ex. 8 | M10 | 65 nm | 240° C./60 sec | SiO₂ | ∘ | ∘ |
| Ex. 9 | M9 | 65 nm | 400° C./60 sec | SiO₂ | ∘ | ∘ |
| Ex. 10 | M11 | 65 nm | 240° C./60 sec | SiO₂ | ∘ | ∘ |
| Ex. 11 | M12 | 65 nm | 240° C./60 sec | SiO₂ | ∘ | ∘ |
| Ex. 12 | M13 | 65 nm | 240° C./60 sec | SiO₂ | ∘ | ∘ |
| Comp. Ex. 11 | Comp. M12 | 65 nm | 400° C./60 sec | SiO₂ | ∘ | x |
| Comp. Ex. 12 | Comp. M13 | 65 nm | 240° C./60 sec | SiO₂ | ∘ | x |
| Comp. Ex. 13 | Comp. M14 | 65 nm | 400° C./60 sec | SiO₂ | ∘ | x |

### [Test of Gap-Filling Properties on Non-Planar Substrates]

The covering performance was tested using a 100 nm thick SiO₂ non-planar substrate that had a trenched area (a dense pattern area) consisting of 50 nm wide trenches at 100 nm pitches. The resist underlayer film forming compositions prepared in Comparative Examples and Examples were each applied to the substrate, and the coatings were baked on a hot plate at a predetermined temperature for a predetermined time described in the table to form a resist underlayer film with a thickness of 65 nm. Gap-filling properties on the substrates were evaluated using a scanning electron microscope (S-4800) manufactured by Hitachi High-Tech Corporation and were rated as ∘ when the resist underlayer film had filled to the bottom of the trenches (Table 5).

TABLE 5

| | | | | | Gap- |
|---|---|---|---|---|---|
| Ex./ | | Film | Baking | Type of | filling |
| Comp. Ex. | Composition | thickness | temp. | substrate | properties |
| Ex. 1 | M1 | 65 nm | 350° C./ | SiO₂ | ∘ |
| | | | 60 sec | | |
| Ex. 2 | M3 | 65 nm | 350° C./ | SiO₂ | ∘ |
| | | | 60 sec | | |
| Ex. 3 | M5 | 65 nm | 240° C./ | SiO₂ | ∘ |
| | | | 60 sec | | |
| Ex. 4 | M2 | 65 nm | 350° C./ | SiO₂ | ∘ |
| | | | 60 sec | | |
| Ex. 5 | M4 | 65 nm | 350° C./ | SiO₂ | ∘ |
| | | | 60 sec | | |
| Ex. 7 | M8 | 65 nm | 400° C./ | SiO₂ | ∘ |
| | | | 60 sec | | |
| Ex. 8 | M10 | 65 nm | 240° C./ | SiO₂ | ∘ |
| | | | 60 sec | | |
| Ex. 9 | M9 | 65 nm | 400° C./ | SiO₂ | ∘ |
| | | | 60 sec | | |
| Ex. 10 | M11 | 65 nm | 240° C./ | SiO₂ | ∘ |
| | | | 60 sec | | |
| Ex. 11 | M12 | 65 nm | 240° C./ | SiO₂ | ∘ |
| | | | 60 sec | | |
| Ex. 12 | M13 | 65 nm | 240° C./ | SiO₂ | ∘ |
| | | | 60 sec | | |
| Comp. | Comp. M12 | 65 nm | 400° C./ | SiO₂ | ∘ |
| Ex. 11 | | | 60 sec | | |
| Comp. | Comp. M13 | 65 nm | 240° C./ | SiO₂ | ∘ |
| Ex. 12 | | | 60 sec | | |
| Comp. | Comp. M14 | 65 nm | 400° C./ | SiO₂ | ∘ |
| Ex. 13 | | | 60 sec | | |

### [Measurement of Sublimates Amount]

The amount of sublimates was measured using the sublimate amount measuring apparatus described in WO 2007/111147 A1. The resist underlayer film forming compositions prepared in Comparative Example and Examples were each applied to a silicon wafer, and the coatings were baked at 300° C. for 60 seconds to form a 65 nm thick film. The amount of sublimates generated during this process was measured. The rating was ∘ when the amount of sublimates was smaller than in Comparative Example (Table 6).

TABLE 6

| Ex./ | | Baking | Amount of |
|---|---|---|---|
| Comp. Ex. | Composition | temp. | sublimates |
| Ex. 1 | M1 | 300° C./ | ∘ |
| | | 60 sec | |
| Ex. 2 | M3 | 300° C./ | ∘ |
| | | 60 sec | |
| Ex. 3 | M5 | 300° C./ | ∘ |
| | | 60 sec | |
| Ex. 4 | M2 | 300° C./ | ∘ |
| | | 60 sec | |
| Ex. 5 | M4 | 300° C./ | ∘ |
| | | 60 sec | |
| Ex. 6 | M6 | 300° C./ | ∘ |
| | | 60 sec | |
| Ex. 7 | M8 | 300° C./ | ∘ |
| | | 60 sec | |
| Ex. 8 | M10 | 300° C./ | ∘ |
| | | 60 sec | |
| Ex. 9 | M9 | 300° C./ | ∘ |
| | | 60 sec | |
| Ex. 10 | M11 | 300° C./ | ∘ |
| | | 60 sec | |
| Ex. 11 | M12 | 300° C./ | ∘ |
| | | 60 sec | |
| Ex. 12 | M13 | 300° C./ | ∘ |
| | | 60 sec | |
| Comp. | Comp. M14 | 300° C./ | x |
| Ex. 13 | | 60 sec | |

As described above, the materials of Examples, unlike the conventional materials, exhibit curability in the air and in nitrogen even when the materials do not contain a crosslinking agent or a curing catalyst, and can therefore be judged as being self-crosslinkable. It is a matter of course that the materials may contain a crosslinking agent and a curing catalyst similarly to the conventional materials. Furthermore, by changing the polymer skeletons, the materials can be freely controlled in optical constants and in etching resistance and will reflect no or less light at the time of photoexposure, thus allowing for satisfactory resist pattern formation. In addition, the materials exhibit higher resistance to etching by the major etching gases, namely, fluorine-containing or oxygen-containing gases, than the comparative materials. Furthermore, the materials exhibit good applicability with respect to various kinds of deposited films, and also show good gap-filling properties and flattening properties on non-planar substrates having fine irregularities. In addition, the materials generate less sublimates and are less contaminative on devices. Thus, the materials are expected to be applied to a wide range of diverse semiconductor manufacturing processes.

1. A self-crosslinkable polymer comprising:
(A)
one or more kinds of aromatic ring-containing unit structures A; and
(B)
one or more kinds of unit structures B each comprising an organic group having one or more linking carbon atoms,
at least one kind of the unit structure A among the unit structures A is:
(i)
a unit structure including a structure in which at least two aromatic rings are connected via at least one —NR— bond,
(ii)
a unit structure containing a heterocyclic ring having at least one —NR— bond as a ring constituent, the unit structure being such that when the heterocyclic ring is not an aromatic heterocyclic ring, the heterocyclic ring forms a condensed ring with a first aromatic ring and/or is substituted with a substituent containing a second aromatic ring, or
(iii)
a unit structure containing at least one aromatic ring having at least one —NR₂ substituent;
R is a hydrogen atom or an alkoxymethyl group and denotes an alkoxymethyl group in at least part of all the occurrences of R in the polymer; and
the linking carbon atom is a carbon atom in the unit structure B that forms a covalent bond with the aromatic ring in the unit structure A and does not constitute an aromatic ring.

2. The self-crosslinkable polymer according to claim 1, which is a novolac resin.

3. The self-crosslinkable polymer according to claim 1, wherein the unit structures A are selected from unit structures (I-1) to (I-5) below: 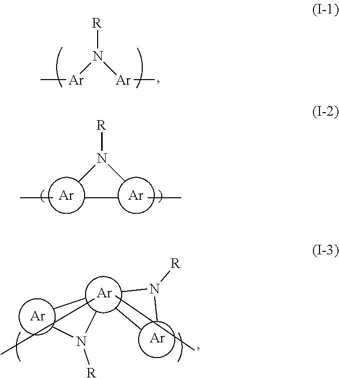
and regioisomers thereof, 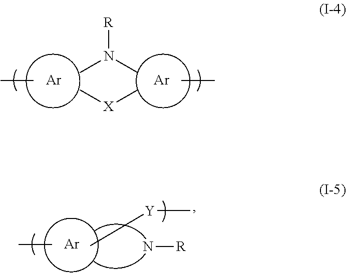
the unit structures (I-1) to (I-5) are optionally further substituted,
R in (I-1) to (I-5) is the same as defined in claim 1,
Ar in (I-1) independently at each occurrence denotes an optionally substituted aromatic ring and is the same as or different from one another,
in (I-2) to (I-5), 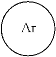
denotes an optionally substituted aromatic ring moiety in the condensed ring and is the same as or different from one another,
X in (I-4) denotes CR¹R², O, S, or NR′; R′ is the same as the definition of R in claim 1 and is the same as or different from R in the chemical formula (I-4); and R and R² are the same as or different from each other and are each an aromatic ring residue or a C1-C3 aliphatic hydrocarbon group,
in (I-5), 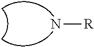
denotes an optionally substituted heterocyclic ring moiety in the condensed ring compound, and
Y is an aromatic ring-containing substituent on the aromatic ring moiety or on the heterocyclic ring moiety.

4. The self-crosslinkable polymer according to claim 1, wherein the unit structures B are unit structures including a structure represented by (II), (III), or (IV) below: 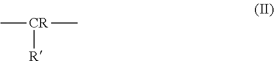
(in the formula (II), R and R′ each independently denote a hydrogen atom, an optionally substituted C6-C30 aromatic ring residue, an optionally substituted C3-C30 heterocyclic ring residue, or an optionally substituted C10 or lower, linear, branched, or cyclic alkyl group), 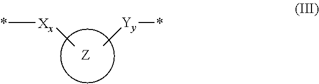
[in the formula (III),
Z is an optionally substituted C4-C25 monocyclic ring or bicyclic, tricyclic, or tetracyclic condensed ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic condensed ring is optionally further condensed with one or more aromatic rings to form a pentacyclic or higher condensed ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1, 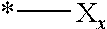
is bonded to any carbon atom (referred to as “carbon atom 1”) constituting any of the non-aromatic monocyclic rings in Z (when x=1) or extends from the carbon atom 1 (when x=0), 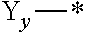
is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond], 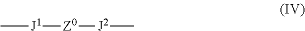
[in the formula (IV), Z⁰ denotes an optionally substituted C6-C30 aromatic ring residue, aliphatic ring residue, or organic group including two aromatic ring residues or aliphatic ring residues connected to each other via a single bond, and J¹ and J² each independently denote a direct bond or an optionally substituted divalent organic group].

5. The self-crosslinkable polymer according to claim 4, wherein
the formula (III) is formula (III-1) below: 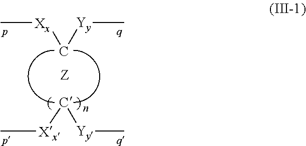
[in the formula (III-1)
Z is an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings,
the monocyclic, bicyclic, tricyclic, or tetracyclic organic group is optionally further condensed or fused with one or more aromatic rings to form a pentacyclic or higher condensed ring,
C and C′ each denote a carbon atom among atoms constituting a ring moiety of any of the non-aromatic monocyclic rings in Z, and C and C belong to the same non-aromatic monocyclic ring or to different non-aromatic monocyclic rings,
n indicates the number of the carbon atoms C′ and denotes an integer of 0 to 2,
p, q, p′, and q′ indicate the number of a valence bond and each independently denote 0 or 1,
when n is 0, p and q are 1,
when n is 1 or 2, at least one of p or q, and at least one of p′ or q′ in each C′ are each 1,
when n is 2, the two C′ atoms belong to the same non-aromatic monocyclic ring while optionally bonding directly to each other, or the two C′ atoms belong to different non-aromatic monocyclic rings,
X, Y, X′, and Y′ denote identical or different —CR¹R²— groups; R¹ and R² are the same as or different from each other and each denote a hydrogen atom or a C1-C3 hydrocarbon group; and when n is 2, the two groups X′ are the same as or different from each other, and the two groups Y′ are the same as or different from each other, and
x, y, x′, and y′ indicate the numbers of X, Y, X′, and Y′, respectively, and each independently denote 0 or 1].

6. The self-crosslinkable polymer according to claim 1, wherein the self-crosslinkable polymer is terminated with an optionally substituted C6-C30 aromatic ring residue, an optionally substituted C1-C10 unsaturated hydrocarbon group, a hydroxyl group, or a hydrogen atom.

7. A resist underlayer film forming composition comprising a thermal acid generator, the self-crosslinkable polymer described in claim 1, and a solvent.

8. The resist underlayer film forming composition according to claim 7, further comprising a crosslinking agent.

9. The resist underlayer film forming composition according to claim 8, wherein the crosslinking agent is an aminoplast crosslinking agent or a phenoplast crosslinking agent.

10. The resist underlayer film forming composition according to claim 9, wherein the aminoplast crosslinking agent is a highly alkylated, alkoxylated, or alkoxyalkylated melamine, benzoguanamine, glycoluril, or urea, or a polymer thereof.

11. The resist underlayer film forming composition according to claim 9, wherein the phenoplast crosslinking agent is a highly alkylated, alkoxylated, or alkoxyalkylated aromatic compound, or a polymer thereof.

12. The resist underlayer film forming composition according to claim 7, wherein the solvent is a compound having an alcoholic hydroxyl group or a compound having a group capable of forming an alcoholic hydroxyl group.

13. The resist underlayer film forming composition according to claim 12, wherein the compound having an alcoholic hydroxyl group or the compound having a group capable of forming an alcoholic hydroxyl group is a propylene glycol solvent, an oxyisobutyric acid ester solvent, or a butylene glycol solvent.

14. The resist underlayer film forming composition according to claim 12, wherein the compound having an alcoholic hydroxyl group or the compound having a group capable of forming an alcoholic hydroxyl group is propylene glycol monomethyl ether, cyclohexanone, propylene glycol monomethyl ether acetate, ethyl lactate, or methyl 2-hydroxy-2-methylpropionate.

15. The resist underlayer film forming composition according to claim 7, further comprising a surfactant.

16. On a semiconductor substrate, a resist underlayer film comprising a baked product of a coating film comprising the resist underlayer film forming composition described in claim 7.

17. A method for forming a resist pattern used in semiconductor manufacturing, the method comprising a step of applying the resist underlayer film forming composition described in claim 7 onto a semiconductor substrate, and baking the resist underlayer film forming composition to form a resist underlayer film.

18. A method for manufacturing a semiconductor device, comprising:
a step of forming on a semiconductor substrate a resist underlayer film from the resist underlayer film forming composition described in claim 7;
a step of forming a resist film on the resist underlayer film;
a step of forming a resist pattern by irradiation with light or electron beam followed by development;
a step of etching the resist underlayer film through the resist pattern; and
a step of processing the semiconductor substrate through the resist underlayer film having been patterned.

19. A method for manufacturing a semiconductor device, comprising:
a step of forming on a semiconductor substrate a resist underlayer film from the resist underlayer film forming composition described in claim 7;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned; and
a step of processing the semiconductor substrate through the resist underlayer film having been patterned.

20. A method for manufacturing a semiconductor device, comprising:
a step of forming on a semiconductor substrate a resist underlayer film from the resist underlayer film forming composition described in claim 7;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.

21. A method for manufacturing a semiconductor device, comprising:
a step of forming on a semiconductor substrate a resist underlayer film from the resist underlayer film forming composition described in claim 7;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.

22. The manufacturing method according to claim 19, wherein the hard mask is formed by applying an inorganic substance or by depositing an inorganic substance.

23. The manufacturing method according to claim 18, wherein the resist film is patterned by a nanoimprinting method or by using a self-assembled film.

24. The method for manufacturing a semiconductor device according to claim 20, wherein the hard mask is removed by etching or with an alkaline chemical solution.
